(19) United States
(12) Patent Application Publication
(10) Pub. No.: US 2026/0047144 A1
(43) Pub. Date: Feb. 12, 2026

(54) SEMICONDUCTOR DEVICE

(71) Applicant: Semiconductor Energy Laboratory Co., Ltd., Atsugi-shi, Kanagawa-ken (JP)

(72) Inventors: Junichi KOEZUKA, Tochigi (JP); Masami JINTYOU, Shimotsuga (JP); Yukinori SHIMA, Tatebayashi (JP)

(21) Appl. No.: 19/102,881

(22) PCT Filed: Aug. 25, 2023
(86) PCT No.: PCT/IB2023/058423

§ 371 Date: Feb. 11, 2025

(30) Foreign Application Priority Data
Sep. 1, 2022 (JP) 2022-139468

(51) Int. Cl. H10D 30/67; H10D 86/40; H10D 86/60

(52) U.S. Cl. CPC H10D 30/6757; H10D 30/6731; H10D 30/6755; H10D 86/423; H10D 86/60

(57) ABSTRACT

A semiconductor device that occupies a small area is provided. The semiconductor device includes a first semiconductor layer, a second semiconductor layer, a third semiconductor layer, a first conductive layer, a second conductive layer, and a first insulating layer. The first insulating layer is provided over the first conductive layer. The second conductive layer is provided over the first insulating layer. The first insulating layer and the second conductive layer include an opening reaching the first conductive layer. The first semiconductor layer is in contact with a top surface of the first conductive layer, a side surface of the first insulating layer, and a top surface and a side surface of the second conductive layer. The second semiconductor layer is provided over the first semiconductor layer. The third semiconductor layer is provided over the second semiconductor layer. The first semiconductor layer contains a first material. The second semiconductor layer contains a second material. The third semiconductor layer contains a third material. A band gap of the first material is larger than a band gap of the second material. A band gap of the third material is larger than the band gap of the second material.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display device including a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a driving method thereof, and a manufacturing method thereof.

Note that in this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means any device that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic device themselves are semiconductor devices and also include a semiconductor device.

### BACKGROUND ART

Semiconductor devices that include transistors are applied to a wide range of electronic devices. In a display device, for example, when the area occupied by transistors is reduced, the pixel size can be reduced and resolution can be increased. Thus, minute transistors have been required.

As devices requiring high-resolution display devices, for example, devices for virtual reality (VR), augmented reality (AR), substitutional reality (SR), or mixed reality (MR) have been actively developed.

As display devices, light-emitting apparatuses including an organic EL (Electro Luminescence) element or a light-emitting diode (LED) has been developed.

Patent Document 1 discloses a high-resolution display device using an organic EL element.

### REFERENCE

### Patent Document

[Patent Document 1] PCT International Publication No. 2016/038508

### SUMMARY OF THE INVENTION

### Problems to be Solved by the Invention

An object of one embodiment of the present invention is to provide a transistor having a minute size. Another object is to provide a transistor having a short channel length. Another object is to provide a transistor having high on-state current. Another object is to provide a transistor having favorable electric characteristics. Another object is to provide a semiconductor device that occupies a small area. Another object is to provide a semiconductor device having small wiring resistance. Another object is to provide a semiconductor device or a display device having low power consumption. Another object is to provide a transistor, a semiconductor device, or a display device having high reliability. Another object is to provide a high-resolution display device. Another object is to provide a method for manufacturing a semiconductor device or a display device having high productivity. Another object is to provide a novel transistor, a novel semiconductor device, a novel display device, and manufacturing methods thereof.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a semiconductor device including a first semiconductor layer, a second semiconductor layer, a third semiconductor layer, a first conductive layer, a second conductive layer, and a first insulating layer. The first insulating layer is provided over the first conductive layer. The second conductive layer is provided over the first insulating layer. The first insulating layer and the second conductive layer include an opening reaching the first conductive layer. The first semiconductor layer is in contact with a top surface of the first conductive layer, a side surface of the first insulating layer, and a top surface and a side surface of the second conductive layer. The second semiconductor layer is provided over the first semiconductor layer. The third semiconductor layer is provided over the second semiconductor layer. The first semiconductor layer includes a first material. The second semiconductor layer includes a second material. The third semiconductor layer includes a third material. A band gap of the first material is larger than a band gap of the second material. A band gap of the third material is larger than the band gap of the second material.

In the above semiconductor device, the first material is preferably the same as the third material.

Another embodiment of the present invention is a semiconductor device including a first semiconductor layer, a second semiconductor layer, a third semiconductor layer, a first conductive layer, a second conductive layer, and a first insulating layer. The first insulating layer is provided over the first conductive layer. The second conductive layer is provided over the first insulating layer. The first insulating layer and the second conductive layer include an opening reaching the first conductive layer. The first semiconductor layer is in contact with a top surface of the first conductive layer, a side surface of the first insulating layer, and a top surface and a side surface of the second conductive layer. The second semiconductor layer is provided over the first semiconductor layer. The third semiconductor layer is provided over the second semiconductor layer. The first semiconductor layer includes a first metal oxide. The second semiconductor layer includes a second metal oxide. The third semiconductor layer includes a third metal oxide. A band gap of the first metal oxide is larger than a band gap of the second metal oxide. A band gap of the third metal oxide is larger than the band gap of the second metal oxide.

In the above semiconductor device, a composition of the first metal oxide is preferably the same as a composition of the third metal oxide.

Another embodiment of the present invention is a semiconductor device including a first semiconductor layer, a second semiconductor layer, a third semiconductor layer, a first conductive layer, a second conductive layer, and a first insulating layer. The first insulating layer is provided over the first conductive layer. The second conductive layer is provided over the first insulating layer. The first insulating layer and the second conductive layer include an opening reaching the first conductive layer. The first semiconductor layer is in contact with a top surface of the first conductive layer, a side surface of the first insulating layer, and a top surface and a side surface of the second conductive layer. The second semiconductor layer is provided over the first semiconductor layer. The third semiconductor layer is provided over the second semiconductor layer. The first semiconductor layer includes a first metal oxide. The second semiconductor layer includes a second metal oxide. The third semiconductor layer includes a third metal oxide. The first metal oxide includes indium and a first element. The second metal oxide includes indium.

The third metal oxide includes indium and a second element. The first element is one or more of gallium, aluminum, and tin. The second element is one or more of gallium, aluminum, and tin. A content percentage of the first element in the first metal oxide is higher than a sum of content percentages of gallium, aluminum, and tin in the second metal oxide. A content percentage of the second element in the third metal oxide is higher than the sum of the content percentages of gallium, aluminum, and tin in the second metal oxide.

In the above semiconductor device, a composition of the first metal oxide is preferably the same as a composition of the third metal oxide.

In the above semiconductor device, a thickness of the first semiconductor layer is preferably smaller than a thickness of the second semiconductor layer. A thickness of the third semiconductor layer is preferably smaller than the thickness of the second semiconductor layer. In the above semiconductor device, the first conductive layer and the second conductive layer each include an oxide conductor.

In the above semiconductor device, the first insulating layer preferably includes a second insulating layer, a third insulating layer over the second insulating layer, and a fourth insulating layer over the third insulating layer. The third insulating layer preferably includes oxygen. The second insulating layer and the fourth insulating layer each preferably include nitrogen. In the above semiconductor device, the first insulating layer preferably includes a second insulating layer, a third insulating layer over the second insulating layer, a fourth insulating layer over the third insulating layer, a fifth insulating layer over the fourth insulating layer, and a sixth insulating layer over the fifth insulating layer. The fourth insulating layer preferably includes oxygen. The second insulating layer, the third insulating layer, the fifth insulating layer, and the sixth insulating layer each preferably include nitrogen. The second insulating layer preferably includes a region having a higher hydrogen content than the third insulating layer. The sixth insulating layer preferably includes a region having a higher hydrogen content than the fifth insulating layer.

### Effect of the Invention

One embodiment of the present invention can provide a transistor having a minute size. Alternatively, a transistor having a short channel length can be provided. Alternatively, a transistor having high on-state current can be provided. Alternatively, a transistor having favorable electrical characteristics can be provided. Alternatively, a semiconductor device that occupies a small area can be provided. Alternatively, a semiconductor device having small wiring resistance can be provided. Alternatively, a semiconductor device or a display device having low power consumption can be provided. Alternatively, a transistor, a semiconductor device, or a display device having high reliability can be provided. Alternatively, a high-resolution display device can be provided. Alternatively, a method for manufacturing a semiconductor device or a display device having high productivity can be provided. Alternatively, a novel transistor, a novel semiconductor device, a novel display device, and manufacturing methods thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a semiconductor device. FIG. 1B and FIG. 1C are cross-sectional views illustrating the example of the semiconductor device.

FIG. 2A to FIG. 2D are perspective views illustrating an example of a semiconductor device.

FIG. 3 is a cross-sectional view illustrating an example of a semiconductor device.

FIG. 4A is a top view illustrating an example of a semiconductor device. FIG. 4B is a cross-sectional view illustrating the example of the semiconductor device.

FIG. 5 is a cross-sectional view illustrating an example of a semiconductor device.

FIG. 6A and FIG. 6B are cross-sectional views illustrating examples of a semiconductor device.

FIG. 7A and FIG. 7B are cross-sectional views illustrating examples of a semiconductor device.

FIG. 8 is a cross-sectional view illustrating an example of a semiconductor device.

FIG. 9A to FIG. 9C are cross-sectional views illustrating an example of a semiconductor device.

FIG. 10A is a top view illustrating an example of a semiconductor device. FIG. 10B and FIG. 10C are cross-sectional views each illustrating the example of the semiconductor device.

FIG. 11A is a top view illustrating an example of a semiconductor device. FIG. 11B and FIG. 11C are cross-sectional views each illustrating the example of the semiconductor device.

FIG. 12 is a cross-sectional view illustrating an example of a semiconductor device.

FIG. 13A to FIG. 13I are circuit diagrams illustrating examples of semiconductor devices.

FIG. 14A is a top view illustrating an example of a semiconductor device. FIG. 14B and FIG. 14C are cross-sectional views each illustrating the example of the semiconductor device.

FIG. 15A to FIG. 15C are cross-sectional views illustrating an example of a semiconductor device.

FIG. 16A is a top view illustrating an example of a semiconductor device. FIG. 16B and FIG. 16C are cross-sectional views each illustrating the example of the semiconductor device.

FIG. 17A is a top view illustrating an example of a semiconductor device. FIG. 17B and FIG. 17C are cross-sectional views each illustrating the example of the semiconductor device.

FIG. 18A is a top view illustrating an example of a semiconductor device. FIG. 18B is a cross-sectional view illustrating the example of the semiconductor device.

FIG. 19A is a top view illustrating an example of a semiconductor device. FIG. 19B is a cross-sectional view illustrating the example of the semiconductor device.

FIG. 20A and FIG. 20B are equivalent circuit diagrams of a semiconductor device. FIG. 20C is a top view illustrating an example of the semiconductor device.

FIG. 21 is a cross-sectional view illustrating an example of a semiconductor device.

FIG. 22 is a perspective view illustrating an example of a semiconductor device.

FIG. 23A to FIG. 23D are perspective views illustrating an example of a semiconductor device.

FIG. 24A and FIG. 24B are equivalent circuit diagrams of a semiconductor device. FIG. 24C is a top view illustrating an example of the semiconductor device.

FIG. 25 is a cross-sectional view illustrating an example of a semiconductor device.

FIG. 26 is a perspective view illustrating an example of a semiconductor device.

FIG. 27A to FIG. 27D are perspective views illustrating an example of a semiconductor device.

FIG. 28A to FIG. 28E are cross-sectional views illustrating an example of a method for manufacturing a semiconductor device.

FIG. 29A to FIG. 29D are cross-sectional views illustrating an example of a method for manufacturing a semiconductor device.

FIG. 30 is a perspective view illustrating an example of a display device.

FIG. 31A and FIG. 31B are cross-sectional views illustrating examples of display devices.

FIG. 32 is a cross-sectional view illustrating an example of a display device.

FIG. 33A to FIG. 33C are cross-sectional views illustrating examples of a display device.

FIG. 34A and FIG. 34B are cross-sectional views illustrating examples of display devices.

FIG. 35 is a cross-sectional view illustrating an example of a display device.

FIG. 36 is a cross-sectional view illustrating an example of a display device.

FIG. 37 is a cross-sectional view illustrating an example of a display device.

FIG. 38A and FIG. 38B are cross-sectional views illustrating examples of display devices.

FIG. 39A to FIG. 39F are cross-sectional views illustrating an example of a method for manufacturing a display device.

FIG. 40A to FIG. 40D are diagrams illustrating examples of electronic devices.

FIG. 41A to FIG. 41F are diagrams illustrating examples of electronic devices.

FIG. 42A to FIG. 42G are diagrams illustrating examples of electronic devices.

FIG. 43 is a diagram showing the Id-Vg characteristics of transistors of Example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Thus, the disclosed invention is not necessarily limited to the position, size, range, or the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the SCOPE OF CLAIMS in some cases.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

A transistor is a kind of semiconductor element and can achieve a function of amplifying current or voltage, a switching operation for controlling conduction or non-conduction, and the like. An IGFET (Insulated Gate Field Effect Transistor) and a thin film transistor (TFT) are in the category of a transistor in this specification.

Functions of a “source” and a “drain” are sometimes replaced with each other when a transistor of opposite polarity is used or when the direction of current is changed in circuit operation, for example. Thus, the terms “source” and “drain” can be switched in this specification. Note that a source and a drain of the transistor can also be referred to as a source terminal and a drain terminal or a source electrode and a drain electrode, for example, as appropriate depending on the situation.

In this specification and the like, “electrically connected” includes the case where connection is made through an “object having any electric function”. Here, there is no particular limitation on the “object having any electric function” as long as electric signals can be transmitted and received between components that are connected through the object. Examples of the “object having any electric function” include a switching element such as a transistor, a resistor, a coil, a capacitor, and other elements with a variety of functions as well as an electrode and a wiring.

Unless otherwise specified, off-state current in this specification and the like refers to leakage current between a source and a drain of a transistor in an off state (also referred to as a non-conduction state or a cutoff state). Unless otherwise specified, an off state in an n-channel transistor refers to a state where voltage V_{gs} between its gate and source is lower than threshold voltage Vₜₕ (in a p-channel transistor, higher than Vₜₕ).

In this specification and the like, the expression “having substantially the same top surface shapes” means that at least outlines of stacked layers partly overlap with each other. For example, the case of processing the upper layer and the lower layer with use of the same mask pattern or mask patterns that are partly the same is included. However, in some cases, the outlines do not completely overlap with each other and the upper layer is positioned inward from the lower layer or the upper layer is positioned outward from the lower layer; such a case is also represented by the expression “top surface shapes are substantially the same”. The state of “having the same top surface shape” or “having substantially the same top surface shapes” can be rephrased as the state where “end portions are aligned with each other” or “end portions are substantially aligned with each other”.

In this specification and the like, a tapered shape refers to such a shape that at least part of a side surface of a component is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the structure are not necessarily completely flat and may be substantially flat with a slight curvature or substantially flat with slight unevenness.

In this specification and the like, a device manufactured using a metal mask or an FMM (fine metal mask, high-resolution metal mask) may be referred to as a device having an MM (metal mask) structure. In this specification and the like, a device manufactured without using a metal mask or an FMM is sometimes referred to as a device having an MML (metal maskless) structure.

In this specification and the like, a structure in which light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can increase the degree of freedom in selecting materials and structures, so that the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

Note that in this specification and the like, a sacrificial layer (also referred to as a mask layer) is positioned above at least a light-emitting layer (specifically, a layer processed into an island shape among layers included in an EL layer) and has a function of protecting the light-emitting layer in the manufacturing process.

Note that in this specification and the like, step disconnection refers to a phenomenon in which a layer, a film, or an electrode is split because of the shape of the formation surface (e.g., a step).

### Embodiment 1

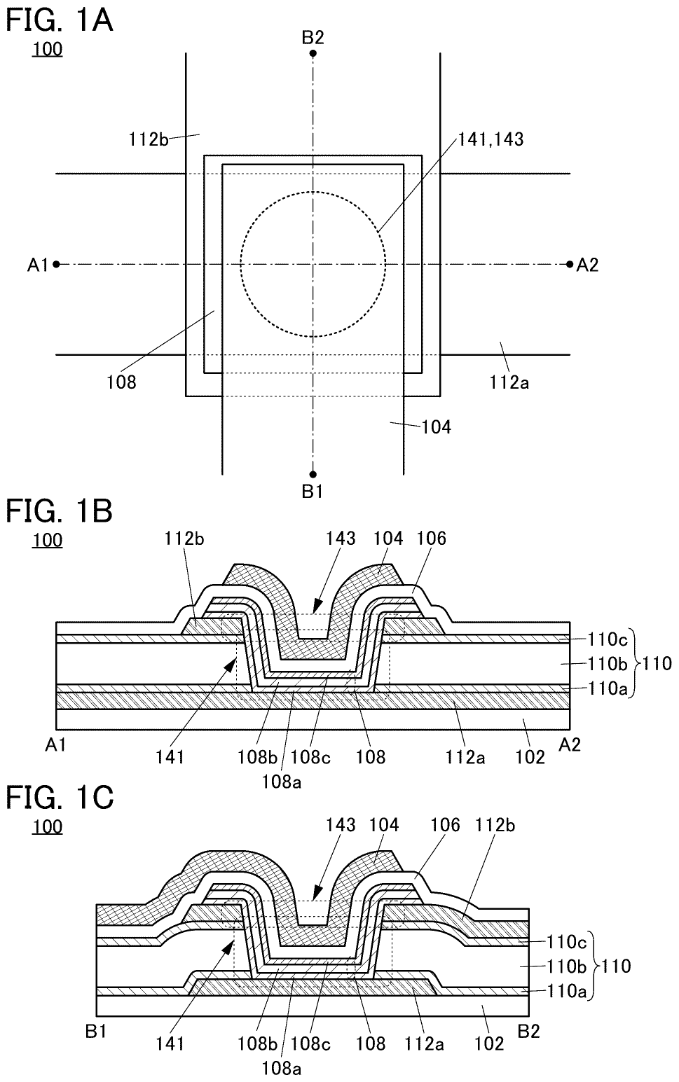

In this embodiment, a semiconductor device of one embodiment of the present invention is described with reference to FIG. 1 to FIG. 27.

### Structure Example 1

### Structure Example 1-1

A transistor that can be used in the semiconductor device of one embodiment of the present invention is described. FIG. 1A is a top view (also referred to as a plan view) of a transistor 100. FIG. 1B is a cross-sectional view of a cut plane along the dashed-dotted line A1-A2 in FIG. 1A, and FIG. 1C is a cross-sectional view of a cut plane along the dashed-dotted line B1-B2. Note that in FIG. 1A, some components (e.g., a gate insulating layer) of the transistor 100 are not illustrated. Some components are not illustrated in top views of transistors in the following drawings, as in FIG. 1A.

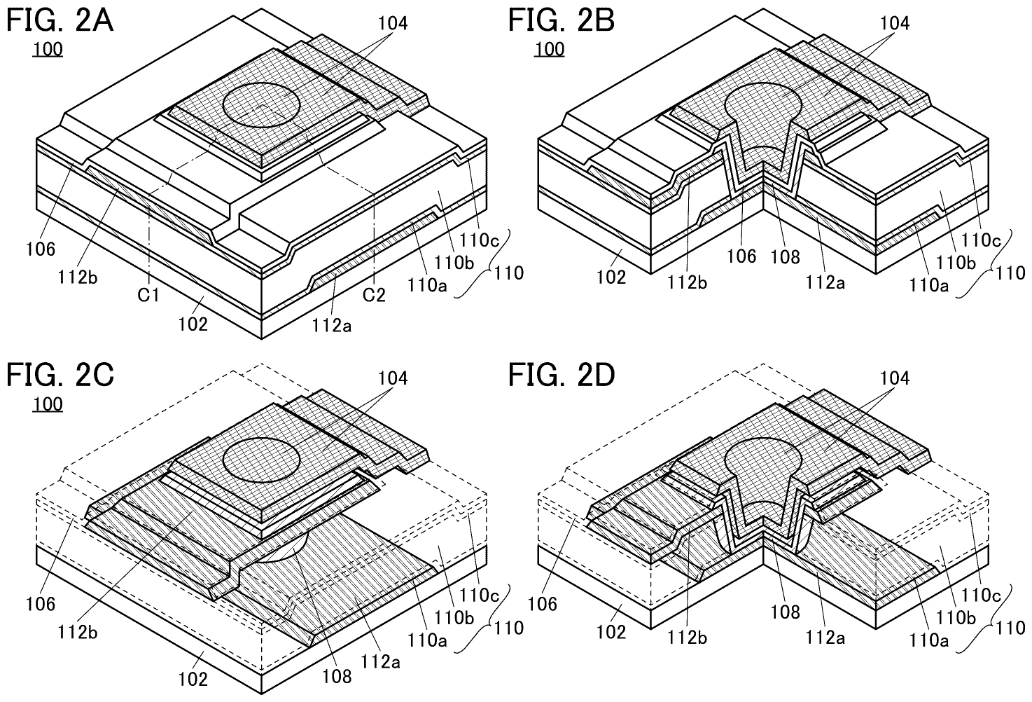

FIG. 2A to FIG. 2D illustrate perspective views of the transistor 100. FIG. 2B illustrates a cut plane along the dashed-dotted line C1-C2 in FIG. 2A. In FIG. 2C, the insulating layer illustrated in FIG. 2A is transparent and its outline is indicated by a dashed line. Similarly, in FIG. 2D, the insulating layer illustrated in FIG. 2B is transparent and its outline is indicated by a dashed line.

The transistor 100 is provided over a substrate 102. The transistor 100 includes a conductive layer 104, an insulating layer 106, a semiconductor layer 108, a conductive layer 112a, and a conductive layer 112b. The conductive layer 104 functions as a gate electrode (that can also be referred to as a first gate electrode). Part of the insulating layer 106 functions as a gate insulating layer (that can also be referred to as a first gate insulating layer). The conductive layer 112a functions as one of a source electrode and a drain electrode, and the conductive layer 112b functions as the other of the source and the drain electrode. In the semiconductor layer 108 between the source electrode and the drain electrode, the whole region overlapping with the gate electrode with the gate insulating layer therebetween functions as a channel formation region. In the semiconductor layer 108, a region in contact with the source electrode functions as a source region, and a region in contact with the drain electrode functions as a drain region.

The conductive layer 112a is provided over the substrate 102, an insulating layer 110 is provided over the conductive layer 112a, and the conductive layer 112b is provided over the insulating layer 110. The insulating layer 110 includes a region interposed between the conductive layer 112a and the conductive layer 112b. The conductive layer 112a includes a region overlapping with the conductive layer 112b with the insulating layer 110 therebetween. The insulating layer 110 has an opening 141 reaching the conductive layer 112a. It can be said that the conductive layer 112a is exposed in the opening 141. The conductive layer 112b has an opening 143 in a region overlapping with the conductive layer 112a. The opening 143 is provided in a region overlapping with the opening 141. Note that although the opening 141 included in the insulating layer 110 and the opening 143 included in the conductive layer 112b are denoted by different reference numerals in FIG. 1A and the like, these openings can be collectively referred to as one opening. In other words, the insulating layer 110 and the conductive layer 112b include an opening reaching the conductive layer 112a.

The semiconductor layer 108 is provided to cover the opening 141 and the opening 143. The semiconductor layer 108 includes a region in contact with the top surface and a side surface of the conductive layer 112b, a side surface of the insulating layer 110, and the top surface of the conductive layer 112a. The semiconductor layer 108 is electrically connected to the conductive layer 112a in the opening 141. The semiconductor layer 108 has a shape along the shapes of the top surface and the side surface of the conductive layer 112b, the side surface of the insulating layer 110, and the top surface of the conductive layer 112a.

The semiconductor layer 108 preferably has a stacked-layer structure. FIG. 1B and the like illustrate a structure in which the semiconductor layer 108 has a stacked-layer structure of a semiconductor layer 108a, a semiconductor layer 108b over the semiconductor layer 108a, and a semiconductor layer 108c over the semiconductor layer 108b.

The insulating layer 106 functioning as the gate insulating layer of the transistor 100 is provided to cover the opening 141 and the opening 143. The insulating layer 106 is provided over the semiconductor layer 108, the conductive layer 112b, and the insulating layer 110. The insulating layer 106 includes a region in contact with the top surface and the side surface of the semiconductor layer 108, the top surface and the side surface of the conductive layer 112b, and the top surface of the insulating layer 110. The insulating layer 106 has a shape along the shapes of the top surface of the insulating layer 110, the top surface and the side surface of the conductive layer 112b, the top surface and the side surface of the semiconductor layer 108, and the top surface of the conductive layer 112a.

The conductive layer 104 functioning as the gate electrode of the transistor 100 is provided over the insulating layer 106 and includes a region in contact with the top surface of the insulating layer 106. The conductive layer 104 includes a region overlapping with the semiconductor layer 108 with the insulating layer 106 therebetween. The conductive layer 104 has a shape along the shape of the top surface of the insulating layer 106.

The transistor 100 is what is called a top-gate transistor including the gate electrode above the semiconductor layer 108. Furthermore, since the bottom surface of the semiconductor layer 108 is in contact with the source electrode and the drain electrode, the transistor 100 can be referred to as a TGBC (Top Gate Bottom Contact) transistor. In the transistor 100, the source electrode and the drain electrode are positioned at different levels with respect to the surface of the substrate 102 over which the transistor 100 is formed, and the drain current flows in a direction perpendicular or substantially perpendicular to the surface of the substrate 102. In the transistor 100, the drain current can also be regarded as flowing in the vertical direction or the substantially vertical direction. Accordingly, the transistor of one embodiment of the present invention can be referred to as a vertical-channel transistor or a vertical field-effect transistor (VFET).

The channel length of the transistor 100 can be controlled by the thickness of the insulating layer 110 provided between the conductive layer 112a and the conductive layer 112b. Thus, a transistor with a channel length shorter than the resolution limit of a light exposure apparatus used for manufacturing the transistor can be manufactured with high accuracy. Furthermore, variations in characteristics among the transistors 100 are also reduced. Accordingly, the operation of the semiconductor device including the transistor 100 can be stabilized and the reliability thereof can be improved. When the variations in characteristics are reduced, the circuit design flexibility is increased and the operation voltage of the semiconductor device can be reduced. Thus, the power consumption of the semiconductor device can be reduced.

In the transistor of one embodiment of the present invention, the source electrode, the semiconductor layer, and the drain electrode can be provided to overlap with each other; thus, the area occupied by the transistor can be significantly smaller than the area occupied by a so-called planar transistor in which a planar semiconductor layer is placed.

The conductive layer 112a, the conductive layer 112b, and the conductive layer 104 can function as wirings, and the transistor 100 can be provided in a region where these wirings overlap with each other. That is, the areas occupied by the transistor 100 and the wirings can be reduced in the circuit including the transistor 100 and the wirings. Accordingly, the area occupied by the circuit can be reduced, which makes it possible to provide a small semiconductor device.

When the semiconductor device of one embodiment of the present invention is used for a pixel circuit of a display device, for example, the area occupied by the pixel circuit can be reduced and a high-resolution display device can be obtained. When the semiconductor device of one embodiment of the present invention is used for a driver circuit (e.g., one or both of a gate line driver circuit and a source line driver circuit) of a display device, the area occupied by the driver circuit can be reduced and the display device can have a narrow bezel, for example.

Although FIG. 1B and the like illustrate an example in which the semiconductor layer 108, the insulating layer 106, and the conductive layer 104 cover the opening 141 and the opening 143, one embodiment of the present invention is not limited thereto. A step may be formed between the conductive layer 112a and each of the insulating layer 110 and the conductive layer 112b, and the semiconductor layer 108, the insulating layer 106, and the conductive layer 104 may be provided along with the step.

### [Semiconductor Layer 108]

The semiconductor layer 108 includes the semiconductor layer 108a, the semiconductor layer 108b over the semiconductor layer 108a, and the semiconductor layer 108c over the semiconductor layer 108b.

A first material used for the semiconductor layer 108a and a second material used for the semiconductor layer 108b preferably have different band gaps. A third material used for the semiconductor layer 108c and the second material used for the semiconductor layer 108b preferably have different band gaps. Note that the band gap of the third material may be the same as or substantially the same as or different from the band gap of the first material.

The band gap of the first material is preferably larger than the band gap of the second material. The band gap of the third material is preferably larger than the band gap of the second material. The semiconductor layer 108b is interposed between the semiconductor layer 108a and the semiconductor layer 108c, which have a larger band gap than the semiconductor layer 108b, and thus can have a structure of a buried channel. Thus, the semiconductor layer 108b serves as a main current path in the semiconductor layer 108.

The conduction band minimum of the first material is preferably closer to the vacuum level than the conduction band minimum of the second material. The conduction band minimum of the third material is preferably closer to the vacuum level than the conduction band minimum of the second material. In other words, the electron affinity of the first material is preferably smaller than the electron affinity of the second material. The electron affinity of the third material is preferably smaller than the electron affinity of the second material. Note that the electron affinity of the third material may be the same as or substantially the same as or different from the electron affinity of the first material.

Here, a trap state due to impurities or defects can be formed at the interface between the insulating layer 110 and the semiconductor layer 108 and in the vicinity thereof. Examples of the impurities include a remaining component of an etchant or an etching gas used in the formation of the opening 141 and components of the conductive layer 112a and the conductive layer 112b attached to the side surface of the insulating layer 110 in the formation of the opening 141. Providing the semiconductor layer 108a between the semiconductor layer 108b and the insulating layer 110 can make the semiconductor layer 108b and the trap state to be distant from each other.

The interface between the insulating layer 106 and the semiconductor layer 108 and the vicinity thereof might be damaged at the time of forming the insulating layer 106. Accordingly, trap states can be formed at the interface between the insulating layer 106 and the semiconductor layer 108 and in the vicinity thereof. Providing the semiconductor layer 108c between the semiconductor layer 108b and the insulating layer 106 can make the semiconductor layer 108b and the trap state to be distant from each other.

When the semiconductor layer 108b, which is the main current path of the semiconductor layer 108, is interposed between the semiconductor layer 108a and the semiconductor layer 108c, the trap states at the interface of the semiconductor layer 108b and the vicinity thereof can be reduced. This structure enables the transistor to have a high-on state and high reliability. Consequently, the semiconductor device can have both high performance and high reliability.

There is no particular limitation on a semiconductor material used for the semiconductor layer 108a, and the semiconductor layer 108b, and the semiconductor layer 108c. For example, a single-element semiconductor or a compound semiconductor can be used. Examples of a single-element semiconductor include silicon and germanium. Examples of the compound semiconductor include gallium arsenide and silicon germanium. Other examples of the compound semiconductor include an organic semiconductor, a nitride semiconductor, and an oxide semiconductor. These semiconductor materials may contain an impurity as a dopant.

The first material is preferably different from the second material. The third material is preferably different from the second material. The third material may be the same as or substantially the same as or different from the first material.

Note that in this specification and the like, different materials mean materials in which some or all of constituent elements are different or materials having the same constituent elements and different compositions.

There is no particular limitation on the crystallinity of a semiconductor material used for the semiconductor layer 108a, the semiconductor layer 108b, and the semiconductor layer 108c, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

The semiconductor layer 108a, the semiconductor layer 108b, and the semiconductor layer 108c each preferably includes a metal oxide (also referred to as an oxide semiconductor) exhibiting semiconductor characteristics.

The band gap of a first metal oxide used for the semiconductor layer 108a, the band gap of a second metal oxide used for the semiconductor layer 108b, and the band gap of a third metal oxide used for the semiconductor layer 108c are each preferably 2.0 eV or more, further preferably 2.5 eV or more.

The first metal oxide and the second metal oxide preferably have different band gaps. For example, a difference between the band gap of the first metal oxide and the band gap of the second metal oxide is preferably greater than or equal to 0.1 eV, further preferably greater than or equal to 0.2 eV, still further preferably greater than or equal to 0.3 eV. The third metal oxide and the second metal oxide preferably have different band gaps. For example, a difference between the band gap of the third metal oxide and the band gap of the second metal oxide is preferably greater than or equal to 0.1 eV, further preferably greater than or equal to 0.2 eV, still further preferably greater than or equal to 0.3 eV. Note that the band gap of the third metal oxide may be the same, substantially the same, or different from the band gap of the first metal oxide.

The band gap of the first metal oxide is preferably larger than the band gap of the second metal oxide. The band gap of the third metal oxide is preferably larger than the band gap of the second metal oxide. Accordingly, a buried channel structure can be obtained.

The conduction band minimum of the first metal oxide is preferably closer to the vacuum level than the conduction band minimum of the second metal oxide. The conduction band minimum of the third metal oxide is preferably closer to the vacuum level than the conduction band minimum of the second metal oxide is. In other words, the electron affinity of the first metal oxide is preferably smaller than the electron affinity of the second metal oxide. The electron affinity of the third metal oxide is preferably smaller than the electron affinity of the second metal oxide. Note that the electron affinity of the third metal oxide may be the same as or substantially the same as or different from the electron affinity of the first metal oxide.

The composition of the first metal oxide is preferably different from the composition of the second metal oxide. The composition of the third metal oxide is preferably different from the composition of the second metal oxide. The composition of the third metal oxide may be the same as or substantially the same as or different from the composition of the first metal oxide.

The composition of the first metal oxide used for the semiconductor layer 108a is preferably the same as the composition of the third metal oxide used for the semiconductor layer 108c. Employing the metal oxides having the same composition can reduce the manufacturing cost because the semiconductor layer 108a and the semiconductor layer 108c can be formed using the same sputtering target.

Examples of the first metal oxide, the second metal oxide, and the third metal oxide include indium oxide, gallium oxide, and zinc oxide. The metal oxide preferably contains at least indium or zinc. The metal oxide preferably contains two or three selected from indium, an element M, and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably one or more kinds selected from gallium, aluminum, and tin. In this specification and the like, a metal element and a metalloid element may be collectively referred to as a “metal element”, and a “metal element” in this specification and the like may refer to a metalloid element.

For example, for each of the first metal oxide, the second metal oxide, and the third metal oxide, an indium zinc oxide (also referred to as In—Zn oxide or IZO (registered trademark)), an indium tin oxide (also referred to as In—Sn oxide or ITO), an indium titanium oxide (In—Ti oxide), an indium gallium oxide (In—Ga oxide), an indium tungsten oxide (also referred to as In—W oxide or IWO), an indium gallium aluminum oxide (In—Ga—Al oxide), an indium gallium tin oxide (also referred to as In—Ga—Sn oxide or IGTO), a gallium zinc oxide (also referred to as Ga—Zn oxide or GZO), an aluminum zinc oxide (also referred to as Al—Zn oxide or AZO), an indium aluminum zinc oxide (also referred to as In—Al—Zn oxide or IAZO), an indium tin zinc oxide (also referred to as In—Sn—Zn oxide or ITZO (registered trademark)), an indium titanium zinc oxide (In—Ti—Zn oxide), an indium gallium zinc oxide (also referred to as In—Ga—Zn oxide or IGZO), an indium gallium tin zinc oxide (also referred to as In—Ga—Sn—Zn oxide or IGZTO), or an indium gallium aluminum zinc oxide (also referred to as In—Ga—Al—Zn oxide, IGAZO, IGZAO, or IAGZO) can be used. Alternatively, indium tin oxide containing silicon (also referred to as ITSO), gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased. In addition, the transistor can have high on-state current.

Note that the metal oxide may contain, instead of or in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a larger period number in the periodic table can have high field-effect mobility in some cases. Examples of the metal element with a larger period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may include one or more kinds selected from nonmetallic elements. By containing a non-metallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Accordingly, a change in electrical characteristics of the transistor can be inhibited, and the reliability of the transistor can be improved.

By increasing the proportion of the element M atoms in the total number of atoms of all the metal elements included in the metal oxide, oxygen vacancies can be inhibited from being formed in the metal oxide. Thus, generation of carriers due to oxygen vacancies is inhibited, which makes the off-state current of the transistor low. Furthermore, a change in electrical characteristics of the transistor can be inhibited, and the reliability of the transistor can be improved.

Electrical characteristics and reliability of a transistor depend on the composition of the metal oxide used for the semiconductor layer 108a, the semiconductor layer 108b, and the semiconductor layer 108c. Therefore, by changing the composition of the metal oxide in accordance with the electrical characteristics and reliability required for the transistor, the semiconductor device can have both excellent electrical characteristics and high reliability. When a metal oxide is an In—M—Zn oxide, the atomic ratio of In is preferably higher than or equal to the atomic ratio of the element M in the In—M—Zn oxide. Examples of the atomic ratio of the metal elements in such an In—M—Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:1, In:M:Zn=10:1:3, In:M:Zn=10:1:4, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or the vicinity thereof. Note that a composition in the vicinity includes the range of +30% of an intended atomic ratio. By increasing the proportion of the number of indium atoms in the metal oxide, the on-state current, field-effect mobility, or the like of the transistor can be improved.

The atomic ratio of In may be less than the atomic ratio of the element M in the In—M—Zn oxide. Examples of the atomic ratio of the metal elements of such an In—M—Zn oxide include In:M:Zn=1:3:2, In:M:Zn=1:3:3, and In:M:Zn=1:3:4 and a composition in the vicinity thereof. By increasing the proportion of the number of M atoms in the metal oxide, generation of oxygen vacancies can be suppressed.

In the case where a plurality of metal elements are contained as the element M, the sum of the proportions of the numbers of atoms of these metal elements can be used as the proportion of the number of element M atoms.

In this specification and the like, the proportion of the number of indium atoms in the total number of atoms of all the metal elements contained is sometimes referred to as indium content percentage. The same applies to other metal elements.

The band gap can be adjusted when the composition of the first metal oxide used for the semiconductor layer 108a and the composition of the second metal oxide used for the semiconductor layer 108b are different from each other. Specifically, the content percentage of the element M in the first metal oxide is preferably higher than that of the element M in the second metal oxide. Thus, the band gap of the first metal oxide can be larger than the band gap of the second metal oxide. For example, in the case where the first metal oxide and the second metal oxide are each an In—M—Zn oxide, the first metal oxide can have an atomic ratio of In:M:Zn=1:1:1 or a composition in the vicinity thereof, and the second metal oxide can have an atomic ratio of In:M:Zn=40:1:10 or a composition in the vicinity thereof. Alternatively, the first metal oxide can have an atomic ratio of In:M:Zn=1:1:1 or a composition in the vicinity thereof, and the second metal oxide can have an atomic ratio of In:M:Zn=10:1:10 or a composition in the vicinity thereof. More specifically, the first metal oxide can have an atomic ratio of In:M:Zn=1:1:1 or a composition in the vicinity thereof, and the second metal oxide can have an atomic ratio of In:M:Zn=10:1:40 or a composition in the vicinity thereof. It is particularly preferable to use one or more of gallium, aluminum, and tin as the element M. The element M included in the first metal oxide, the element M included in the second metal oxide, and the element M included in the third metal oxide may be the same or different from each other. In the case where one or more of the first metal oxide, the second metal oxide, and the third metal oxide contain a plurality of the elements M, each of the elements M may be the same as or different from any of the elements M of the other metal oxides.

The composition of the third metal oxide is preferably different from the composition of the second metal oxide. Specifically, the content percentage of the element M in the third metal oxide is preferably higher than that of the second metal oxide. Accordingly, the band gap of the third metal oxide can be larger than that of the second metal oxide. For the third metal oxide, the description of the first metal oxide can be referred to. Note that the content percentage of the element M in the third metal oxide may be the same as or substantially the same as or different from the content percentage of the element M in the first metal oxide.

For example, the first metal oxide can have an atomic ratio of In:M:Zn=1:1:1 or a composition in the vicinity thereof, the second metal oxide can have an atomic ratio of In:M:Zn=40:1:10 or a composition in the vicinity thereof, and the third metal oxide can have an atomic ratio of In:M:Zn=1:1:1 or a composition in the vicinity thereof. Alternatively, the first metal oxide can have an atomic ratio of In:M:Zn=1:1:1 or a composition in the vicinity thereof, the second metal oxide can have an atomic ratio of In:M:Zn=10:1:10 or a composition in the vicinity thereof, and the third metal oxide can have an atomic ratio of In:M:Zn=1:1:1 or a composition in the vicinity thereof. Alternatively, the first metal oxide can have an atomic ratio of In:M:Zn=1:1:1 or a composition in the vicinity thereof, the second metal oxide can have an atomic ratio of In:M:Zn=10:1:40 or a composition in the vicinity thereof, and the third metal oxide can have an atomic ratio of In:M:Zn=1:1:1 or a composition in the vicinity thereof.

More specifically, it is preferable that the first metal oxide have an atomic ratio of In:Ga:Zn=1:1:1 or a composition in the vicinity thereof, the second metal oxide have an atomic ratio of In:Sn:Zn=40:1:10 or a composition in the vicinity thereof, and the third metal oxide have an atomic ratio of In:Ga:Zn=1:1:1 or a composition in the vicinity thereof. Alternatively, it is preferable that the first metal oxide have an atomic ratio of In:Ga:Zn=1:1:1 or a composition in the vicinity thereof, the second metal oxide have an atomic ratio of In:Sn:Zn=10:1:10 or a composition in the vicinity thereof, and the third metal oxide have an atomic ratio of In:Ga:Zn=1:1:1 or a composition in the vicinity thereof. Alternatively, it is preferable that the first metal oxide have an atomic ratio of In:Ga:Zn=1:1:1 or a composition in the vicinity thereof, the second metal oxide have an atomic ratio of In:Sn:Zn=10:1:40 or a composition in the vicinity thereof, and the third metal oxide have an atomic ratio of In:Ga:Zn=1:1:1 or a composition in the vicinity thereof.

The second metal oxide may have a composition not including the element M. For example, the second metal oxide can be an In—Zn oxide, and the first metal oxide and the third metal oxide can be an In—M—Zn oxide. Specifically, the second metal oxide can be an In—Zn oxide, and the first metal oxide and the third metal oxide can be an In—M—Zn oxide. More specifically, it is preferable that the first metal oxide have an atomic ratio of In:Ga:Zn=1:1:1 or a composition in the vicinity thereof, the second metal oxide have an atomic ratio of In:Zn=4:1 or a composition in the vicinity thereof, and the third metal oxide have an atomic ratio of In:Ga:Zn=1:1:1 or a composition in the vicinity thereof. Alternatively, it is preferable that the first metal oxide have an atomic ratio of In:Ga:Zn=1:1:1 or a composition in the vicinity thereof, the second metal oxide have an atomic ratio of In:Zn=1:1 or a composition in the vicinity thereof, and the third metal oxide have an atomic ratio of In:Ga:Zn=1:1:1 or a composition in the vicinity thereof. Alternatively, it is preferable that the first metal oxide have an atomic ratio of In:Ga:Zn=1:1:1 or a composition in the vicinity thereof, the second metal oxide have an atomic ratio of In:Zn=1:4 or a composition in the vicinity thereof, and the third metal oxide have an atomic ratio of In:Ga:Zn=1:1:1 or a composition in the vicinity thereof.

The ratio of the content percentage of the element M to indium in the first metal oxide is preferably higher than the ratio of the content percentage of the element M to indium in the second metal oxide. Thus, the band gap of the first metal oxide can be larger than that of the second metal oxide. Similarly, the ratio of the content percentage of the element M to indium in the third metal oxide is preferably higher than the ratio of the content percentage of the element M to indium in the second metal oxide. Accordingly, the band gap of the third metal oxide can be larger than that of the second metal oxide.

Alternatively, the content percentage of the element M in the first metal oxide is preferably higher than or equal to indium (i.e., the ratio of the content percentage of the element M to the content percentage of indium is preferably higher than or equal to 1). The content percentage of the element M in the second metal oxide is preferably lower than the content percentage of indium (i.e., the ratio of the content percentage of the element M to the content percentage of indium is preferably lower than 1). The content percentage of the element M in the third metal oxide is preferably higher than or equal to indium (i.e., the ratio of the content percentage of the element M to the content percentage of indium is preferably higher than or equal to 1).

The content percentage of indium in the second metal oxide is preferably higher than that in the first metal oxide. The content percentage of indium in the second metal oxide is preferably higher than that in the third metal oxide. This enables the transistor have a large on-state current.

As an analysis of the composition of the first metal oxide, the second metal oxide, and the third metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage, may be difficult to measure, or may be undetectable.

The case where EDX is used for analysis of the compositions of the first metal oxide, the second metal oxide, and the third metal oxide will be specifically described. In EDX, the proportion of the number of atoms of each element contained in the analysis target can be calculated. A comparison is made of the proportion of the number of indium atoms in the sum of the calculated total number of atoms of all the metal elements (indium content percentage), whereby the difference in indium content percentage can be confirmed. In EDX, the number of counts of characteristic X-rays corresponds to the proportion of an element contained in a metal oxide. Thus, from the peak heights of indium, the difference in indium content percentage can be confirmed. For example, in the case where the content percentage of indium in the second metal oxide is higher than the content percentage of indium in the first metal oxide, the number of counts of characteristic X-rays derived from indium in the second metal oxide is higher than the number of counts of characteristic X-rays derived from indium in the first metal oxide. Note that in EDX, the peak of a certain element refers to a point at which the number of counts of the element reaches a local maximum value in a spectrum where the horizontal axis represents the energy of characteristic X-rays and the vertical axis represents the number of counts of characteristic X-rays. Alternatively, the number of counts at an energy of a characteristic X-ray unique to the element may be used to confirm a difference in content percentage. For example, the number of counts at 3.287 keV (In—La) can be used for indium.

Although the difference in indium content percentage is described here as an example, the same applied to the content percentage of other elements. Note that in the case where the difference in content percentage is observed using the number of counts in the energy of characteristic X-rays unique to the element, for example, the number of counts at 9.243 keV (Ga—Kα) can be used for gallium and the number of counts at 8.632 keV (Zn—Kα) can be used for zinc.

A sputtering method or an atomic layer deposition (ALD) method can be suitably used for forming a film of the metal oxide. Note that in the case where the metal oxide film is formed by a sputtering method, the composition of the formed metal oxide may be different from the composition of a sputtering target. In particular, the content percentage of the zinc in the formed metal oxide film may be reduced to approximately 50% of that of the sputtering target.

It is preferable to use a metal oxide having crystallinity for each of the semiconductor layer 108a, the semiconductor layer 108b, and the semiconductor layer 108c. Examples of the structure of a metal oxide having crystallinity include a CAAC (c-axis aligned crystalline) structure, a polycrystalline structure, and a nano-crystal (nc) structure. With use of a metal oxide having crystallinity for the semiconductor layer 108, the density of defect states in the semiconductor layer 108 can be reduced, which enables the semiconductor device to have high reliability.

When a metal oxide having high crystallinity is used for the semiconductor layer, the density of defect states in the semiconductor layer can be reduced. By contrast, the use of a metal oxide having low crystallinity enables a transistor to flow a large amount of current.

When the first metal oxide having crystallinity is used for the semiconductor layer 108a, the crystallinity of the second metal oxide included in the semiconductor layer 108b formed over the semiconductor layer 108a can be increased. Similarly, when the second metal oxide having crystallinity is used for the semiconductor layer 108b, the crystallinity of the third metal oxide included in the semiconductor layer 108c formed over the semiconductor layer 108b can be increased.

The crystallinity of the formed metal oxide can be increased as the substrate temperature at the time of formation is higher. For example, the substrate temperature at the time of formation can be adjusted by the temperature of the stage on which the substrate is placed. The crystallinity of the formed metal oxide layer can be increased with a higher proportion of the flow rate of an oxygen gas to the total flow rate of the film formation gas used at the time of formation (hereinafter also referred to as oxygen flow rate ratio) or with higher oxygen partial pressure in a processing chamber of a film formation apparatus.

The composition of the first metal oxide used for the semiconductor layer 108a, the composition of the second metal oxide used for the semiconductor layer 108b, and the composition of the third metal oxide used for the semiconductor layer 108c may be the same or substantially the same. Employing the metal oxides having the same composition can reduce the manufacturing cost because the metal oxides can be formed using the same sputtering target, for example. Here, the degree of crystallinity of the semiconductor layer 108b is preferably different from the degree of crystallinity of the semiconductor layer 108a. The degree of crystallinity of the semiconductor layer 108b is preferably different from the degree of crystallinity of the semiconductor layer 108c. Specifically, the crystallinity of the semiconductor layer 108b is preferably lower than that of the semiconductor layer 108a. The crystallinity of the semiconductor layer 108b is preferably lower than that of the semiconductor layer 108c. Accordingly, the conductivity of the semiconductor layer 108b is increased, so that the transistor can have a high on-state current. Providing the semiconductor layer 108a having high crystallinity on the insulating layer 110 side can inhibit diffusion of impurities at the interface between the insulating layer 110 and the semiconductor layer 108 and the vicinity thereof into the semiconductor layer 108. Furthermore, providing the semiconductor layer 108c having high crystallinity on the insulating layer 106 side can reduce damage to the semiconductor layer 108 in forming the insulating layer 106. For example, the semiconductor layer 108b can have a microcrystalline (nc) structure, and the semiconductor layer 108a and the semiconductor layer 108c each can have a CAAC structure.

Although an example in which the crystallinity of the semiconductor layer 108b is lower than that of the semiconductor layer 108a and the semiconductor layer 108c is described here, one embodiment of the present invention is not limited thereto. The crystallinity of the semiconductor layer 108b may be higher than that of the semiconductor layer 108a and the semiconductor layer 108c.

The composition of the first metal oxide can be the same or substantially the same as the composition of the second metal oxide, and the composition of the third metal oxide can be different from the composition of the second metal oxide. In this case, the degree of crystallinity of the semiconductor layer 108a is preferably different from the degree of crystallinity of the semiconductor layer 108b. Specifically, the crystallinity of the semiconductor layer 108a is preferably higher than that of the semiconductor layer 108b. Alternatively, the composition of the third metal oxide can be the same or substantially the same as the composition of the second metal oxide, and the composition of the first metal oxide can be different from the composition of the second metal oxide. In this case, the degree of crystallinity of the semiconductor layer 108c is preferably different from the degree of crystallinity of the semiconductor layer 108b. Specifically, the crystallinity of the semiconductor layer 108c is preferably higher than that of the semiconductor layer 108b.

The crystallinity of the semiconductor layer 108a, the semiconductor layer 108b, and the semiconductor layer 108c can be analyzed with X-ray diffraction (XRD), a transmission electron microscope (TEM), electron diffraction (ED), or the like, for example. Alternatively, such kinds of analysis methods may be performed in combination.

Note that in the case where the composition of the first metal oxide is the same or substantially the same as the composition of the second metal oxide, a boundary (interface) between the semiconductor layer 108a and the semiconductor layer 108b cannot be clearly observed in some cases. Similarly, in the case where the composition of the second metal oxide is the same or substantially the same as the composition of the third metal oxide, a boundary (interface) between the semiconductor layer 108b and the semiconductor layer 108c cannot be clearly observed in some cases.

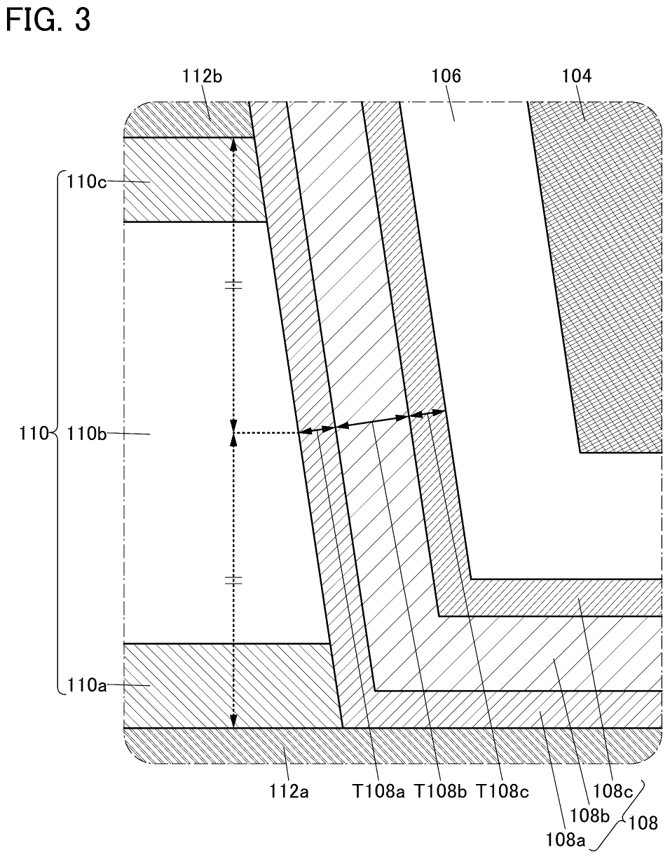

FIG. 3 is an enlarged view of the side surface of the insulating layer 110 and the vicinity thereof. In FIG. 3, a thickness T108a of the semiconductor layer 108a, a thickness T108b of the semiconductor layer 108b, and a thickness T108c of the semiconductor layer 108c are indicated by solid double-headed arrows. Here, the shortest distance between the insulating layer 110 and the insulating layer 106 in the cross-sectional view is the thickness of the semiconductor layer 108. Specifically, FIG. 3 shows the thicknesses of the layers of the semiconductor layer 108 at the midpoint between the level of the top surface and the level of the bottom surface of the insulating layer 110.

The thickness T108b of the semiconductor layer 108b is preferably larger than or equal to 1.0 nm and smaller than or equal to 100 nm, further preferably larger than or equal to 1.0 nm and smaller than or equal to 50 nm, further preferably larger than or equal to 3.0 nm and smaller than or equal to 50 nm, further preferably larger than or equal to 3.0 nm and smaller than or equal to 40 nm, further preferably larger than or equal to 3.0 nm and smaller than or equal to 30 nm, further preferably larger than or equal to 3.0 nm and smaller than or equal to 20 nm, further preferably larger than or equal to 3.0 nm and smaller than or equal to 15 nm, further preferably larger than or equal to 3.0 nm and smaller than or equal to 10 nm, further preferably larger than or equal to 5.0 nm and smaller than or equal to 10 nm.

When the thickness T108a of the semiconductor layer 108a is small, the distance between the semiconductor layer 108b which is the main current path and the trap states at the interface between the insulating layer 110 and the semiconductor layer 108 and the vicinity thereof is reduced; thus, an on-state current of the transistor may be reduced. In addition, the reliability of the transistor may be degraded. Meanwhile, when the thickness T108a of the semiconductor layer 108a is large, the distance between the semiconductor layer 108b and the conductive layers 112a and 112b functioning as the source electrode and the drain electrode is increased; thus, an on-state current may be reduced. The thickness T108a of the semiconductor layer 108a is preferably greater than or equal to 0.1 nm and less than or equal to 10 nm, further preferably greater than or equal to 0.3 nm and less than or equal to 10 nm, still further preferably greater than or equal to 0.3 nm and less than or equal to 5.0 nm, yet still further preferably greater than or equal to 0.5 nm and less than or equal to 5.0 nm, yet still further preferably greater than or equal to 0.5 nm and less than or equal to 3.0 nm, yet still further preferably greater than or equal to 0.7 nm and less than or equal to 3.0 nm, yet still further preferably greater than or equal to 0.7 nm and less than or equal to 2.0 nm, yet still further preferably greater than or equal to 1.0 nm and less than or equal to 2.0 nm. When the thickness of the semiconductor layer 108a is within the above range, the transistor can have a high on-state current and high reliability.

When the thickness T108c of the semiconductor layer 108c is small, the distance between the semiconductor layer 108b which is the main current path and the trap states at the interface between the insulating layer 106 and the semiconductor layer 108 and the vicinity thereof; thus, an on-state current of the transistor may be reduced. In addition, the reliability of the transistor may be degraded. Meanwhile, when the thickness T108c of the semiconductor layer 108c is large, the distance between the conductive layer 104 functioning as a gate electrode and the semiconductor layer 108b is increased; thus, an on-state current may be reduced. The thickness T108c of the semiconductor layer 108c is preferably larger than or equal to 0.5 nm and smaller than or equal to 20 nm, further preferably larger than or equal to 0.5 nm and smaller than or equal to 15 nm, further preferably larger than or equal to 1.0 nm and smaller than or equal to 15 nm, further preferably larger than or equal to 1.0 nm and smaller than or equal to 10 nm, further preferably larger than or equal to 2.0 nm and smaller than or equal to 10 nm, further preferably larger than or equal to 2.0 nm and smaller than or equal to 7.0 nm, further preferably larger than or equal to 2.0 nm and smaller than or equal to 5.0 nm. When the thickness of the semiconductor layer 108c is within the above range, the transistor can have a high on-state current and high reliability.

In the case where an oxide semiconductor is used for the semiconductor layer 108, hydrogen contained in the oxide semiconductor reacts with oxygen bonded to a metal atom to be water, and thus may form an oxygen vacancy (Vo) in the oxide semiconductor. In some cases, a defect that is an oxygen vacancy into which hydrogen enters (hereinafter referred to as VoH) functions as a donor and generates an electron serving as a carrier. In other cases, bonding of part of hydrogen to oxygen bonded to a metal atom generates electrons serving as carriers. Thus, a transistor including an oxide semiconductor that contains a large amount of hydrogen is likely to have normally-on characteristics. Moreover, hydrogen in an oxide semiconductor is easily transferred by stress such as heat or an electric field; thus, the reliability of the transistor might be reduced when the oxide semiconductor includes a large amount of hydrogen.

In the case where an oxide semiconductor is used for the semiconductor layer 108, the amount of VoH in the semiconductor layer 108 is preferably reduced as much as possible so that the semiconductor layer 108 becomes a highly purified intrinsic or substantially highly purified intrinsic semiconductor layer. In order to obtain such an oxide semiconductor with sufficiently reduced VoH, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with sufficiently reduced impurities such as VoH is used for a channel formation region of a transistor, the transistor can have stable electrical characteristics. Note that repairing oxygen vacancies by supplying oxygen to an oxide semiconductor is sometimes referred to as oxygen adding treatment. In particular, the amount of VoH is preferably small in the semiconductor layer 108b which is the main current path.

When an oxide semiconductor is used for the semiconductor layer 108, the carrier concentration of the oxide semiconductor in the region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. The lower limit of the carrier concentration of the oxide semiconductor in the region functioning as the channel formation region is not particularly limited and can be, for example, 1×10⁻⁹ cm⁻³. In the semiconductor layer 108b, the carrier concentration of the region functioning as the channel formation region is particularly preferably low and is preferably within the above-described range.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be retained for a long period. Furthermore, a semiconductor device can have lower power consumption by including the OS transistor.

A change in electrical characteristics of an OS transistor due to irradiation with radiation is small, i.e., an OS transistor has high resistance to radiation; thus, an OS transistor can be suitably used even in an environment where radiation might enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Examples of silicon that can be used for the semiconductor layer 108 include single crystal silicon, polycrystalline silicon, microcrystalline silicon, and amorphous silicon. An example of polycrystalline silicon is low-temperature polysilicon (LTPS).

The transistor using amorphous silicon for the semiconductor layer 108 can be formed over a large glass substrate, and can be manufactured at low cost. The transistor including polycrystalline silicon in the semiconductor layer 108 has high field-effect mobility and enables high-speed operation. The transistor including microcrystalline silicon in the semiconductor layer 108 has higher field-effect mobility and enables higher speed operation than the transistor including amorphous silicon.

The semiconductor layer 108 may include a layered material functioning as a semiconductor. The layered material generally refers to a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having high on-state current can be provided.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Opening 141 and Opening 143]

There is no limitation on the top-view shapes of the opening 141 and the opening 143, and the shapes can be polygons such as a circle, an ellipse, a triangle, a tetragon (including a rectangle, a rhombus, and a square), and a pentagon; and polygons with rounded corners, for example. Note that the polygon may be a concave polygon (a polygon at least one of the interior angles of which is greater than) 180° or a convex polygon (a polygon all the interior angles of which are less than or equal to) 180°. The top-view shapes of the opening 141 and the opening 143 are each preferably a circle as illustrated in FIG. 1A and the like. When the top-view shapes of the openings are circles, processing accuracy in forming the openings can be high, whereby the openings can be formed to have minute sizes. In this specification and the like, a circular shape is not necessarily a perfect circular shape.

In this specification and the like, the top-view shape of the opening 141 refers to the shape of the end portion of the top surface of the insulating layer 110 on the opening 141 side. The top-view shape of the opening 143 refers to the shape of the end portion of the bottom surface of the conductive layer 112b on the opening 143 side.

As shown in FIG. 1A and the like, the opening 141 and the opening 143 can have the same or substantially the same top-view shapes. In that case, it is preferable that the end portion of the bottom surface of the conductive layer 112b on the opening 143 side be aligned with or substantially aligned with the end portion of the top surface of the insulating layer 110 on the opening 141 side as illustrated in FIG. 1B, FIG. 1C, and the like. The bottom surface of the conductive layer 112b refers to the surface thereof on the insulating layer 110 side. The top surface of the insulating layer 110 refers to the surface thereof on the conductive layer 112b side. Note that the opening 141 and the opening 143 do not necessarily have the same top-view shapes. In the case where the top-view shapes of the opening 141 and the opening 143 are circular, the opening 141 and the opening 143 may be concentrically arranged, but not necessarily concentrically arranged.

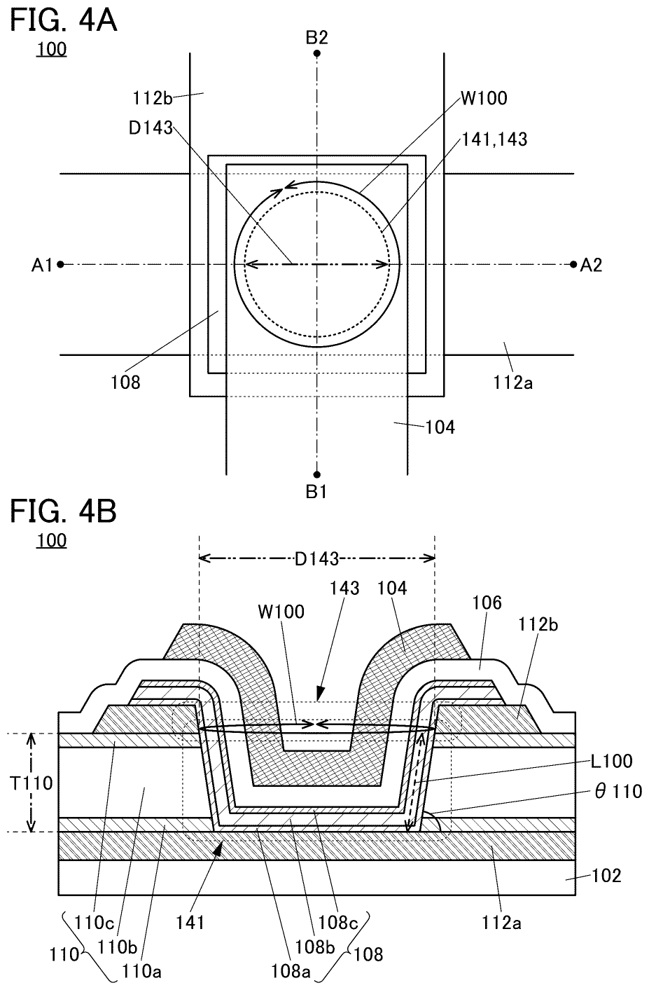

The channel length, channel width, and the like of the transistor 100 are described with reference to FIG. 4A and FIG. 4B. FIG. 4A and FIG. 4B are enlarged views of FIG. 1A and FIG. 1B, respectively.

In the semiconductor layer 108, a region in contact with the conductive layer 112a functions as one of the source region and the drain region, a region in contact with the conductive layer 112b functions as the other of the source region and the drain region, and a region between the source region and the drain region functions as the channel formation region.

The channel length of the transistor 100 is a distance between the source region and the drain region. In FIG. 4B, a channel length L100 of the transistor 100 is indicated by a dashed double-headed arrow. It can be said that in a cross-sectional view, the channel length L100 is the shortest distance between a region of the semiconductor layer 108 that is in contact with the conductive layer 112a and a region of the semiconductor layer 108 that is in contact with the conductive layer 112b.

The channel length L100 of the transistor 100 corresponds to the length of the side surface of the insulating layer 110 on the opening 141 side in a cross-sectional view. In other words, the channel length L100 depends on a thickness T110 of the insulating layer 110 and an angle θ110 formed by the side surface of the insulating layer 110 on the opening 141 side and the formation surface of the insulating layer 110 (here, the top surface of the conductive layer 112a). Thus, the channel length L100 can be a value smaller than that of the resolution limit of a light-exposure apparatus, for example, which enables the transistor to have a minute size. Specifically, a transistor with an extremely short channel length that could not be achieved with a conventional light-exposure apparatus for mass production of flat panel displays (the minimum line width:approximately 2 μm or approximately 1.5 μm, for example) can be achieved. Moreover, it is also possible to obtain a transistor with a channel length shorter than 10 nm without using an extremely expensive light-exposure apparatus used in the latest LSI technology.

The channel length L100 can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 can be greater than or equal to 100 nm and less than or equal to 1 μm.

The reduction in the channel length L100 can increase the on-state current of the transistor 100. With the use of the transistor 100, a circuit capable of high-speed operation can be manufactured. Furthermore, the area occupied by the circuit can be reduced. Therefore, a semiconductor device with a small size can be obtained. The application of the semiconductor device of one embodiment of the present invention to a large display device or a high-resolution display device can reduce signal delay in wirings and reduce display unevenness even if the number of wirings is increased, for example. In addition, since the area occupied by the circuit can be reduced, the bezel of the display device can be narrowed.

By adjusting the thickness T110 and the angle θ110 of the insulating layer 110, the channel length L100 can be controlled. In FIG. 4B, the thickness T110 of the insulating layer 110 is indicated by a dashed-dotted double-headed arrow.

The thickness T110 of the insulating layer 110 can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm.

The side surface of the insulating layer 110 on the opening 141 side preferably has a tapered shape. The angle θ110 formed by the side surface of the insulating layer 110 on the opening 141 side and the formation surface of the insulating layer 110 (here, the top surface of the conductive layer 112a) is preferably smaller than 90°. By reducing the angle θ110, the coverage with a layer (e.g., the semiconductor layer 108) formed over the insulating layer 110 can be improved. The smaller the angle θ110 is, the longer the channel length L100 is. The larger the angle θ110 is, the shorter the channel length L100 is.

The angle θ110 can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, or greater than or equal to 70° and less than 90°, less than or equal to 85°, or less than or equal to 80°. The angle θ110 may be less than or equal to 75°, less than or equal to 70°, less than or equal to 65°, or less than or equal to 60°.

Although FIG. 1B and the like illustrate the structure in which the side surface of the insulating layer 110 on the opening 141 side is linear in the cross-sectional view, one embodiment of the present invention is not limited thereto. In the cross-sectional view, the side surface of the insulating layer 110 on the opening 141 side may be curved, or the side surface may include both a linear region and a curved region. Similarly, the side surface of the conductive layer 112b on the opening 143 side may be curved, or the side surface may include both a linear region and a curved region.

In FIG. 4A and FIG. 4B, a width D143 of the opening 143 is indicated by a dashed double-dotted double-headed arrow. FIG. 4A illustrates an example where the top-view shape of each of the opening 141 and the opening 143 is a circle. In this case, the width D143 corresponds to the diameter of the circle and a channel width W100 of the transistor 100 is the length of the circumference of the circle. That is, the channel width W100 is π×D143. Accordingly, in the case where the opening 141 and the opening 143 have circular top-view shapes, the channel width W100 of the transistor can be smaller than in the case where the opening 141 and the opening 143 have any other shape.

Note that the opening 141 and the opening 143 sometimes have different diameters. The inner diameter of each of the opening 141 and the opening 143 sometimes varies in the depth direction. As the diameter of each of the openings, for example, the average value of the following three diameters can be used: the diameter at the highest level of the insulating layer 110 (or an insulating layer 110b) in a cross-sectional view, the diameter at the lowest level of the insulating layer 110 (or the insulating layer 110b) in a cross-sectional view, and the diameter at the midpoint between these levels. For another example, any of the diameter at the highest level of the insulating layer 110 (or the insulating layer 110b) in a cross-sectional view, the diameter at the lowest level of the insulating layer 110 (or the insulating layer 110b) in a cross-sectional view, and the diameter at the midpoint between these levels can be used as the diameter of each of the openings.

In the case where the opening 143 is formed by a photolithography method, the width D143 of the opening 143 is larger than or equal to the resolution limit of a light-exposure apparatus. The width D143 can be, for example, greater than or equal to 200 nm, greater than or equal to 300 nm, greater than or equal to 400 nm, or greater than or equal to 500 nm and less than 5.0 μm, less than or equal to 4.5 μm, less than or equal to 4.0 μm, less than or equal to 3.5 μm, less than or equal to 3.0 μm, less than or equal to 2.5 μm, less than or equal to 2.0 μm, less than or equal to 1.5 μm, or less than or equal to 1.0 μm.

### [Insulating Layer 110]

The insulating layer 110 may have either a single-layer structure or a stacked-layer structure of two or more layers. The insulating layer 110 preferably include one or more of an inorganic insulating film. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film.

In this specification and the like, an oxynitride refers to a material that contains more oxygen than nitrogen in its composition. A nitride oxide refers to a material that contains more nitrogen than oxygen in its composition.

The insulating layer 110 includes a region in contact with the semiconductor layer 108. In the case where the semiconductor layer 108 is formed using an oxide semiconductor, at least part of the region of the insulating layer 110 that is in contact with the semiconductor layer 108 is preferably formed using one or more of an oxide or oxynitride to improve the characteristics of the interface between the semiconductor layer 108 and the insulating layer 110. Specifically, an oxide or an oxynitride is preferably used for the region of the insulating layer 110 that is in contact with the channel formation region in the semiconductor layer 108.

As the insulating layer 110b in contact with the channel formation region of the semiconductor layer 108, one or more of the oxide insulating film and the oxynitride insulating film described above are preferably used. Specifically, as the insulating layer 110b, one or both of a silicon oxide film and a silicon oxynitride film are preferably used.

It is further preferable that a film from which oxygen is released by heating be used as the insulating layer 110b. When the insulating layer 110b releases oxygen by heat applied during the manufacturing process of the transistor 100, the oxygen can be supplied to the semiconductor layer 108. Supplying oxygen from the insulating layer 110b to the semiconductor layer 108, particularly to the channel formation region in the semiconductor layer 108, can allow the amount of oxygen vacancy to be reduced in the semiconductor layer 108, so that a highly reliable transistor having favorable electrical characteristics can be obtained.

For example, the insulating layer 110b can be supplied with oxygen when heat treatment in an atmosphere including oxygen or plasma treatment in an atmosphere including oxygen is performed. Alternatively, an oxide film may be formed by a sputtering method in an atmosphere including oxygen to supply oxygen to the top surface of the insulating layer 110b. After that, the oxide film may be removed. Embodiment 2 described later shows an example in which oxygen is supplied to the insulating layer 110b by forming a metal oxide layer.

Here, oxygen released from the insulating layer 110b reaches the semiconductor layer 108b through the semiconductor layer 108a. When the thickness T108a of the semiconductor layer 108a is large, the amount of oxygen supplied to the semiconductor layer 108b, which is a main current path, is reduced and the amount of oxygen vacancies in the semiconductor layer 108b is increased in some cases. The thickness T108a of the semiconductor layer 108a is preferably within the above range. Furthermore, the thickness T108a of the semiconductor layer 108a is preferably smaller than the thickness T108b of the semiconductor layer 108b and smaller than the thickness T108c of the semiconductor layer 108c. Accordingly, the amount of oxygen supplied to the semiconductor layer 108b is increased, so that oxygen vacancies in the semiconductor layer 108b can be reduced. Consequently, a transistor with favorable electrical characteristics and high reliability can be obtained. Note that at least the thickness T108a of the semiconductor layer 108a is preferably smaller than the thickness T108b of the semiconductor layer 108b. The thickness T108a of the semiconductor layer 108a may be the same as the thickness T108c of the semiconductor layer 108c or may be larger than the thickness T108c.

The insulating layer 110b is preferably formed by a film formation method such as a sputtering method or a plasma-enhanced chemical vapor deposition (PECVD) method. In particular, a film is formed by a sputtering method as a film formation method that does not use a gas containing hydrogen for a film formation gas, so that a film with an extremely low hydrogen content can be formed. In that case, supply of hydrogen to the semiconductor layer 108 is inhibited and the electrical characteristics of the transistor 100 can be stabilized.

The thickness of the insulating layer 110b can be determined in the above range of the thickness T110 of the insulating layer 110.

For each of an insulating layer 110a and an insulating layer 110c, a film through which oxygen hardly diffuses is preferably used. Accordingly, it is possible to prevent oxygen included in the insulating layer 110b from being transmitted toward the substrate 102 side through the insulating layer 110a and being transmitted toward the insulating layer 106 side through the insulating layer 110c due to heating. In other words, when the insulating layers 110a and 110c through which oxygen hardly diffuses are respectively provided above and below the insulating layer 110b so that the insulating layer 110b is held therebetween, oxygen included in the insulating layer 110b can be enclosed. Accordingly, oxygen can be effectively supplied to the semiconductor layer 108.

For each of the insulating layer 110a and the insulating layer 110c, a film through which hydrogen hardly diffuses is preferably used. In that case, hydrogen can be inhibited from diffusing from outside the transistor to the semiconductor layer 108 through the insulating layer 110a or the insulating layer 110c.

For each of the insulating layer 110a and the insulating layer 110c, any one or more of the oxide insulating film, the nitride insulating film, the oxynitride insulating film, and the nitride oxide insulating film described above are preferably used, and any one or more of the silicon nitride film, the silicon nitride oxide film, the silicon oxynitride film, the aluminum oxide film, the aluminum oxynitride film, the aluminum nitride film, the hafnium oxide film, and the hafnium aluminate film described above are further preferably used. The silicon nitride film and the silicon nitride oxide film can be particularly suitably used for the insulating layer 110a and the insulating layer 110c because the silicon nitride film and the silicon nitride oxide film release fewer impurities (e.g., water and hydrogen) and are less likely to transmit oxygen and hydrogen.

The conductive layer 112a and the conductive layer 112b are oxidized by oxygen included in the insulating layer 110b and have high electric resistance in some cases. Providing the insulating layer 110a between the insulating layer 110b and the conductive layer 112a can inhibit the conductive layer 112a from being oxidized and having high electric resistance. Similarly, providing the insulating layer 110c between the insulating layer 110b and the conductive layer 112b can inhibit the conductive layer 112b from being oxidized and having high electric resistance. Accordingly, the amount of oxygen supplied from the insulating layer 110b to the semiconductor layer 108 is increased, whereby the amount of oxygen vacancy in the semiconductor layer 108 can be reduced.

The thicknesses of the insulating layer 110a and the insulating layer 110c are each preferably larger than or equal to 5 nm and smaller than or equal to 100 nm, further preferably larger than or equal to 5 nm and smaller than or equal to 70 nm, further preferably larger than or equal to 10 nm and smaller than or equal to 70 nm, further preferably larger than or equal to 10 nm and smaller than or equal to 50 nm, further preferably larger than or equal to 20 nm and smaller than or equal to 50 nm, further preferably larger than or equal to 20 nm and smaller than or equal to 40 nm. When the thickness of each of the insulating layer 110a and the insulating layer 110c is in the above-described range, the amount of oxygen vacancies in the semiconductor layer 108, or specifically the channel formation region, can be reduced.

It is preferable that, for example, the insulating layer 110a and the insulating layer 110c be formed using silicon nitride films and the insulating layer 110b be formed using a silicon oxynitride film.

One or both of a region in contact with the insulating layer 110a and a region in contact with the insulating layer 110c in the semiconductor layer 108 may have higher carrier concentration and lower resistance than the channel formation region. A region of the semiconductor layer 108 that is in contact with the insulating layer 110a and a region of the semiconductor layer 108 that is in contact with the insulating layer 110c each function as the source region or the drain region in some cases. In this case, the effective channel length of the transistor 100 is sometimes shorter than the channel length L100 described above.

For example, when a material that releases impurities (e.g., water or hydrogen) is used for the insulating layer 110a, the electrical resistance of a region of the semiconductor layer 108 that is in contact with the insulating layer 110a is reduced in some cases. The region can function as a buffer region that relieves a drain electric field. Note that the region may function as the source region or the drain region. The same applies to the insulating layer 110c.

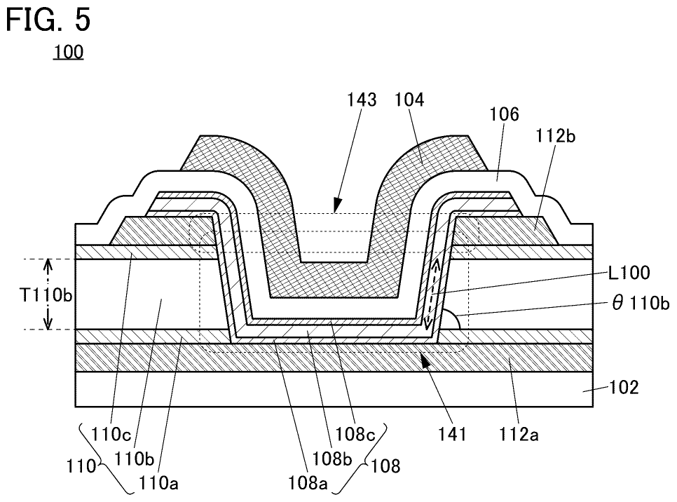

FIG. 5 illustrates a structure in which a region of the semiconductor layer 108 that is in contact with the insulating layer 110b functions as a channel formation region. The channel length L100 of the transistor 100 is determined by a thickness T110b of the insulating layer 110b in contact with the channel formation region and an angle θ110b formed by the side surface of the insulating layer 110b on the opening 141 side and the formation surface (here, the top surface of the insulating layer 110a) in a cross-sectional view. The thickness T110b is preferably within the range of the thickness T110 described above. The angle θ110b is preferably within the range of the angle θ110.

Here, hydrogen diffuses from one or both of the insulating layer 110a and the insulating layer 110c into the region of the semiconductor layer 108 in contact with the insulating layer 110b in some cases. However, supply of oxygen from the insulating layer 110b to the semiconductor layer 108 inhibits an increase in oxygen vacancies (Vo) and VoH in the region of the semiconductor layer 108 in contact with the insulating layer 110b. Thus, at least the region of the semiconductor layer 108 in contact with the insulating layer 110b can function as the channel formation region, and the transistor can have favorable electrical characteristics and high reliability.

Note that in the case where the channel length L100 of the transistor 100 is shortened, the thickness of the insulating layer 110a and the insulating layer 110c are preferably small. For example, in the case where the channel length L100 is less than or equal to 100 nm, the thicknesses of the insulating layer 110a and the insulating layer 110c are each preferably greater than or equal to 1.0 nm and less than or equal to 50 nm, further preferably greater than or equal to 3.0 nm and less than or equal to 50 nm, still further preferably greater than or equal to 3.0 nm and less than or equal to 40 nm, yet still further preferably greater than or equal to 3.0 nm and less than or equal to 30 nm, yet still further preferably greater than or equal to 3.0 nm and less than or equal to 20 nm, yet still further preferably greater than or equal to 3.0 nm and less than or equal to 15 nm, yet still further preferably greater than or equal to 3.0 nm and less than or equal to 10 nm, yet still further preferably greater than or equal to 5.0 nm and less than or equal to 10 nm. Accordingly, the amount of hydrogen diffusing into the region of the semiconductor layer 108 in contact with the insulating layer 110b can be reduced, and the transistor can have favorable electrical characteristics and high reliability even with the short channel length L100.

### [Conductive Layer 112a, Conductive Layer 112b, and Conductive Layer 104]

The conductive layer 112a, the conductive layer 112b, and the conductive layer 104 may each have a single-layer structure or a stacked-layer structure of two or more layers. The conductive layer 112a, the conductive layer 112b, and the conductive layer 104 can each be formed using, for example, one or more of chromium, copper, aluminum, gold, silver, zinc, tantalum, titanium, tungsten, manganese, nickel, iron, cobalt, molybdenum, and niobium, or an alloy containing one or more of these metals as its components. For each of the conductive layer 112a, the conductive layer 112b, and the conductive layer 104, a conductive material with low resistance that contains one or more of copper, silver, gold, and aluminum can be suitably used. Copper or aluminum is particularly preferable because of its high mass-productivity.

For the conductive layer 112a, the conductive layer 112b, and the conductive layer 104, a conductive metal oxide (also referred to as an oxide conductor) can be used. Examples of an oxide conductor (OC) include indium oxide, zinc oxide, In—Sn oxide (ITO), In—Zn oxide, In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. An oxide conductor containing indium is particularly preferable because of its high conductivity.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

Each of the conductive layer 112a, the conductive layer 112b, and the conductive layer 104 may have a stacked-layer structure of a conductive film containing the above-described oxide conductor (the metal oxide) and a conductive film containing a metal or an alloy. The use of the conductive film containing a metal or an alloy can reduce the wiring resistance.

A Cu—X alloy film (X is Mn, Ni, Cr, Fe, Co, Mo, Ta, or Ti) may be used for each of the conductive layer 112a, the conductive layer 112b, and the conductive layer 104. The use of a Cu—X alloy film enables the manufacturing cost to be reduced because a wet etching method can be used in the processing.

Note that all of the conductive layer 112a, the conductive layer 112b, and the conductive layer 104 may be formed using the same material or at least one of them may be formed using a different material.

Each of the conductive layer 112a and the conductive layer 112b has a region that is in contact with the semiconductor layer 108. In the case where the semiconductor layer 108 is formed using an oxide semiconductor, when the conductive layer 112a or the conductive layer 112b is formed using a metal that is likely to be oxidized (e.g., aluminum), an insulating oxide (e.g., aluminum oxide) is formed between the conductive layer 112a or the conductive layer 112b and the semiconductor layer 108, which might prevent electrical continuity between the conductive layer 112a or the conductive layer 112b and the semiconductor layer 108. Thus, a conductive material that is less likely to be oxidized, a conductive material that maintains low electric resistance even after being oxidized, or an oxide conductor is preferably used for the conductive layer 112a and the conductive layer 112b.

For the conductive layer 112a and the conductive layer 112b, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or materials that maintain low electric resistance even when being oxidized. In the case where the conductive layer 112a or the conductive layer 112b has a stacked-layer structure, at least the layer thereof that is in contact with the semiconductor layer 108 is preferably formed using a conductive material that is less likely to be oxidized.

The above-described oxide conductor can be used for each of the conductive layer 112a and the conductive layer 112b. Specifically, an oxide conductor such as indium oxide, zinc oxide, ITO, In—Zn oxide, In—W oxide, In—W—Zn oxide, In—Ti oxide, In—Ti—Sn oxide, In—Sn oxide containing silicon, or zinc oxide to which gallium is added can be used.

For the conductive layer 112a and the conductive layer 112b, a nitride conductor may be used. Examples of the nitride conductor include tantalum nitride and titanium nitride. [Insulating layer 106]

The insulating layer 106 may have a single-layer structure or a stacked-layer structure of two or more layers. The insulating layer 106 preferably includes one or more inorganic insulating films. Examples of the inorganic insulating film include an oxide insulating film, a nitride insulating film, an oxynitride insulating film, and a nitride oxide insulating film. For the insulating layer 106, a material that can be used for the insulating layer 110 can be used.

The insulating layer 106 includes a region in contact with the semiconductor layer 108. In the case where the semiconductor layer 108 is formed using an oxide semiconductor, at least the film of the insulating layer 106 that is in contact with the semiconductor layer 108 is preferably any of the above-described oxide insulating films and oxynitride insulating films. A film from which oxygen is released by heating is further preferably used as the insulating layer 106.

Specifically, in the case where the insulating layer 106 has a single-layer structure, the insulating layer 106 is preferably formed using a silicon oxide film or a silicon oxynitride film.

The insulating layer 106 can have a stacked-layer structure of an oxide insulating film or an oxynitride insulating film on the side that is in contact with the semiconductor layer 108 and a nitride insulating film or a nitride oxide insulating film on the side that is in contact with the conductive layer 104. As the oxide insulating film or the oxynitride insulating film, for example, a silicon oxide film or a silicon oxynitride film is preferably used. As the nitride insulating film or the nitride oxide insulating film, a silicon nitride film or a silicon nitride oxide film is preferably used.

A silicon nitride film and a silicon nitride oxide film can be suitably used as the insulating layer 106 because they release fewer impurities (e.g., water and hydrogen) and less likely to transmit oxygen and hydrogen. Diffusion of impurities from the insulating layer 106 to the semiconductor layer 108 is inhibited, whereby the transistor can have favorable electrical characteristics and high reliability.

A miniaturized transistor including a thin gate insulating layer may have a high leakage current. When a high dielectric constant material (also referred to as a high-k material) is used for the gate insulating layer, the voltage at the time of operation of the transistor can be reduced while the physical thickness is maintained. Examples of the high-k material usable for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

### [Substrate 102]

Although there is no great limitation on a material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. The substrate 102 may be provided with a semiconductor element. The shape of the semiconductor substrate and an insulating substrate may be a circular shape or a shape with corners.

A flexible substrate may be used as the substrate 102, and the transistor 100 and the like may be formed directly on the flexible substrate. Alternatively, a separation layer may be provided between the substrate 102 and the transistor 100 and the like. With the separation layer, part or the whole of a semiconductor device completed thereover can be separated from the substrate 102 and transferred onto another substrate. In that case, the transistor 100 and the like can be transferred onto a substrate having low heat resistance or a flexible substrate as well.

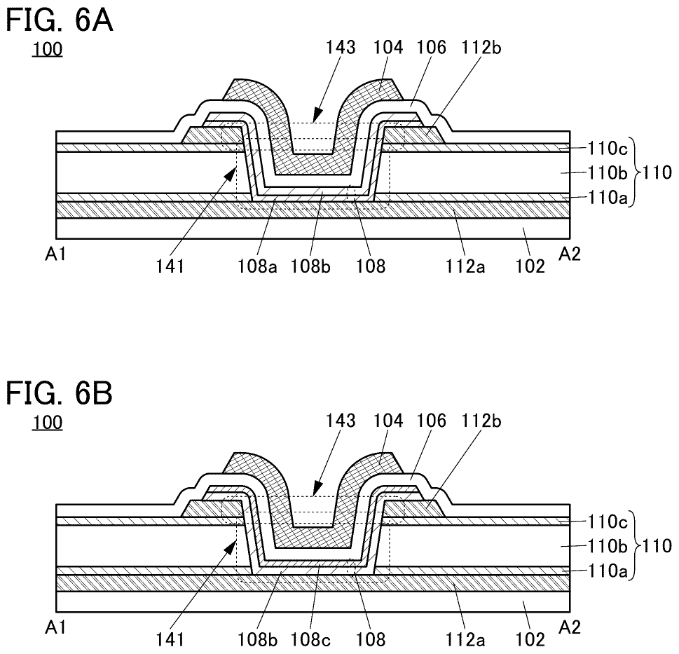

Note that the semiconductor layer 108a may have a stacked-layer structure. The same applies to the semiconductor layer 108b and the semiconductor layer 108c. In addition, although FIG. 1B and the like illustrate an example in which the semiconductor layer 108 has a three-layer structure of the semiconductor layer 108a, the semiconductor layer 108b, and the semiconductor layer 108c, one embodiment of the present invention is not limited thereto. For example, a structure without one or both of the semiconductor layer 108a and the semiconductor layer 108c may be employed. Specifically, as illustrated in FIG. 6A, the semiconductor layer 108 can have a two-layer structure of the semiconductor layer 108a and the semiconductor layer 108b. Alternatively, as illustrated in FIG. 6B, the semiconductor layer 108 can have a two-layer structure of the semiconductor layer 108b and the semiconductor layer 108c.

A structure example which is partly different from that of Structure example 1 shown above will be described below. Note that description of the same portions as those in Structure example 1 shown above is omitted below in some cases. Furthermore, in drawings that are referred to later, the same hatching pattern is applied to portions having functions similar to those in Structure example 1 shown above, and the portions are not denoted by reference numerals in some cases.

### Structure Example 1-2

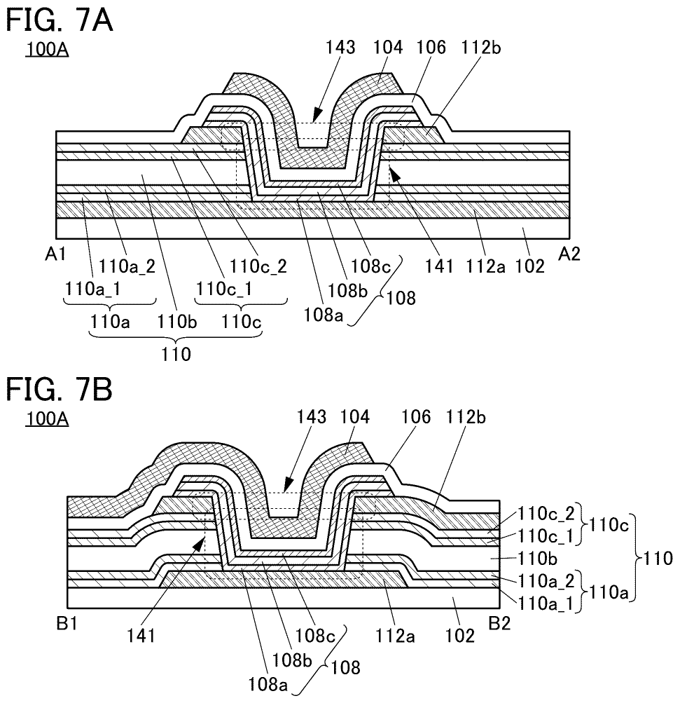

FIG. 7A and FIG. 7B illustrate cross-sectional views of a transistor 100A that can be used in the semiconductor device of one embodiment of the present invention. FIG. 1A can be referred to for a top view of the transistor 100A. FIG. 7A is a cross-sectional view of a cut plane along the dashed-dotted line A1-A2 in FIG. 1A, and FIG. 7B is a cross-sectional view of a cut plane along the dashed-dotted line B1-B2 in FIG. 1A.

The transistor 100A is different from the transistor 100 illustrated in FIG. 1B and the like mainly in that the insulating layer 110a and the insulating layer 110c each have a stacked-layer structure.

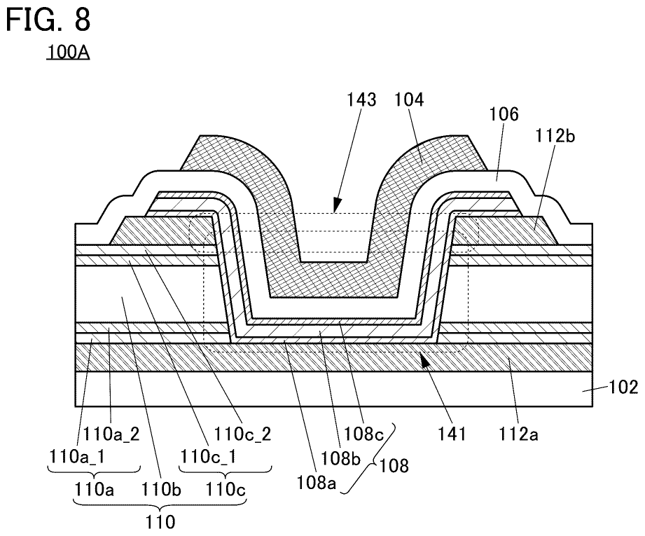

FIG. 8 is an enlarged view of FIG. 7A. The insulating layer 110a preferably includes an insulating layer 110a_1 and an insulating layer 110a_2 over the insulating layer 110a_1. For each of the insulating layer 110a_1 and the insulating layer 110a_2, the material that can be used for the insulating layer 110a can be used. For example, a silicon nitride film or a silicon nitride oxide film can be suitably used for each of the insulating layer 110a_1 and the insulating layer 110a_2.

The insulating layer 110c includes an insulating layer 110c_1 and an insulating layer 110c_2 over the insulating layer 110c_1. For each of the insulating layer 110c_1 and the insulating layer 110c_2, the material that can be used for the insulating layer 110c can be used. For example, a silicon nitride film or a silicon nitride oxide film can be suitably used for each of the insulating layer 110c_1 and the insulating layer 110c_2.

When a material that releases impurities (e.g., water and hydrogen) is used for the insulating layer 110a_1, the region of the semiconductor layer 108 in contact with the insulating layer 110a_1 can be a low-resistance region. In the semiconductor layer 108, the low-resistance region can be formed between the channel formation region and the region in contact with the conductive layer 112a (one of a source region and a drain region). Similarly, when a material that releases impurities is used for the insulating layer 110c_2, the region of the semiconductor layer 108 in contact with the insulating layer 110c_2 can be a low-resistance region. In the semiconductor layer 108, the low-resistance region can be formed between the channel formation region and the region in contact with the conductive layer 112b (the other of the source region and the drain region). The low-resistance region can serve as a buffer region for relieving a drain electric field. These low-resistance regions may function as the source region or the drain region.

The low-resistance region between the drain region and the channel formation region inhibits generation of a high electric field in the vicinity of the drain region, so that generation of hot carriers is inhibited to prevent the degradation of the transistor. For example, in the case where the conductive layer 112a serves as a drain electrode and the conductive layer 112b serves as a source electrode, the region of the semiconductor layer 108 that is in contact with the insulating layer 110a_1 is made to serve as the low-resistance region, so that a high electric field is not easily generated in the vicinity of the drain region, fewer hot carriers are generated, and the transistor are less likely to deteriorate. In the case where the conductive layer 112a serves as the source electrode and the conductive layer 112b serves as the drain electrode, the region of the semiconductor layer 108 that is in contact with the insulating layer 110c_2 is made to serve as the low-resistance region. In such a case, a high electric field is not easily generated in the vicinity of the drain region, fewer hot carriers are generated, and the transistor are less likely to deteriorate.

In the case where the region of the semiconductor layer 108 that is in contact with the insulating layer 110a_1 functions as the source region or the drain region, the shortest distance from the source region to the gate electrode of the semiconductor layer 108 and the shortest distance from the drain region to the gate electrode can be more uniform. Thus, the electric field of the gate electrode applied to the channel formation region can be more uniform.

It is preferable that the insulating layer 110a_2 release a small amount of impurity and be not easily transmits impurities. In that case, an impurity and hydrogen can be inhibited from diffusing into the channel formation region of the semiconductor layer 108 and the vicinity thereof through the insulating layer 110a_2 and the insulating layer 110b, whereby the transistor can have excellent electrical characteristics and high reliability.

The insulating layer 110a_1 preferably includes a region including more hydrogen than the insulating layer 110a_2. The hydrogen content of the insulating layer 110a can be analyzed by secondary ion mass spectrometry (SIMS), for example.

When the film formation conditions for the insulating layer 110a_1 and the insulating layer 110a_2 are different from each other, the amount of released hydrogen can be adjusted. Specifically, the film formation conditions for the insulating layer 110a_1 and the insulating layer 110a_2 are different from each other in any one or more of a film formation power (film formation power density), a film formation pressure, the kind of a film formation gas, the flow rate ratio of a film formation gas, a film formation temperature, and the distance between the substrate and an electrode during formation. For example, the film formation power density for the insulating layer 110a_1 may be lower than that for the insulating layer 110a_2, in which case the insulating layer 110a_1 can have a higher hydrogen content than the insulating layer 110a_2. Accordingly, the amount of hydrogen released from the insulating layer 110a_1 due to heat applied thereto can be increased.

The film formation gas used for the formation of the insulating layer 110a_1 preferably includes more hydrogen than the film formation gas used for the formation of the insulating layer 110a_2. Specifically, when a silicon nitride film or a silicon nitride oxide film is formed as each of the insulating layer 110a_1 and the insulating layer 110a_2 by using a PECVD method, the proportion of a flow rate of an ammonia gas to the whole film formation gas used for forming the insulating layer 110a_1 (hereinafter also referred to as ammonia flow rate ratio) is preferably higher than the proportion of a flow rate of an ammonia gas to the whole film formation gas used for forming the insulating layer 110a_2. The formation of the insulating layer 110a_1 under the condition where the ammonia flow rate ratio is high can increase the hydrogen content in the insulating layer 110a_1. Furthermore, the amount of hydrogen released from the insulating layer 110a_1 due to heat applied thereto can be increased. The insulating layer 110a_1 can be formed using an ammonia gas, and the insulating layer 110a_2 can be formed not using an ammonia gas (the flow rate of the ammonia gas can be regarded as zero). In that case, the ammonia flow rate ratio of the film formation gas used for the formation of the insulating layer 110a_2 can be regarded as zero, and the ammonia flow rate ratio of the film formation gas used for the formation of the insulating layer 110a_1 can be regarded as higher than the ammonia flow rate ratio of the film formation gas used for the formation of the insulating layer 110a_2.

The film density of the insulating layer 110a_2 is preferably higher than that of the insulating layer 110a_1. In that case, hydrogen contained in the insulating layer 110a_1 can be inhibited from diffusing into the channel formation region of the semiconductor layer 108 and the vicinity thereof through the insulating layer 110a_2 and the insulating layer 110b. The film density can be evaluated by Rutherford backscattering spectrometry (RBS) or X-ray reflection (XRR), for example. A difference in film density can be evaluated using a transmission electron microscopy (TEM) image of a cross section in some cases. In TEM observation, a transmission electron (TE) image is dark-colored (dark) when the film density is high, and a transmission electron (TE) image is pale (bright) when the film density is low. Thus, the transmission electron (TE) image of the insulating layer 110a_2 is a dark-colored (dark) image compared to the insulating layer 110a_1 in some cases. Note that since the insulating layer 110a_1 and the insulating layer 110a_2 have different film densities even when including the same materials, it is sometimes possible to identify the boundary between the insulating layer 110a_1 and the insulating layer 110a_2 by a difference in contrast in a TEM image of a cross section.

It is preferable that the amount of impurities released from the insulating layer 110c_1 itself be small and the impurities be less likely to pass through the insulating layer 110c_1. This inhibits impurities from diffusing into the channel formation region of the semiconductor layer 108 and the vicinity thereof through the insulating layer 110c_1 and the insulating layer 110b, whereby the transistor can have excellent electrical characteristics and high reliability. The film density of the insulating layer 110c_1 is preferably higher than that of the insulating layer 110c_2. For the insulating layer 110c_1, the description of the insulating layer 110a_2 can be referred to. Note that although an example where the insulating layer 110 has a five-layer structure is described here, one embodiment of the present invention is not limited to this. The insulating layer 110 may have a single-layer structure or a stacked-layer structure of two, three, four, six or more layers.

The structures of the insulating layer 110a and the insulating layer 110c described in Structure example 1-2 can also be applied to other structure examples.

### Structure Example 1-3

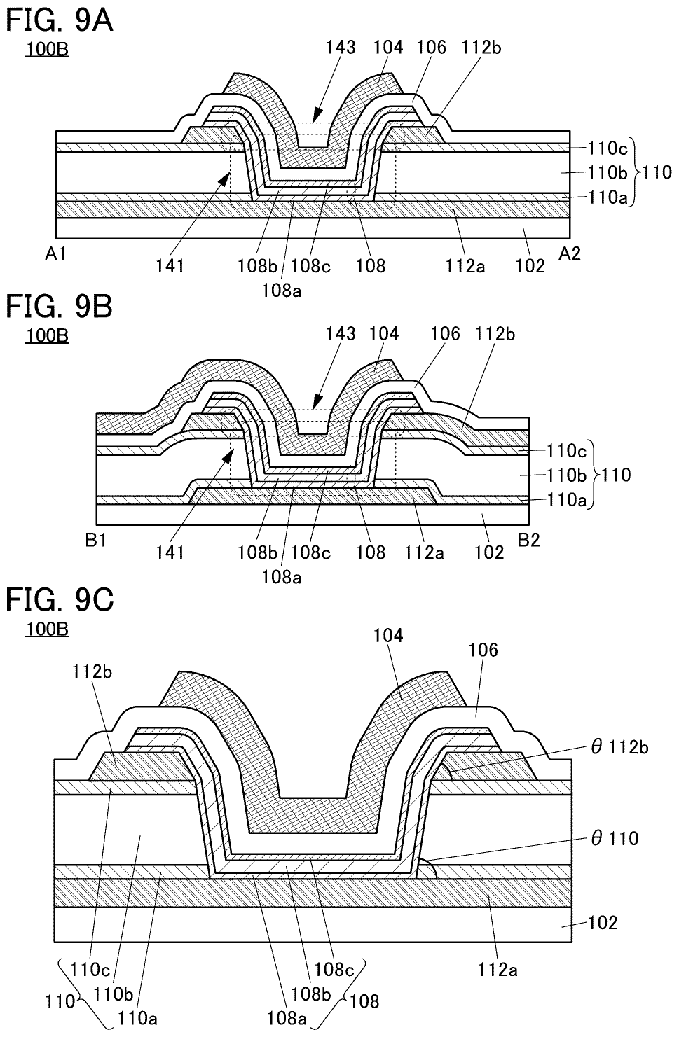

FIG. 9A and FIG. 9B illustrate cross-sectional views of a transistor 100B that can be used in the semiconductor device of one embodiment of the present invention. FIG. 1A can be referred to for a top view of the transistor 100B. FIG. 9A is a cross-sectional view of a cut plane along the dashed-dotted line A1-A2 in FIG. 1A, and FIG. 9B is a cross-sectional view of a cut plane along the dashed-dotted line B1-B2 in FIG. 1A.

The transistor 100B is different from the transistor 100 illustrated in FIG. 1B and the like mainly in that the angle formed by the side surface of the conductive layer 112b on the opening 143 side and the formation surface of the conductive layer 112b (here, the top surface of the insulating layer 110) is different from the angle formed by the side surface of the insulating layer 110 on the opening 141 side and the formation surface of the insulating layer 110 (here, the top surface of the conductive layer 112a).

FIG. 9C is an enlarged view of FIG. 9A. As illustrated in FIG. 9C, an angle θ112b formed by the side surface of the conductive layer 112b on the opening 143 side and the formation surface of the conductive layer 112b (here, the top surface of the insulating layer 110) is preferably smaller than the angle θ110 in the cross-sectional view. When the angle θ112b is smaller than the angle θ110, a step of the formation surface of the layer (e.g., the semiconductor layer 108) formed over the conductive layer 112b and the insulating layer 110 is small, so that coverage with the layer can be improved. This can inhibit generation of a defect such as step disconnection or a void in the layer.

For example, by employing different methods for formation of the opening 141 and the opening 143, the angle θ112b of the conductive layer 112b and the angle θ110 of the insulating layer 110 can be made different from each other. For example, when a wet etching method is used for the formation of the opening 143 and a dry etching method is used for the formation of the opening 141, the angle θ112b can be made smaller than the angle θ110.

The structures of the insulating layer 110 and the conductive layer 112b described in Structure example 1-3 can be applied to other structure examples.

### Structure Example 1-4

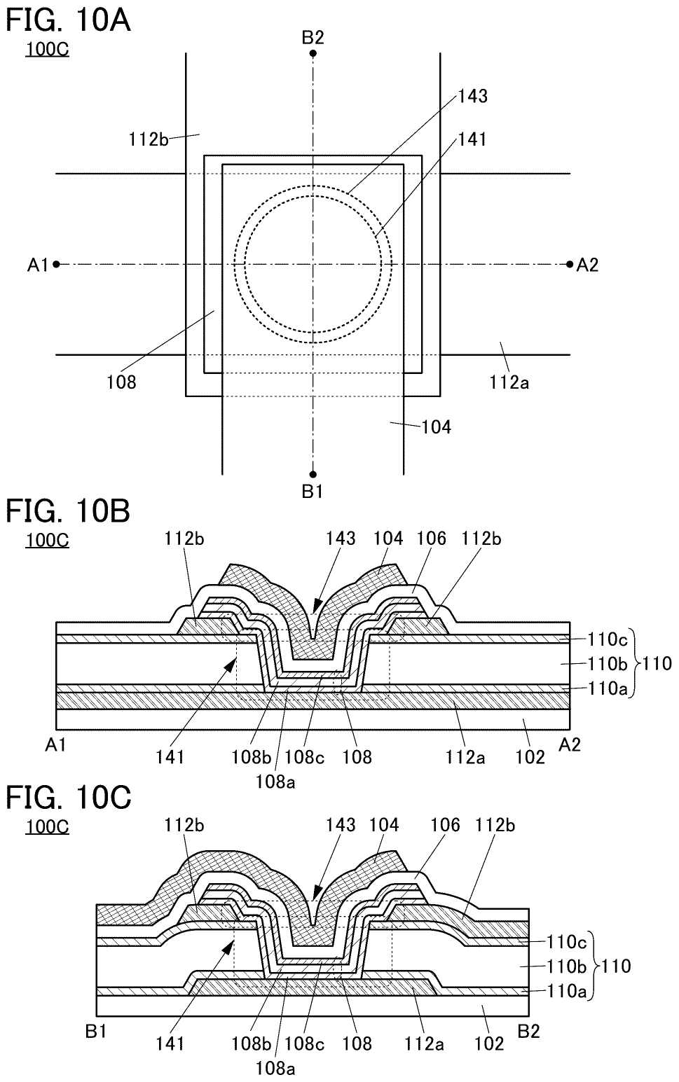

FIG. 10A illustrates a top view of a transistor 100C that can be used in the semiconductor device of one embodiment of the present invention. FIG. 10B is a cross-sectional view of a cut plane along the dashed-dotted line A1-A2 in FIG. 10A and FIG. 10C is a cross-sectional view of a cut plane along the dashed-dotted line B1-B2.

The transistor 100C is different from the transistor 100 illustrated in FIG. 1B and the like mainly in that the top-view shape of the opening 143 does not match with the top-view shape of the opening 141.

As illustrated in FIG. 10A, in the top view, the opening 143 preferably covers the opening 141 completely. As illustrated in FIG. 10B and FIG. 10C, the insulating layer 110 preferably includes a region projecting from the conductive layer 112b on the opening 141 side in the cross-sectional view. With such a structure, a step on the formation surface of a layer (e.g., the semiconductor layer 108) formed over the conductive layer 112b and the insulating layer 110 is reduced, so that coverage with the layer can be improved. This can inhibit generation of a defect such as step disconnection or a void in the layer.

The semiconductor layer 108 includes a region in contact with the top surface and the side surface of the conductive layer 112b, the top surface and the side surface of the insulating layer 110, and the top surface of the conductive layer 112a. The semiconductor layer 108 has a shape along the shapes of the top surface and the side surface of the conductive layer 112b, the top surface and the side surface of the insulating layer 110, and the top surface of the conductive layer 112a.

Note that in the case where the top-view shapes of the opening 141 and the opening 143 are circular, the opening 141 and the opening 143 may be concentrically arranged, but not necessarily concentrically arranged.

The structures of the opening 141 and the opening 143 described in Structure example 1-4 can also be used in the other structure examples.

### Structure Example 1-5

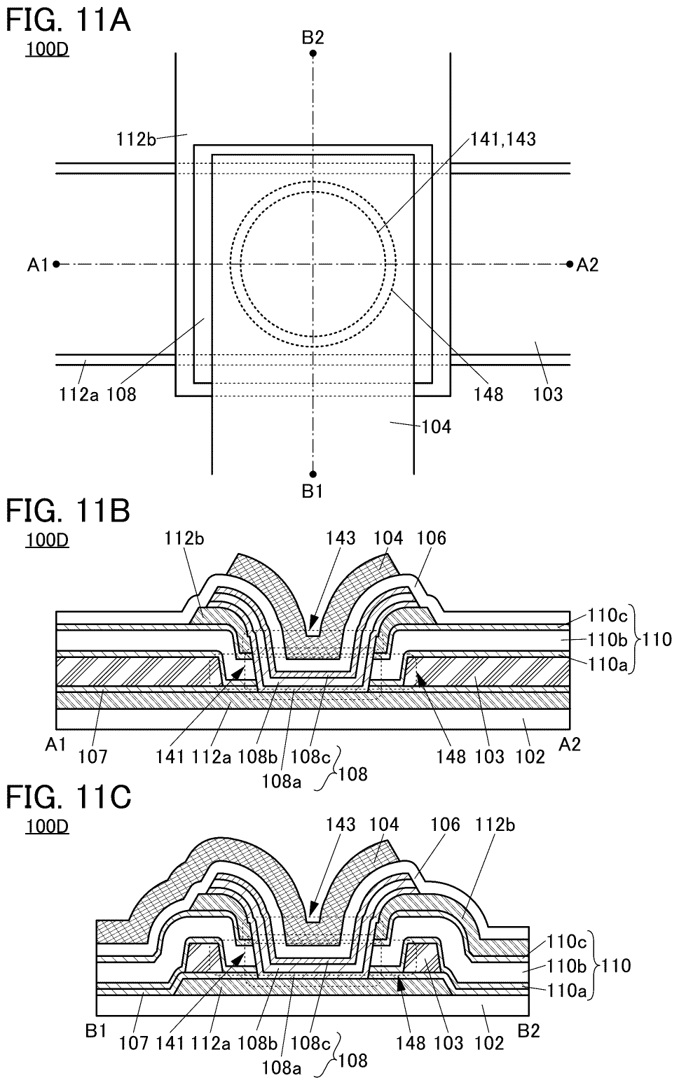

FIG. 11A is a top view of a transistor 100D that can be used in the semiconductor device of one embodiment of the present invention. FIG. 11B is a cross-sectional view of a cut plane along the dashed-dotted line A1-A2 in FIG. 11A and FIG. 11C is a cross-sectional view of a cut plane along the dashed-dotted line B1-B2.

The transistor 100D is different from the transistor 100 illustrated in FIG. 1B and the like mainly in that a conductive layer 103 and an insulating layer 107 are included.

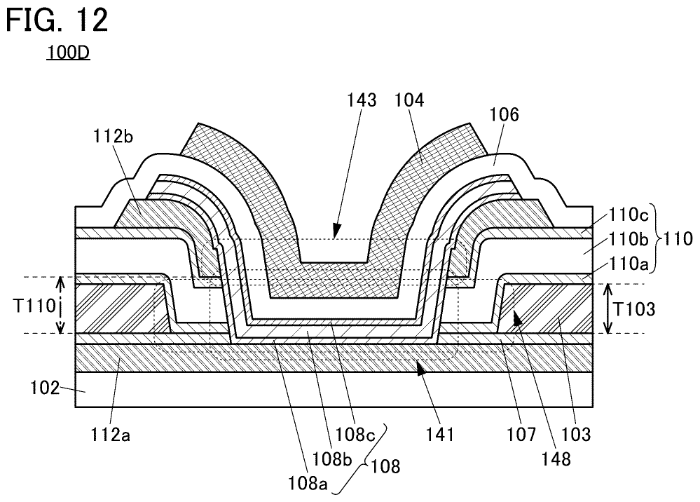

FIG. 12 is an enlarged view of FIG. 11B. As illustrated in FIG. 12, the transistor 100D includes the conductive layer 103 and the insulating layer 107 between the conductive layer 112a and the insulating layer 110.

The insulating layer 107 is positioned over the conductive layer 112a. The insulating layer 107 is provided so as to cover the top surface and the side surface of the conductive layer 112a.

The conductive layer 103 is positioned over the insulating layer 107. The conductive layer 112a and the conductive layer 103 are electrically insulated from each other by the insulating layer 107. In the conductive layer 103, an opening 148 reaching the insulating layer 107 is provided in a region overlapping with the conductive layer 112a.

The insulating layer 110 is provided over the insulating layer 107 and the conductive layer 103. The insulating layer 110 is provided so as to cover the top surface and the side surface of the conductive layer 103 and the top surface of the insulating layer 107. The opening 141 reaching the conductive layer 112a is provided in the insulating layer 110 and the insulating layer 107.

The insulating layer 110a is positioned over the insulating layer 107 and the conductive layer 103. The insulating layer 110a is provided to cover the top surface and the side surface of the conductive layer 103. In addition, the insulating layer 110a is provided to cover part of the opening 148. The insulating layer 110a is in contact with the insulating layer 107 through the opening 148.

There is no particular limitation on the top-view shape of the opening 148. As the top-view shape of the opening 148, the shapes that can be used for the openings 141 and 143 can be employed. The top-view shapes of the opening 141, the opening 143, and the opening 148 are preferably circular as illustrated in FIG. 11A. When the top-view shapes of the openings are circular, processing accuracy in forming the openings can be high, whereby the openings can be formed to have minute sizes.

In this specification and the like, the top-view shape of the opening 148 refers to the shape of the end portion of the top surface or the bottom surface of the conductive layer 103 on the opening 148 side.

When the top-view shape of each of the opening 141 and the opening 148 is circular, the opening 141 and the opening 148 are preferably concentrically arranged. In that case, the shortest distances between the semiconductor layer 108 and the conductive layer 103 on the left and right sides of the opening 141 can be the same in the cross-sectional view. The opening 141 and the opening 148 are not concentrically arranged in some cases.

In the transistor 100D, the semiconductor layer 108 has a region overlapping with the conductive layer 104 with the insulating layer 106 therebetween and overlapping with the conductive layer 103 with part of the insulating layer 110 (specifically, the insulating layer 110a and the insulating layer 110b) therebetween. In other words, the semiconductor layer 108 has a region interposed between the conductive layer 104 and the conductive layer 103 with the insulating layer 106 positioned between the region and the conductive layer 104 and with part of the insulating layer 110 (e.g., the insulating layer 110a and the insulating layer 110b) positioned between the region and the conductive layer 103.

The conductive layer 103 can function as a back gate electrode (also referred to as a second gate electrode) of the transistor 100D. Part of the insulating layer 110 functions as a back gate insulating layer (also referred to as a second gate insulating layer) of the transistor 100D. The conductive layer 103 can be formed using a material that can be used for the conductive layer 112a, the conductive layer 112b, and the conductive layer 104. In addition, the conductive layer 103 is not necessarily provided.

Since the back gate electrode is provided with the transistor 100D, the potential of the back channel side of the semiconductor layer 108 can be fixed, so that the saturation of the Id-Vd characteristics of the transistor 100D can be improved.

In this specification and the like, the state where the change in current is small in the saturation region of the Id-Vd characteristics of a transistor is sometimes described using the expression “favorable saturation”.

Since the transistor 100D includes the back gate electrode, the potential of the back channel side of the semiconductor layer 108 can be fixed and a shift of the threshold voltage can be inhibited. A shift in the threshold voltage of the transistor might increase the drain current flowing at a gate voltage of 0 V (hereinafter, also referred to as cut-off current). When the threshold voltage shift is inhibited, the cut-off current of the transistor can be reduced. Thus, a semiconductor device with low power consumption can be obtained.

For the insulating layer 107, a material that can be used for the insulating layer 110 can be used. An insulating layer containing nitrogen is preferably used as the insulating layer 107 in contact with the conductive layer 112a and the conductive layer 103. For the insulating layer 107, a material that can be used for the insulating layer 110a and the insulating layer 110c can be suitably used. For example, silicon nitride can be suitably used for the insulating layer 107. Although the insulating layer 107 has a single-layer structure in this embodiment, one embodiment of the present invention is not limited thereto. The insulating layer 107 may have a stacked-layer structure of two or more layers.

The conductive layer 103 and the conductive layer 112a may be electrically connected to each other. For example, when an opening is provided in a region of the insulating layer 107 which overlaps with the conductive layer 112a and the conductive layer 103 is provided to cover the opening, the conductive layer 103 and the conductive layer 112a can be in contact with each other. When the conductive layer 112a functioning as a source electrode or a drain electrode and the conductive layer 103 functioning as the back gate electrode are electrically connected to each other, the gate electrode can have the same potential as the source electrode or the drain electrode. For example, in the case where the conductive layer 112a functions as the source electrode, a shift in the threshold voltage of the transistor 100D can be inhibited. In addition, the reliability of the transistor 100D can be improved. Note that the conductive layer 103 may be formed in contact with the top surface of the conductive layer 112a without providing the insulating layer 107.

The conductive layer 103 and the conductive layer 112b may be electrically connected to each other. For example, when an opening is provided in a region of the insulating layer 110 which overlaps with the conductive layer 103 and the conductive layer 112b is provided to cover the opening, the conductive layer 103 and the conductive layer 112b can be in contact with each other.

The conductive layer 103 may be electrically connected to the conductive layer 104. For example, when an opening is provided in a region of the insulating layer 106 and the insulating layer 110 which overlaps with the conductive layer 103 and the conductive layer 104 is provided to cover the opening, the conductive layer 103 and the conductive layer 104 can be in contact with each other. When the conductive layer 104 functioning as the gate electrode and the conductive layer 103 functioning as the back gate electrode are electrically connected to each other, the back gate electrode and the gate electrode can have the same potential, so that the on-state current of the transistor 100D can be increased.

A thickness T103 of the conductive layer 103 may be larger than the thickness T110 of the insulating layer 110. Accordingly, the potential of the back channel side of the semiconductor layer 108 can be fixed in a wide range between a source region and a drain region of the semiconductor layer 108.

In a region of the transistor 100D, the conductive layer 103, the insulating layer 110, the semiconductor layer 108, the insulating layer 106, and the conductive layer 104 are stacked in this order in one direction with no any other layer provided between these layers. The direction can be perpendicular to the channel length direction. When the above region is wide, the potential applied to the back channel side of the semiconductor layer 108 can be controlled more reliably.

The thickness T103 of the conductive layer 103 can be larger than the sum of the thickness of a portion of the semiconductor layer 108 in contact with the conductive layer 112a inside the opening 141 and the thickness of the insulating layer 106 in contact with the portion.

The structure of the conductive layer 103 and the insulating layer 107 described in Structure example 1-5 can also be applied to other structure examples.

### Structure Example 2

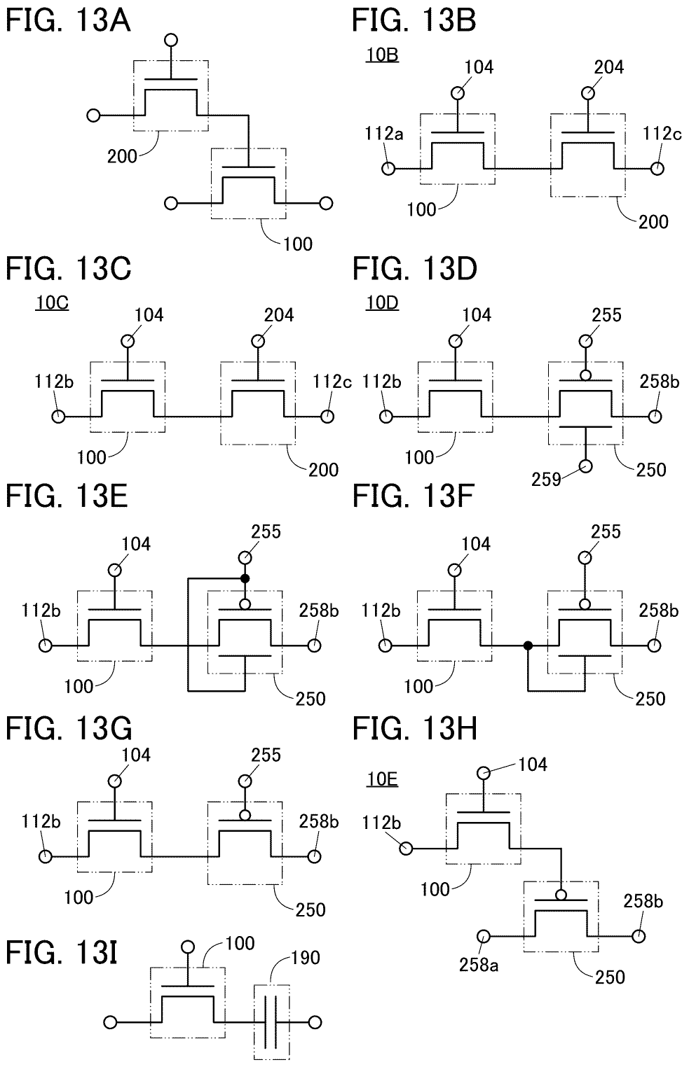

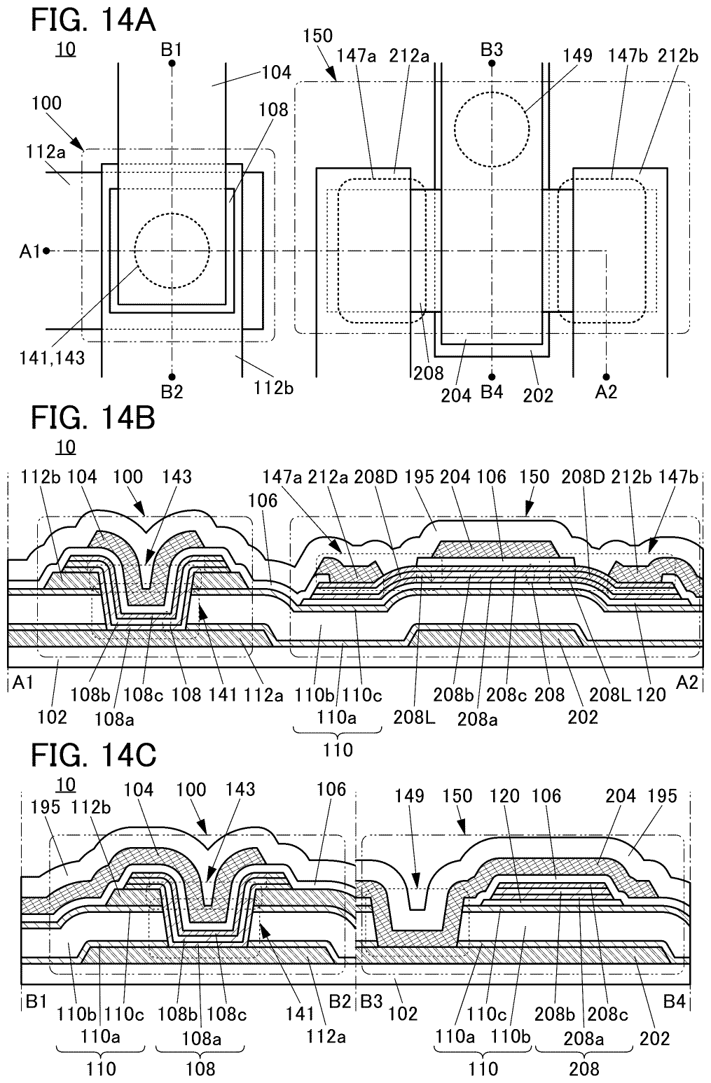

FIG. 13A to FIG. 13I are circuit diagrams of the semiconductor device of one embodiment of the present invention. FIG. 14 to FIG. 19 show top views and cross-sectional views of the semiconductor device of one embodiments of the present invention. In the following description, the transistor 100 is used as an example of a transistor included in the semiconductor device of one embodiment of the present invention. The semiconductor device of one embodiment of the present invention may include any one or more of the transistor 100 to the transistor 100D described above, instead of the transistor 100.

The semiconductor device of one embodiment of the present invention includes at least two transistors in which any of a gate, a source, and a drain of one transistor is electrically connected to any of a gate, a source, and a drain of another transistor.

For example, the semiconductor device in FIG. 13A includes the transistor 100 and a transistor 200. One of a source and a drain of the transistor 200 is electrically connected to a gate of the transistor 100.

Although the transistor 100 and the transistor 200 are shown as n-channel transistors in FIG. 13A to FIG. 13C, one embodiment of the present invention is not limited thereto. One or both of the transistor 100 and the transistor 200 may be a p-channel transistor(s).

[Structure example 2-1]

FIG. 14A is a top view of a semiconductor device 10 of one embodiment of the present invention. FIG. 14B is a cross-sectional view of a cut plane along the dashed-dotted line A1-A2 in FIG. 14A, and FIG. 14C is a cross-sectional view of cut planes along the dashed-dotted line B1-B2 and the dashed-dotted line B3-B4 in FIG. 14A.

The semiconductor device 10 includes the transistor 100 and a transistor 150. In the semiconductor device 10, any of the gate, a source, and a drain of the transistor 100 can be electrically connected to any of a gate, a source, and a drain of the transistor 150. In FIG. 14A to FIG. 14C, the electrical connection between the transistor 100 and the transistor 150 is omitted.

The transistor 100 and the transistor 200 are provided over the substrate 102.

The above description can be referred to for the transistor 100; thus, the detailed description thereof is omitted.

The transistor 150 includes a conductive layer 202, the insulating layer 110, an insulating layer 120, a semiconductor layer 208, the insulating layer 106, a conductive layer 204, a conductive layer 212a, and a conductive layer 212b. The layers included in the transistor 150 may each have a single-layer structure or a stacked-layer structure.

The conductive layer 202 is provided over the substrate 102. The conductive layer 202 functions as a back gate electrode of the transistor 150. The conductive layer 202 can be formed using the same material as the conductive layer 112a included in the transistor 100. The conductive layer 202 can be formed in the same step as the conductive layer 112a. For example, a film to be the conductive layer 112a and the conductive layer 202 is formed and then processed, whereby the conductive layer 112a and the conductive layer 202 can be formed. In addition, the transistor 150 does not necessarily include the back gate electrode.

The insulating layer 110 is provided to cover the conductive layer 202, and the insulating layer 120 is provided over the insulating layer 110. The insulating layer 110 and the insulating layer 120 function as a back gate insulating layer of the transistor 150. The insulating layer 120 is a layer in contact with a channel formation region of the semiconductor layer 208 and thus is preferably an insulating layer containing oxygen. The insulating layer 120 can be formed using a material suitable for the insulating layer 110b, for example.

The semiconductor layer 208 is provided over the insulating layer 120. The semiconductor layer 208 includes a region overlapping with the conductive layer 202 with the insulating layer 110 and the insulating layer 120 therebetween. The semiconductor layer 208 can be formed using the same material as the semiconductor layer 108. The semiconductor layer 208 can be formed in the same step as the semiconductor layer 108.

FIG. 14B and FIG. 14C each illustrate a structure in which the semiconductor layer 208 has a stacked-layer structure of a semiconductor layer 208a, a semiconductor layer 208b over the semiconductor layer 208a, and a semiconductor layer 208c over the semiconductor layer 208b. For example, a film to be the semiconductor layer 108 and the semiconductor layer 208 is formed and then processed, whereby the semiconductor layer 108 and the semiconductor layer 208 can be formed. The semiconductor layer 208a can be formed using the same material as the semiconductor layer 108a. The semiconductor layer 208b can be formed using the same material as the semiconductor layer 108b. The semiconductor layer 208c can be formed using the same material as the semiconductor layer 108c.

The insulating layer 106 is provided to cover the insulating layer 120 and the semiconductor layer 208. The insulating layer 106 functions as a gate insulating layer of the transistor 150. The insulating layer 106 includes an opening 147a and an opening 147b reaching the semiconductor layer 208.

The conductive layer 204, the conductive layer 212a, and the conductive layer 212b are provided over the insulating layer 106. The conductive layer 204, the conductive layer 212a, and the conductive layer 212b can include the same material as the conductive layer 104. The conductive layer 204, the conductive layer 212a, and the conductive layer 212b can be formed in the same step as the conductive layer 104. For example, a film to be the conductive layer 104, the conductive layer 204, the conductive layer 212a, and the conductive layer 212b is formed and then processed, whereby the conductive layer 104, the conductive layer 204, the conductive layer 212a, and the conductive layer 212b can be formed.

The conductive layer 212a and the conductive layer 212b are provided to cover part of the opening 147a and part of the opening 147b, respectively. The conductive layer 212a is electrically connected to the semiconductor layer 208 through the opening 147a. The conductive layer 212b is electrically connected to the semiconductor layer 208 through the opening 147b. The conductive layer 212a functions as one of a source electrode and a drain electrode of the transistor 150 and the conductive layer 212b functions as the other of the source and the drain of the transistor 150.

The conductive layer 204 includes a region overlapping with the semiconductor layer 208 with the insulating layer 106 therebetween. The conductive layer 204 functions as a gate electrode of the transistor 150.

As illustrated in FIG. 14C, the conductive layer 204 may be electrically connected to the conductive layer 202. In that case, the conductive layer 204 and the conductive layer 202 can be supplied with the same potential. When the same potential is applied to the conductive layer 204 and the conductive layer 202, the amount of current that can flow in the transistor 200 in an on state can be increased. The conductive layer 204 can be in contact with the conductive layer 202 through an opening 149 provided in the insulating layer 106, the insulating layer 120, and the insulating layer 110.

The conductive layer 212a or the conductive layer 212b may be electrically connected to the conductive layer 202. The same potential is supplied to the source and the back gate, whereby the potential of the back channel can be stabilized and the saturation in the Id-Vd characteristics of the transistor can be improved. The conductive layer 212a or the conductive layer 212b can be in contact with the conductive layer 202 through an opening provided in the insulating layer 106 and the insulating layer 110.

A structure may be employed in which the conductive layer 202 is not electrically connected to any of the conductive layer 204, the conductive layer 212a, and the conductive layer 212b. For example, a constant potential can be supplied to the back gate and a signal for driving the transistor 150 can be supplied to the gate. Accordingly, the potential supplied to the back gate enables control of the threshold voltage at the time of driving the transistor 150.

In the semiconductor layer 208 between the source electrode and the drain electrode, the whole region overlapping with the gate electrode with the gate insulating layer therebetween functions as a channel formation region. The semiconductor layer 208 includes a pair of regions 208L between which a channel formation region is sandwiched and a pair of regions 208D outside the pair of regions 208L.

The region 208D can also be referred to as a region having a higher carrier concentration or a region having a lower resistance than the channel formation region, or an n-type region. In the semiconductor layer 208, a region in contact with the conductive layer 212a and the region 208D adjacent to the region serve as one of a source region and a drain region. In the semiconductor layer 208, a region in contact with the conductive layer 212b and the region 208D adjacent to the region serve as the other of the source region and the drain region.

The region 208L can be referred to as a region whose electric resistance is substantially equal to or lower than that of the channel formation region, a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region. Moreover, the region 208L can be referred to as a region whose electric resistance is substantially equal to or higher than the resistance of the region 208D, a region whose carrier concentration is substantially equal to or lower than the carrier concentration of the region 208D, a region whose oxygen vacancy density is substantially equal to or lower than the oxygen vacancy density of the region 208D, or a region whose impurity concentration is substantially equal to or lower than the impurity concentration of the region 208D.

The region 208L functions as a buffer region that relieves a drain electric field. The region 208L is a region not overlapping with the conductive layer 204 and thus is a region where a channel is hardly formed by application of gate voltage to the conductive layer 204. The region 208L preferably has a higher carrier concentration than the channel formation region. Thus, the region 208L can function as an LDD (Lightly Doped Drain) region. The region 208L serving as the LDD region is provided between the channel formation region and the region 208D, whereby the transistor 150 can have a high drain breakdown voltage.

For example, after the conductive layer 204, the conductive layer 212a, and the conductive layer 212b are formed, an impurity element is added to the semiconductor layer 208 using these conductive layers as masks, whereby the region 208L and the region 208D can be formed. The region 208L is a region of the semiconductor layer 208 that overlaps with the insulating layer 106 and does not overlap with the conductive layer 204. The region 208D is a region of the semiconductor layer 208 that overlaps with neither the insulating layer 106 nor the conductive layer 204.

As illustrated in FIG. 14A and FIG. 14B, end portions of parts of the conductive layer 212a and the conductive layer 212b are preferably positioned in the opening 147a and the opening 147b, respectively. In other words, the end portions of parts of the conductive layer 212a and the conductive layer 212b are preferably in contact with the semiconductor layer 208 in the opening 147a and the opening 147b, respectively. Accordingly, the region in contact with the conductive layer 212a can be adjacent to one of the pair of regions 208D and the region in contact with the conductive layer 212b can be adjacent to the other of the pair of regions 208D. There is no limitation on the top-view shapes of the opening 147a and the opening 147b.

The region 208L and the region 208D include an impurity element. Examples of the impurity element contain one or more of hydrogen, boron, carbon, nitrogen, fluorine, phosphorus, sulfur, arsenic, aluminum, magnesium, silicon, and a noble gas. Typical examples of a noble gas include helium, neon, argon, krypton, and xenon. It is particularly preferable to use one or more of boron, phosphorus, aluminum, magnesium, and silicon as the impurity element.

When the region 208L and the region 208D are formed by adding an impurity element to the semiconductor layer 208, the impurity element may be supplied to the semiconductor layer 108 through the insulating layer 106 with use of the conductive layer 104 as a mask. Consequently, a region including the impurity element is formed in the region of the semiconductor layer 108 not overlapping with the conductive layer 104. Here, in the transistor 100, a region of the semiconductor layer 108 in contact with the conductive layer 112b serves as the source region or the drain region. Thus, the region including the impurity element is formed in part of the source region or the drain region.

The transistor 150 is what is called a top-gate transistor including the gate electrode above the semiconductor layer 208. For example, an impurity element is added to the semiconductor layer 208 with the conductive layer 204 serving as a gate electrode used as a mask, so that the source region and the drain region can be formed in a self-aligned manner. The transistor 150 can be referred to as a TGSA (Top Gate Self-Aligned) transistor.

The channel length of the transistor 150 can be controlled by the width of the conductive layer 204 in the channel length direction. Accordingly, the channel length of the transistor 150 is greater than or equal to the resolution limit of a light exposure apparatus used for manufacturing the transistor. The transistor with a long channel length can have favorable saturation.

An insulating layer 195 is provided over the transistor 100 and the transistor 150. The insulating layer 195 functions as a protective layer. The insulating layer 195 is preferably formed using a material that does not easily allow diffusion of impurities. Providing the insulating layer 195 can effectively inhibit diffusion of impurities into the transistors from the outside and increase the reliability of the semiconductor device. Examples of the impurities include water and hydrogen. The insulating layer 195 includes, for example, one or both of an inorganic insulating layer and an organic insulating layer. The insulating layer 195 may have a stacked-layer structure of an inorganic insulating layer and an organic insulating layer.

Examples of the inorganic insulating film usable for the insulating layer 195 include an oxide insulating film, a nitride insulating film, an oxynitride insulating film, and a nitride oxide insulating film. Specific examples of these inorganic insulating films are as listed in the description of the insulating layer 110. Specifically, the insulating layer 195 can be formed using one or more of silicon nitride, silicon nitride oxide, silicon oxynitride, aluminum oxide, aluminum oxynitride, aluminum nitride, hafnium oxide, and hafnium aluminate. One or both of an acrylic resin and a polyimide resin, which are organic materials, can be used for the insulating layer 195.

In manufacturing of the semiconductor device 10, the transistor 100 with a short channel length and the transistor 150 with a long channel length can be formed over the same substrate by the formation steps some of which are shared. For example, the transistor 100 is used as the transistor required to have a high on-state current and the transistor 150 is used as the transistor required to have favorable saturation, thereby providing a high-performance semiconductor device.

Although the conductive layer 212a and the conductive layer 212b are formed in the same process as the conductive layer 104 and the conductive layer 204 here, one embodiment of the present invention is not limited thereto. For example, the conductive layer 212a and the conductive layer 212b may be formed after the insulating layer 195 is formed. Specifically, the structure in which the conductive layer 212a and the conductive layer 212b are electrically connected to the semiconductor layer 208 may be formed as follows: after the insulating layer 195 is provided to cover the conductive layer 104 and the conductive layer 204, an opening is provided in the insulating layer 195 and the insulating layer 106; then, the conductive layer 212a and the conductive layer 212b are provided to cover the opening.

### Structure Example 2-2

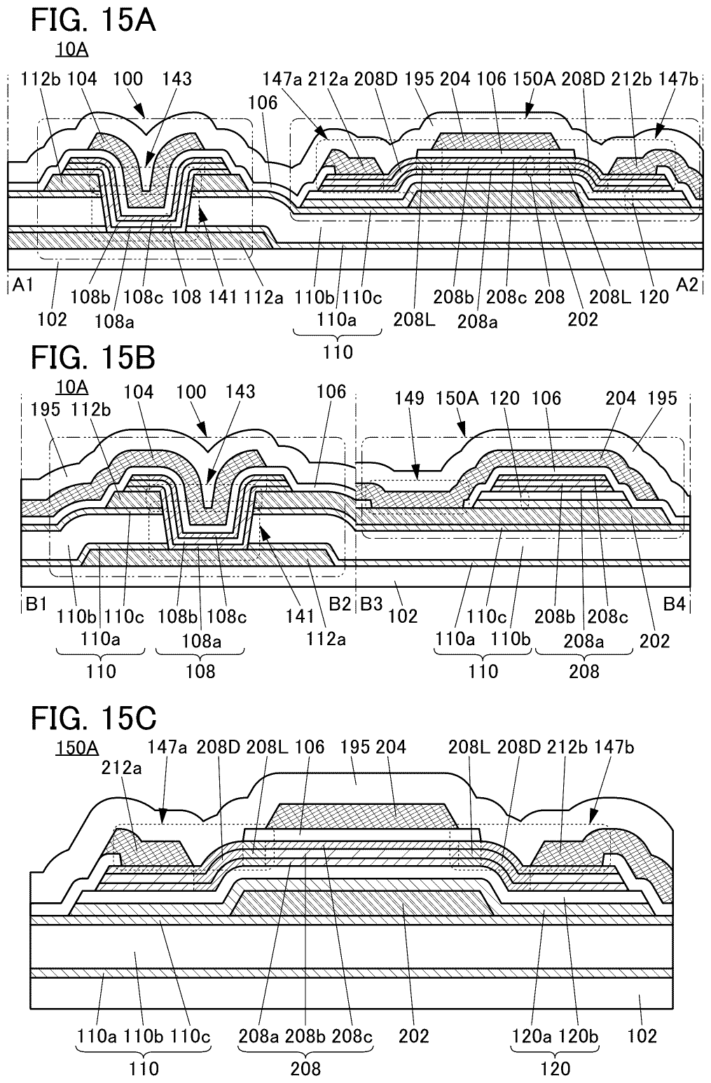

A cross-sectional view of a semiconductor device 10A that is one embodiment of the present invention is illustrated in FIG. 15A and FIG. 15B. FIG. 14A can be referred to for a top view of the semiconductor device 10A. FIG. 15A is a cross-sectional view of a cut plane along the dashed-dotted line A1-A2 in FIG. 14A, and FIG. 15B is a cross-sectional view of a cut plane along the dashed-dotted line B1-B2 in FIG. 14A.

The semiconductor device 10A includes the transistor 100 and a transistor 150A. The transistor 150A is different from the transistor 150 illustrated in FIG. 14B and the like mainly in that the conductive layer 202 is provided between the insulating layer 110 and the insulating layer 120.

FIG. 15C is an enlarged view of FIG. 15A. The conductive layer 202 is provided over the insulating layer 110. The conductive layer 202 can be formed using the same material as the conductive layer 112b. The conductive layer 202 can be formed in the same step as the conductive layer 112b.

The insulating layer 120 is provided over the conductive layer 202. The insulating layer 120 is provided so as to cover a top surface and a side surface of part of the conductive layer 202. In the transistor 150A, part of the insulating layer 120 functions as the back gate insulating layer. When the conductive layer 202 is provided between the insulating layer 110 and the insulating layer 120, the thickness of the back gate insulating layer of the transistor 150A can be reduced. Thus, the electric field of the back gate electrode can be intensified. In addition, the saturation of the I_{d}-V_{d} characteristics of the transistor 150A can be improved. Furthermore, a shift in the threshold voltage can be inhibited, so that the transistor can have a low cut-off current.

The insulating layer 120 preferably has a stacked-layer structure. FIG. 15A and the like illustrate an example in which the insulating layer 120 has a stacked-layer structure of an insulating layer 120a and an insulating layer 120b over the insulating layer 120a.

For the insulating layer 120a provided in contact with the conductive layer 202, a material that does not easily allow diffusion of a metal element included in the conductive layer 202 is preferably used. This inhibits the metal element contained in the conductive layer 202 from being diffused into the channel formation region of the semiconductor layer 208 and the vicinity thereof. For the insulating layer 120a, a material that can be used for the insulating layer 110a and the insulating layer 110c can be suitably used. For the insulating layer 120a, a silicon nitride can be suitably used, for example.

As the insulating layer 120b, which includes a region in contact with the channel formation region of the semiconductor layer 208, an insulating layer containing oxygen is preferably used. For the insulating layer 120b, a material that can be suitably used for the insulating layer 110b can be used. For example, silicon oxynitride can be suitably used for the insulating layer 120b.

The above description can be referred to for the transistor 100; thus, the detailed description thereof is omitted.

### Structure Example 2-3

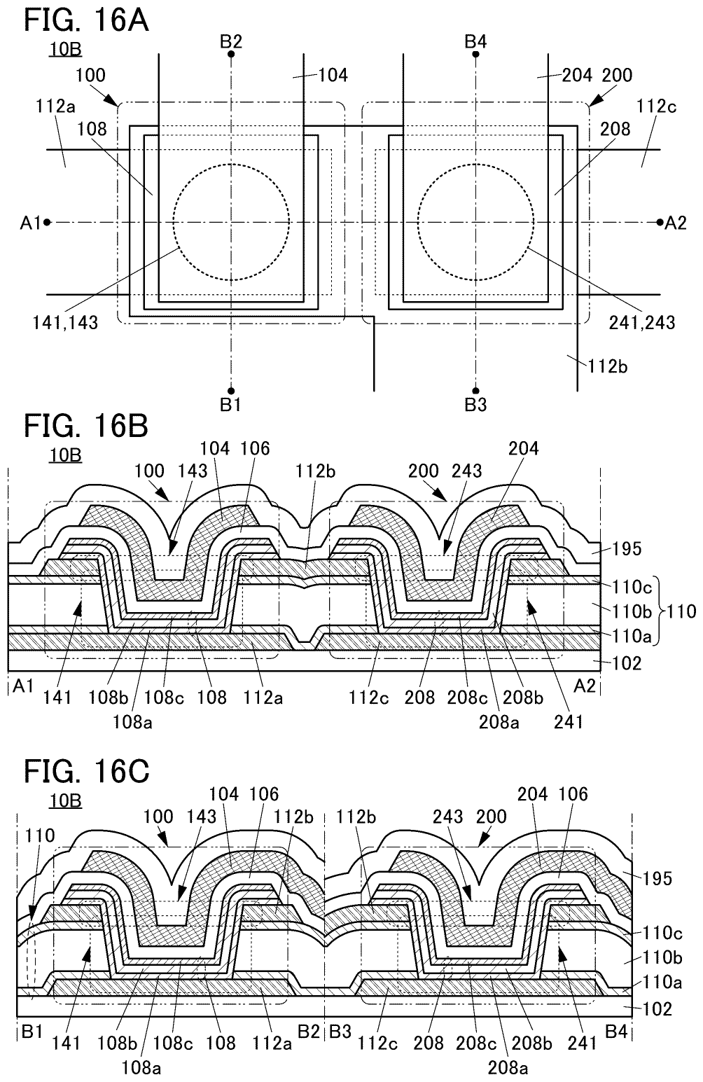

FIG. 13B is a circuit diagram of a semiconductor device 10B of one embodiment of the present invention. FIG. 16A is a top view of the semiconductor device 10B. FIG. 16B is a cross-sectional view of a cut plane along the dashed-dotted line A1-A2 in FIG. 16A, and FIG. 16C is a cross-sectional view of cut planes along the dashed-dotted line B1-B2 and the dashed-dotted line B3-B4 in FIG. 16A.

The semiconductor device 10B includes the transistor 100 and the transistor 200. The other of a source and a drain of the transistor 200 is electrically connected to the other of the source and the drain of the transistor 100.

The transistor 100 and the transistor 200 are provided over the substrate 102.

The above description can be referred to for the transistor 100; thus, the detailed description thereof is omitted.

The transistor 200 includes the conductive layer 112b, a conductive layer 112c, the semiconductor layer 208, the insulating layer 106, and the conductive layer 204. The transistor 200 can have a structure similar to that of the transistor 100.

The conductor 112c functions as one of a source electrode and a drain electrode of the transistor 200. The conductive layer 112b functions as the other of the source electrode and the drain electrode of the transistor 100 and also functions as the other of the source electrode and the drain electrode of the transistor 200. Since the transistor 100 and the transistor 200 share the conductive layer 112b, the semiconductor device occupies a smaller area. Part of the insulating layer 106 functions as a gate insulating layer of the transistor 200. The conductive layer 204 functions as a gate electrode of the transistor 200.

For the conductive layer 112c, the same material as the conductive layer 112a can be used. The conductive layer 112c can be formed in the same step as the conductive layer 112a. The insulating layer 110 has an opening 241 reaching the conductive layer 112c. The opening 241 can be formed in the same step as the opening 141. The conductive layer 112b has an opening 243 in a region overlapping with the opening 241. The opening 243 can be formed in the same step as the opening 143. Although the top-view shapes of the opening 241 and the top-view shapes of the opening 243 are not limited, the shapes are preferably circular. Although the top-view shape of the opening 241 and the top-view shape of the opening 243 are the same here, one embodiment of the present invention is not limited thereto. The opening 241 and the opening 243 do not necessarily have the same top-view shapes.

The width of the opening 143 may be different from the width of the opening 243. When the openings have different widths, two transistors with different channel widths can be manufactured.

The semiconductor layer 208 is provided to cover the opening 241 and the opening 243. The semiconductor layer 208 can be formed in the same step as the semiconductor layer 108. The insulating layer 106 is provided over the semiconductor layer 208, and the conductive layer 204 is provided over the insulating layer 106. The conductive layer 204 can be formed in the same step as the conductive layer 104.

### Structure Example 2-4

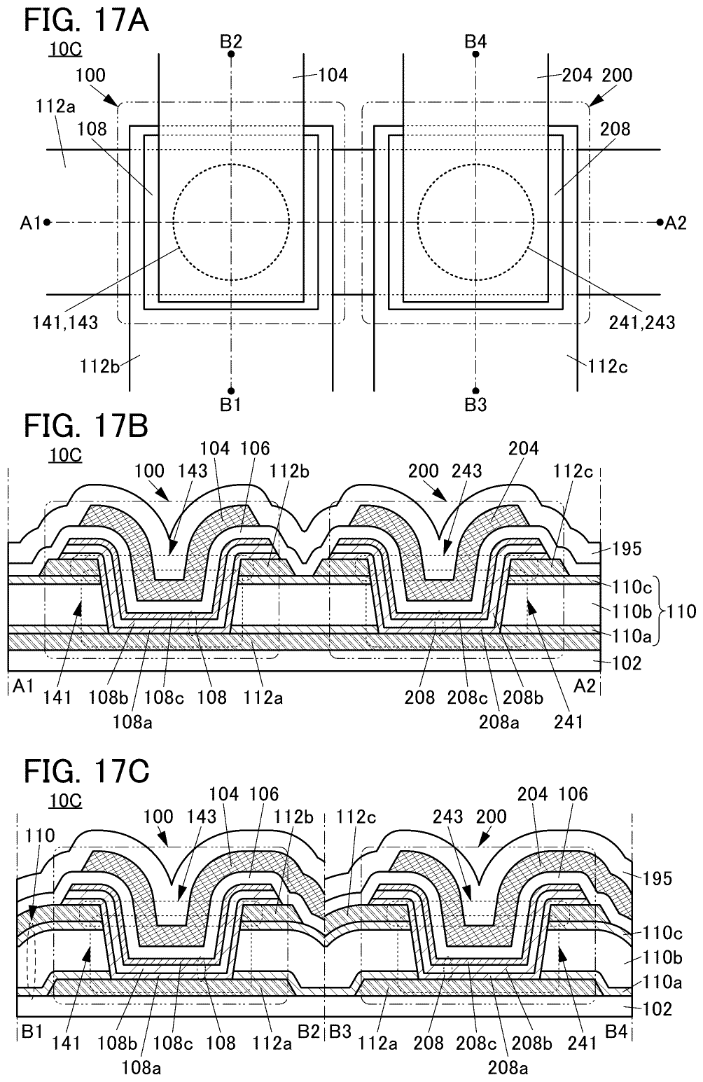

FIG. 13C is a circuit diagram of a semiconductor device 10C of one embodiment of the present invention. FIG. 17A is a top view of the semiconductor device 10C. FIG. 17B is a cross-sectional view of a cut plane along the dashed-dotted line A1-A2 in FIG. 17A, and FIG. 17C is a cross-sectional view of cut planes along the dashed-dotted line B1-B2 and the dashed-dotted line B3-B4 in FIG. 17A.

The semiconductor device 10C includes the transistor 100 and the transistor 200. One of the source and the drain of the transistor 200 is electrically connected to one of the source and the drain of the transistor 100.

The transistor 100 and the transistor 200 are provided over the substrate 102.

The above description can be referred to for the transistor 100; thus, the detailed description thereof is omitted.

The transistor 200 includes the conductive layer 112a, the conductive layer 112c, the semiconductor layer 208, the insulating layer 106, and the conductive layer 204.

The conductive layer 112c functions as the one of the source electrode and the drain electrode of the transistor 200. The conductive layer 112a functions as the one of the source electrode and the drain electrode of the transistor 100 and also functions as the other of the source electrode and the drain electrode of the transistor 200. Since the transistor 100 and the transistor 200 share the conductive layer 112a, the semiconductor device occupies a smaller area.

For the conductive layer 112c, the same material as the conductive layer 112b can be used. The conductive layer 112c can be formed in the same step as the conductive layer 112b.

### Structure Example 2-5

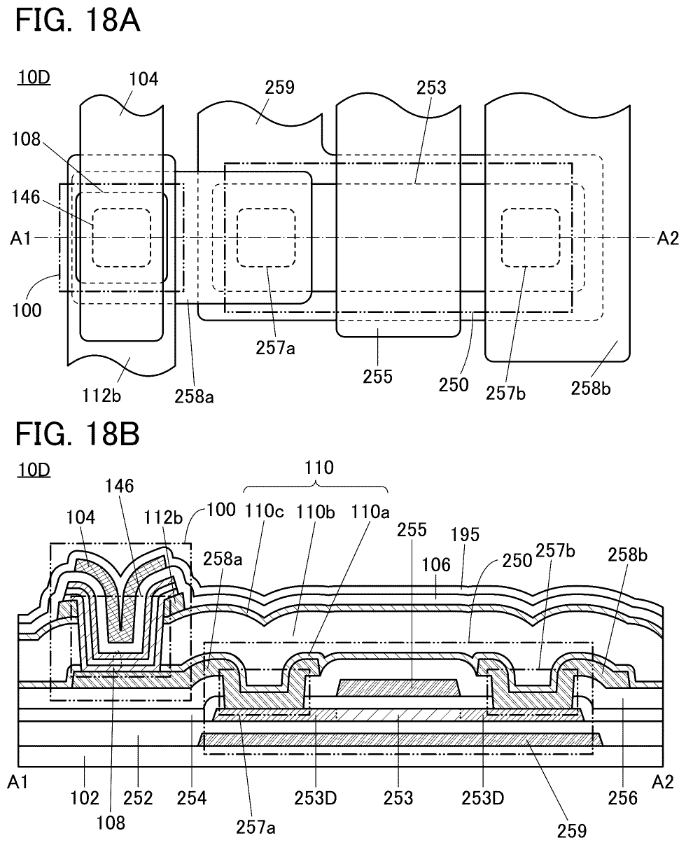

FIG. 13D is a circuit diagram of a semiconductor device 10D of one embodiment of the present invention. FIG. 18A is a top view of the semiconductor device 10D. FIG. 18B is a cross-sectional view of a cut plane along the dashed-dotted line A1-A2 in FIG. 18A.

The semiconductor device 10D includes the transistor 100 and a transistor 250. One of a source and a drain of the transistor 250 is electrically connected to the one of the source and the drain of the transistor 100.

Although the transistor 100 is shown as an n-channel transistor and the transistor 250 is shown as a p-channel transistor in FIG. 13D to FIG. 13H, one embodiment of the present invention is not limited to these examples. Both the transistor 100 and the transistor 250 may be n-channel transistors or p-channel transistors. Alternatively, the transistor 100 may be a p-channel transistor and the transistor 250 may be an n-channel transistor.

The transistor 100 and the transistor 250 are provided over the substrate 102.

The semiconductor device 10D includes a conductive layer 259 over the substrate 102, an insulating layer 252 over the substrate 102 and the conductive layer 259, and a semiconductor layer 253 over the insulating layer 252. The semiconductor device 10D also includes an insulating layer 254 over the insulating layer 252 and the semiconductor layer 253 and a conductive layer 255 over the insulating layer 254. The semiconductor layer 253 and the conductive layer 255 overlap with each other in a region. The conductive layer 259 functions as a back gate electrode of the transistor 250, and the insulating layer 252 functions as a back gate insulating layer. The insulating layer 254 functions as a gate insulating layer, and the conductive layer 255 functions as a gate electrode.

Furthermore, an insulating layer 256 is provided over the insulating layer 254 and the conductive layer 255. The insulating layer 254 and the insulating layer 256 are provided with an opening 257a in a region overlapping with part of the semiconductor layer 253. The insulating layer 254 and the insulating layer 256 are provided with an opening 257b in a region overlapping with another part of the semiconductor layer 253.

A conductive layer 258a is provided over the insulating layer 256 and the opening 257a and a conductive layer 258b is provided over the insulating layer 256 and the opening 257b. The conductive layer 258a is electrically connected to the semiconductor layer 253 in the opening 257a. The conductive layer 258b is electrically connected to the semiconductor layer 253 in the opening 257b.

The region of the semiconductor layer 253 that overlaps with the conductive layer 255 functions as a channel formation region. The semiconductor layer 253 includes a pair of regions 253D between which the channel formation region is sandwiched. One of the pair of regions 253D functions as one of a source region and a drain region and is electrically connected to the conductive layer 258a. The other of the pair of regions 253D functions as the other of the source region and the drain region and is electrically connected to the conductive layer 258b.

The insulating layer 110 is provided over the insulating layer 256, the conductive layer 258a, and the conductive layer 258b, and the conductive layer 112b is provided over the insulating layer 110.

The conductive layer 112b and the insulating layer 110 have an opening 146 in a region overlapping with part of the conductive layer 258a (FIG. 18A). The semiconductor layer 108 is provided to cover the opening 146.

The insulating layer 106 is provided over the insulating layer 110, the conductive layer 112b, and the semiconductor layer 108, and the conductive layer 104 is provided over the insulating layer 106. The insulating layer 195 is provided over the insulating layer 106 and the conductive layer 104.

It is thus preferable that the conductive layer 259 overlap with the channel formation region and extend beyond the end portion of the channel formation region. That is, the conductive layer 259 is preferably larger than the channel formation region. The conductive layer 259 preferably extends beyond the end portion of the semiconductor layer 253. That is, the conductive layer 259 is preferably larger than the semiconductor layer 253.

The gate electrode and the back gate electrode are placed so that a channel formation region of the semiconductor layer is sandwiched therebetween. By changing the potential of the back gate electrode, the threshold voltage of a transistor can be changed. The potential of the back gate electrode may be a ground potential or a given potential.

The back gate electrode can be formed using a material and a method similar to those used for the gate electrode, a source electrode, a drain electrode, or the like. The gate electrode and the back gate electrode are conductive layers and thus each have a function of preventing an electric field generated outside the transistor from affecting the semiconductor layer in which the channel is formed (in particular, an electric field blocking function against static electricity). That is, a variation in the electrical characteristics of the transistor due to the influence of an external electric field such as static electricity can be prevented. By providing the back gate electrode, the amount of change in threshold voltage of the transistor in a BT (Bias Temperature) stress test can be reduced. By providing the back gate electrode, the variation in the characteristics of the transistor can be reduced and the reliability of a semiconductor device can be increased. As shown in FIG. 13E, a back gate and a gate of the transistor 250 may be electrically connected to each other. As shown in FIG. 13F, the back gate of the transistor 250 and the source or the drain thereof may be electrically connected to each other. As shown in FIG. 13G, the transistor 250 may not include the back gate.

Like the transistor 100, the transistor 250 may be an OS transistor.

Here, the semiconductor layer 108 and the semiconductor layer 253 may be formed using the same material or different materials. For the structures of the semiconductor layer 108 and the semiconductor layer 253, the description of the semiconductor layer 108 and the semiconductor layer 208 of the semiconductor device 10 can be referred to.

A transistor including silicon in its channel formation region (hereinafter also referred to as a Si transistor) may be used as the transistor 250.

Examples of silicon include single crystal silicon, polycrystalline silicon, and amorphous silicon. In particular, a transistor including LTPS in a semiconductor layer (hereinafter also referred to as an LTPS transistor) can be used. The LTPS transistor has high field-effect mobility and favorable frequency characteristics.

The structure of the transistor 100 is the same as the above-described structure (see FIG. 1) except that the conductive layer 258a is provided instead of the conductive layer 112a.

The conductive layer 258a functions as the one of the source electrode and the drain electrode of the transistor 100 and also functions as one of the source electrode and the drain electrode of the transistor 250. Since the transistor 100 and the transistor 250 share the conductive layer 258a, the semiconductor device occupies a smaller area.

As described above, the transistor 100 is a vertical channel-type transistor. Meanwhile, in the semiconductor layer of the transistor 250, a current flows in the horizontal direction, i.e., the direction parallel or substantially parallel to a surface of the substrate 102. Such a transistor can be called a lateral channel-type transistor.

As described above, a semiconductor device of one embodiment of the present invention may include not only a vertical channel-type transistor but also a lateral channel-type transistor.

Note that the transistor 100 may be formed in a region overlapping with the opening 257a. Specifically, the opening 146 can be provided in a region overlapping with the opening 257a, and the conductive layer 258a and the semiconductor layer 108 can be in contact with each other in the opening 257a. Furthermore, a structure may be employed in which the conductive layer 258a is not provided and the region 253D and the semiconductor layer 108 are in contact with each other in the opening 257a. With such a structure, a semiconductor device that occupies a smaller area can be obtained.

### Structure Example 2-6

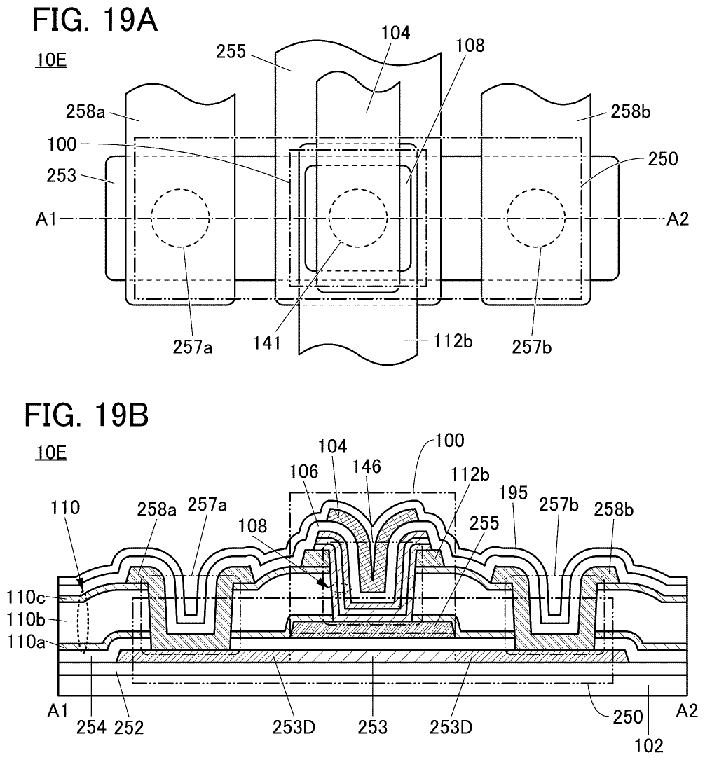

FIG. 13H is a circuit diagram of a semiconductor device 10E of one embodiment of the present invention. FIG. 19A is a top view of the semiconductor device 10E. FIG. 19B is a cross-sectional view of a cut plane along the dashed-dotted line A1-A2 in FIG. 19A.

The semiconductor device 10E includes the transistor 100 and the transistor 250. The gate of the transistor 250 is electrically connected to the one of the source and the drain of the transistor 100.

The semiconductor device 10E is different from the semiconductor device 10D mainly in that the opening 146 overlaps with the conductive layer 255 functioning as the gate electrode of the transistor 250. Accordingly, in the semiconductor device 10D, the transistor 100 is provided over the gate electrode of the transistor 250.

Although the opening 146 overlaps with the channel formation region in FIG. 19A and FIG. 19B, one embodiment of the present invention is not limited to this example. A structure may be employed in which the opening 146 does not overlap with the channel formation region but overlaps with the conductive layer 255. In the semiconductor device 10E, the conductive layer 255 functions as the gate electrode of the transistor 250 and the one of the source electrode and the drain electrode of the transistor 100.

When the transistor 100 and the transistor 250 overlap with each other, the semiconductor device that occupies a smaller area can be obtained.

The semiconductor device 10E is different from the semiconductor device 10D in the structures of the opening 257a, the opening 257b, the conductive layer 258a, and the conductive layer 258b.

The opening 257a and the opening 257b is formed by selectively removing part of the insulating layer 254 and part of the insulating layer 110 in a region overlapping with the region 253D of the semiconductor layer 253. The conductive layer 258a and the conductive layer 258b are provided over the insulating layer 110 and electrically connected to the region 253D through the opening 257a and the opening 257b, respectively.

In the semiconductor device 10E, the conductive layer 258a and the conductive layer 258b can be formed in the same step as the conductive layer 112b. Formation processes of the conductive layers 258a and 258b and the conductive layer 112b are not necessarily separate; thus, the manufacturing process of the semiconductor device can be shortened and the productivity of the semiconductor device can be increased.

The semiconductor device of one embodiment of the present invention includes at least one transistor and at least one capacitor, and a source and a drain of the transistor are electrically connected to one of a pair of electrodes of the capacitor. In FIG. 131, the source or the drain of the transistor 100 is electrically connected to one electrode of a capacitor 190.

In the transistor of one embodiment of the present invention, which is a kind of vertical transistor, a source electrode, a semiconductor layer, and a drain electrode can be provided to overlap with each other; thus, the area occupied by the transistor can be significantly small compared to the area occupied by a planar transistor. Furthermore, combination of a planar p-channel Si transistor and a vertical n-channel OS transistor makes it possible to form a CMOS (complementary metal oxide semiconductor) circuit. When the planar transistor and the vertical transistor overlap with each other in this structure, the CMOS circuit occupies a smaller area.

### Structure Example 2-7

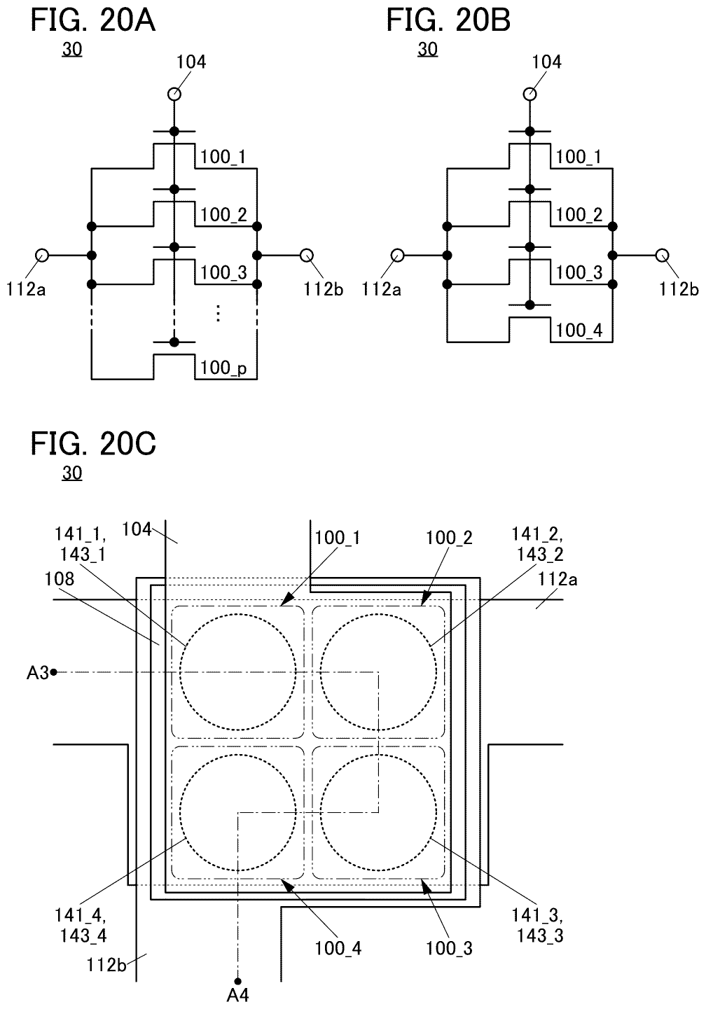

FIG. 20A is an equivalent circuit diagram of a semiconductor device 30 of one embodiment of the present invention. The semiconductor device 30 includes a transistor 100_1 to a transistor 100_p (p is an integer greater than or equal to 2). The semiconductor device 30 can be regarded as one transistor, in which the transistor 100_1 to the transistor 100_p are connected in parallel.

Gate electrodes of the transistor 100_1 to the transistor 100_p are electrically connected to each other. Source electrodes of the transistor 100_1 to the transistor 100_p are electrically connected to each other. Drain electrodes of the transistor 100_1 to the transistor 100_p are electrically connected to each other.

Although the transistor 100_1 to the transistor 100_p are shown as n-channel transistors in FIG. 20A, one embodiment of the present invention is not limited thereto. The transistor 100_1 to the transistor 100_p may be p-channel transistors.

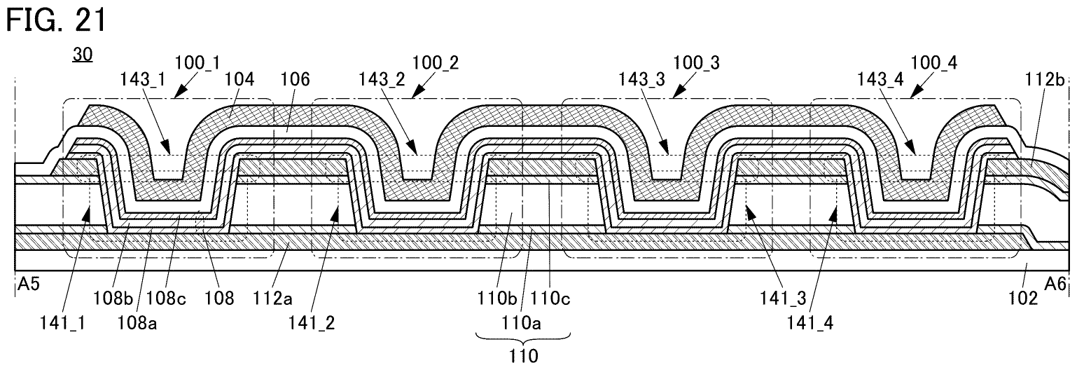

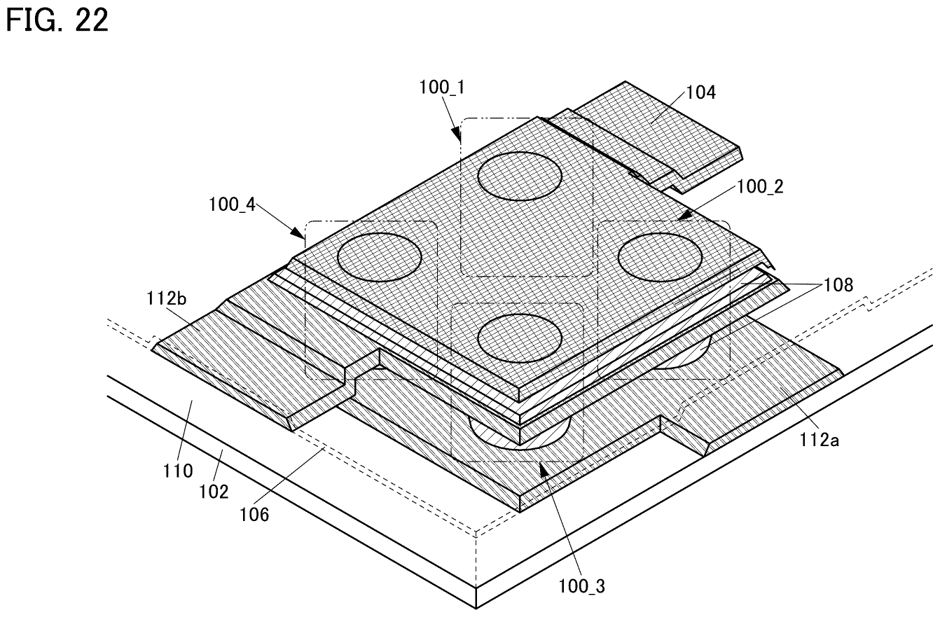

The case where p is 4 is specifically described as an example. FIG. 20B is an equivalent circuit diagram of the semiconductor device 30 of one embodiment of the present invention. FIG. 20C is a top view of the semiconductor device 30. FIG. 21 is a cross-sectional view of a cross section along the dashed-dotted line A3-A4 in FIG. 20C. FIG. 22 is a perspective view of the semiconductor device 30.

The semiconductor device 30 includes the transistor 100_1 to the transistor 100_4. The transistor 100_1 to the transistor 100_4 can each employ the above-described structure of the transistor 100. Although the transistor 100 is described as an example here, one embodiment of the present invention is not limited thereto. Any of the transistor 100A to the transistor 100D may be used as the transistor 100_1 to the transistor 100_4.

Although the transistor 100_1 to the transistor 100_4 are arranged in two rows and two columns in FIG. 15C and the like, there is no limitation on the transistor arrangement. For example, the transistor 100_1 to the transistor 100_4 may be arranged in one row and four columns.

The transistor 100_1 to the transistor 100_4 each include the conductive layer 104, the insulating layer 106, the semiconductor layer 108, the conductive layer 112a, and the conductive layer 112b. The conductive layer 104 functions as a gate electrode of each of the transistor 100_1 to the transistor 100_4. Part of the insulating layer 106 functions as a gate insulating layer of each of the transistor 100_1 to the transistor 100_4. The conductive layer 112a functions as the other of the source electrode and the drain electrode, and the conductive layer 112b functions as one thereof in each of the transistor 100_1 to the transistor 100_4.

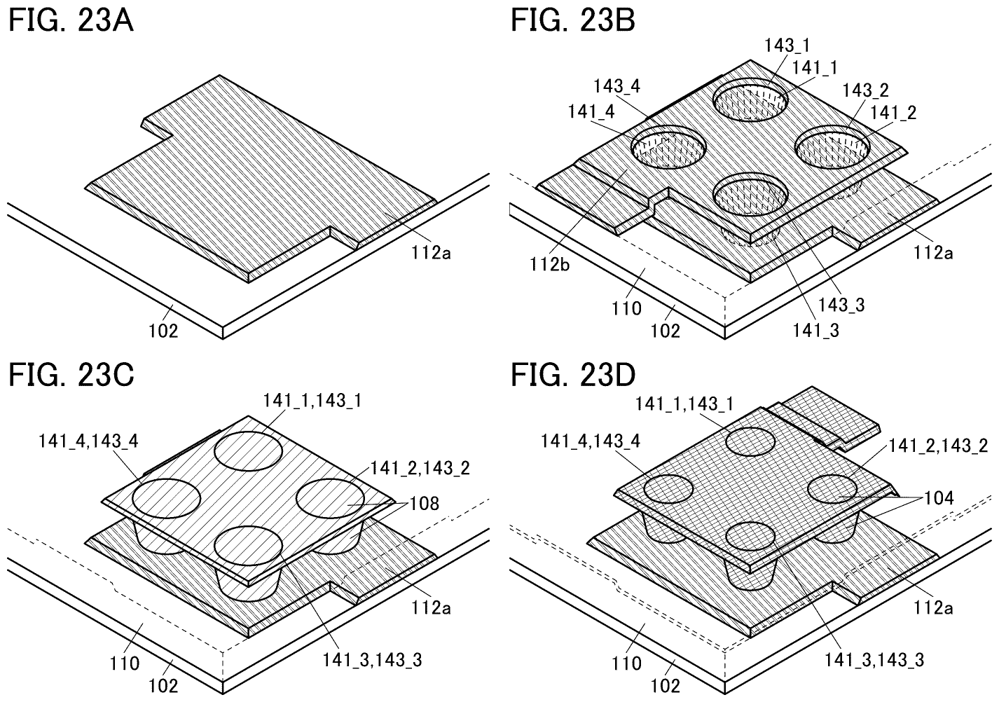

FIG. 23A is a perspective view selectively illustrating the conductive layer 112a.

FIG. 23B is a perspective view selectively illustrating the conductive layer 112a, the conductive layer 112b, an opening 141_1 to an opening 141_4, and an opening 143_1 to an opening 143_4. The opening 141_1 to the opening 141_4 provided in the insulating layer 110 are indicated by dashed lines. The description of the opening 141 and the opening 143 can be referred to for the opening 141_1 to the opening 141_4 and the opening 143_1 to the opening 143_4; thus, the detailed description thereof is omitted.

In the case where the semiconductor device 30 is regarded as one transistor, the channel width of the transistor is the sum of the channel widths of the transistor 100_1 to the transistor 100_4. For example, in the case where the top-view shapes of the opening 143_1 to the opening 143_4 are circular and the width D143 corresponds to the width of each of the opening 143_1 to the opening 143_4, the semiconductor device 30 can be regarded as a transistor having a channel width of “D143×π×4” (see FIG. 4A and FIG. 4B). The semiconductor device 30 composed of p transistors can be regarded as a transistor having a channel width of “D143×π×p”. The semiconductor device 30 can be regarded as a transistor having the channel length L100 (see FIG. 4B). A plurality of transistors connected in parallel can have a larger channel width and a higher on-state current. By adjusting the number (p) of transistors connected in parallel, the channel width can be changed. The number (p) of transistors connected in parallel is determined so that a desired on-state current is obtained.

FIG. 23C is a perspective view showing the conductive layer 112a and the semiconductor layer 108. The semiconductor layer 108 is provided to cover the opening 141_1 to the opening 141_4 and the opening 143_1 to the opening 143_4. Although FIG. 23C and the like illustrates the structure in which the transistor 100_1 to the transistor 100_4 share the semiconductor layer 108, one embodiment of the present invention is not limited thereto. The semiconductor layer 108 may be separated for each of the transistor 100_1 to the transistor 100_4. FIG. 23D is a perspective view showing the conductive layer 112a and the conductive layer 104. The conductive layer 104 is provided to cover the opening 141_1 to the opening 141_4 and the opening 143_1 to the opening 143_4.

Note that the structure of the semiconductor device 30 described in Structure example 2-7 can also be applied to other structure examples. For example, the semiconductor device 30 may be used as one or more transistors included in the semiconductor device illustrated in FIG. 13A to FIG. 13I. [Structure example 2-8]

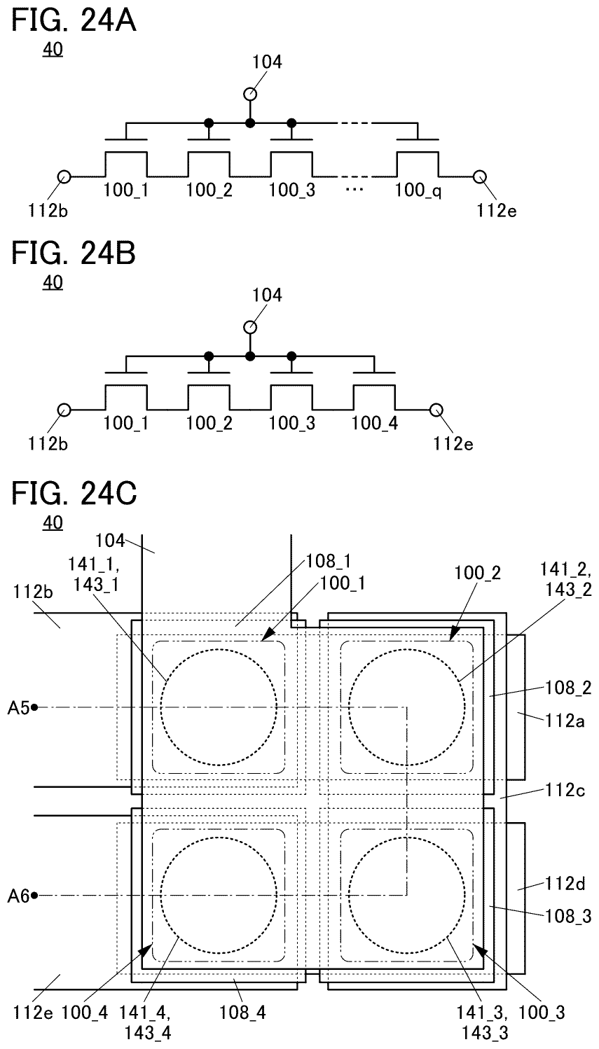

FIG. 24A is an equivalent circuit diagram of a semiconductor device 40 of one embodiment of the present invention. The semiconductor device 40 includes the transistor 100_1 to a transistor 100_q (q is an integer greater than or equal to 2). The semiconductor device 40 can be regarded as one transistor in which the transistor 100_1 to the transistor 100_q are connected in series.

Although the transistor 100_1 to the transistor 100_q are shown as n-channel transistors in FIG. 24A, one embodiment of the present invention is not limited thereto. The transistor 100_1 to the transistor 100_q may be p-channel transistors.

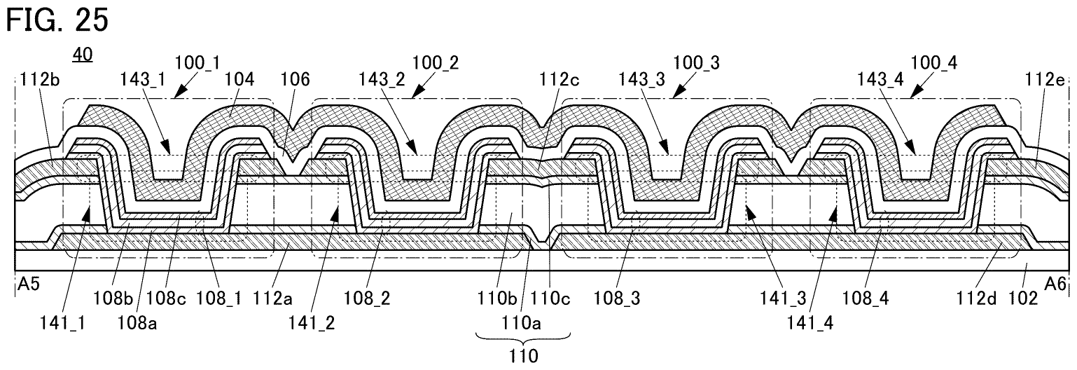

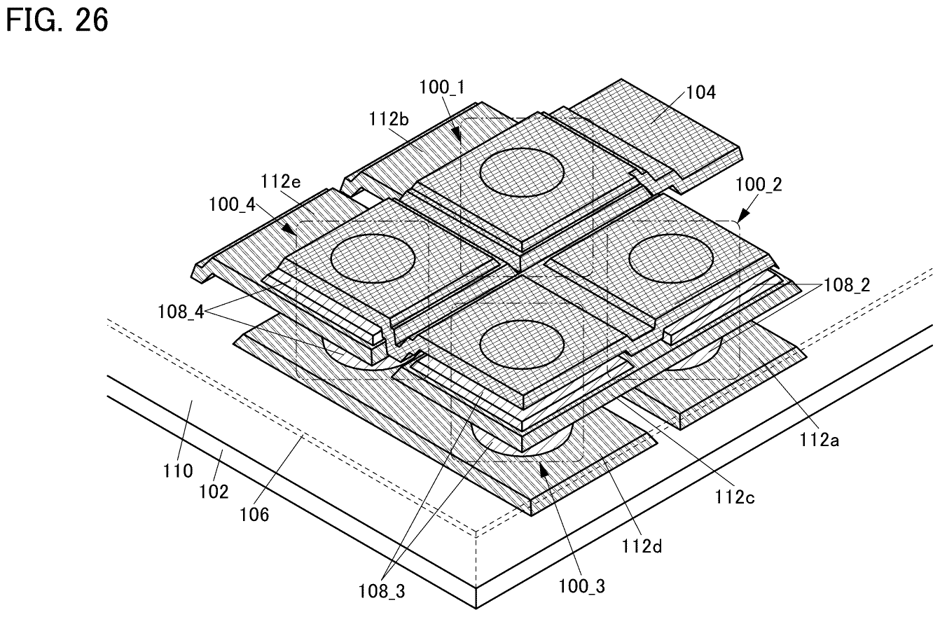

The case where q is 4 is specifically described as an example. FIG. 24B is an equivalent circuit diagram of the semiconductor device 40 of one embodiment of the present invention. FIG. 24C is a top view of the semiconductor device 40. FIG. 25 is a cross-sectional view of a cross section along the dashed-dotted line A5-A6 in FIG. 24C. FIG. 26 is a perspective view of the semiconductor device 40.

The semiconductor device 40 includes the transistor 100_1 to the transistor 100_4. The transistor 100_1 to the transistor 100_4 can each employ the above-described structure of the transistor 100. Although the transistor 100 is described as an example here, one embodiment of the present invention is not limited thereto. Any of the transistor 100A to the transistor 100D may be used as the transistor 100_1 to the transistor 100_4.

Although the transistor 100_1 to the transistor 100_4 are arranged in two rows and two columns in FIG. 24C and the like, there is no limitation on the transistor arrangement. For example, the transistor 100_1 to the transistor 100_4 may be arranged in one row and four columns.

The transistor 100_1 includes the conductive layer 104, the insulating layer 106, a semiconductor layer 108_1, the conductive layer 112a, and the conductive layer 112b. The conductive layer 112a functions as one of the source electrode and the drain electrode of the transistor 100_1 and the conductive layer 112b functions as the other of the source and the drain of in the transistor 100_1.

The transistor 100_2 includes the conductive layer 104, the insulating layer 106, a semiconductor layer 108_2, the conductive layer 112a, and a conductive layer 112c. The conductive layer 112a functions as one of the source electrode and the drain electrode of the transistor 100_2 and the conductive layer 112c functions as the other of the source electrode and the drain electrode of the transistor 100_2. The conductive layer 112a is shared by the transistor 100_1 and the transistor 100_2.

The transistor 100_3 includes the conductive layer 104, the insulating layer 106, a semiconductor layer 108_3, the conductive layer 112c, and a conductive layer 112d. The conductive layer 112c functions as one of the source electrode and the drain electrode of the transistor 100_3 and the conductive layer 112d functions as the other of the source electrode and the drain electrode of the transistor 100_3. The conductive layer 112c is shared by the transistor 100_2 and the transistor 100_3.

The transistor 100_4 includes the conductive layer 104, the insulating layer 106, a semiconductor layer 108_4, the conductive layer 112d, and a conductive layer 112e. The conductive layer 112d functions as one of the source electrode and the drain electrode of the transistor 100_4 and the conductive layer 112e functions as the other of the source electrode and the drain electrode of the transistor 100_4. The conductive layer 112d is shared by the transistor 100_3 and the transistor 100_4.

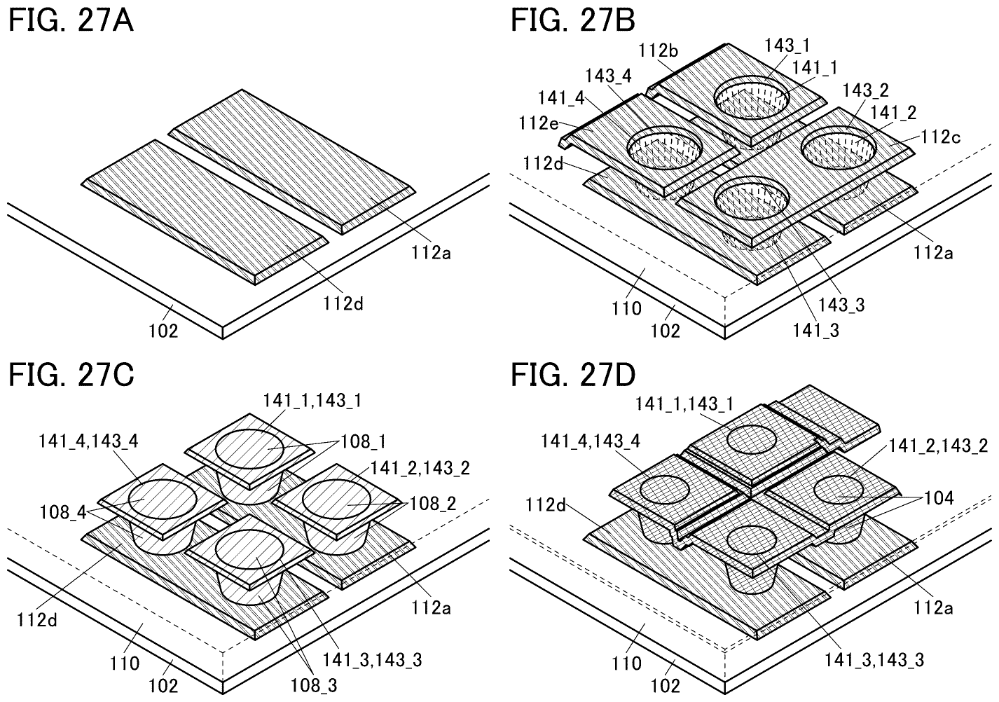

FIG. 27A is a perspective view selectively illustrating the conductive layer 112a and the conductive layer 112d. The conductive layer 112a and the conductive layer 112d can be formed in the same step.

FIG. 27B is a perspective view selectively illustrating the conductive layer 112a, the conductive layer 112b, the conductive layer 112c, the conductive layer 112d, the conductive layer 112e, the opening 141_1 to the opening 141_4, and the opening 143_1 to the opening 143_4. The conductive layer 112a to the conductive layer 112e can be formed in the same step. The opening 143_1 is provided in the conductive layer 112b, the opening 143_2 and the opening 143_3 are provided in the conductive layer 112c, and the opening 143_4 is provided in the conductive layer 112e.

FIG. 27C is a perspective view selectively illustrating the conductive layer 112a, the conductive layer 112d, and the semiconductor layer 108_1 to the semiconductor layer 108_4. The semiconductor layer 108_1 to the semiconductor layer 108_4 can be formed in the same step.

FIG. 27D is a perspective view selectively illustrating the conductive layer 112a, the conductive layer 112d, and the conductive layer 104. The conductive layer 104 functions as a gate electrode of each of the transistor 100_1 to the transistor 100_4.

The one of the source electrode and the drain electrode of the transistor 100_1 is electrically connected to the one of the source electrode and the drain electrode of the transistor 100_2. The other of the source electrode and the drain electrode of the transistor 100_2 is electrically connected to the one of the source electrode and the drain electrode of the transistor 100_3. The other of the source electrode and the drain electrode of the transistor 100_3 is electrically connected to the one of the source electrode and the drain electrode of the transistor 100_4.

In the case where the semiconductor device 40 is regarded as one transistor, the channel length of the transistor is the sum of the channel lengths of the transistor 100_1 to the transistor 100_4. For example, in the case where the channel length L100 corresponds to the channel length of each of the transistor 100_1 to the transistor 100_4, the semiconductor device 40 can be regarded as a transistor having a channel length of “L100×4” (see FIG. 4B). The semiconductor device 40 composed of q transistors can be regarded as a transistor having a channel length of “L100×q”. The semiconductor device 40 can be regarded as a transistor having the channel width W100 (see FIG. 4A and FIG. 4B). A plurality of transistors connected in series can have a larger channel length and favorable saturation. By adjusting the number (q) of transistors connected in series, the channel length can be changed. The number (q) of transistors connected in series is determined so that desired saturation is obtained.

The structure of the semiconductor device 40 described in Structure example 2-8 can also be applied to other structure examples. For example, the semiconductor device 40 may be used as one or more transistors included in the semiconductor device illustrated in FIG. 13A to FIG. 13I.

The semiconductor device 40 may be used as each of the transistors included in the semiconductor device 30. That is, the groups of transistors connected in parallel can further be connected in series (hereinafter also referred to as series-parallel connection).

This embodiment can be combined with the other embodiments as appropriate. In this specification, in the case where a plurality of structure examples are shown in one embodiment, the structure examples can be combined as appropriate.

### Embodiment 2

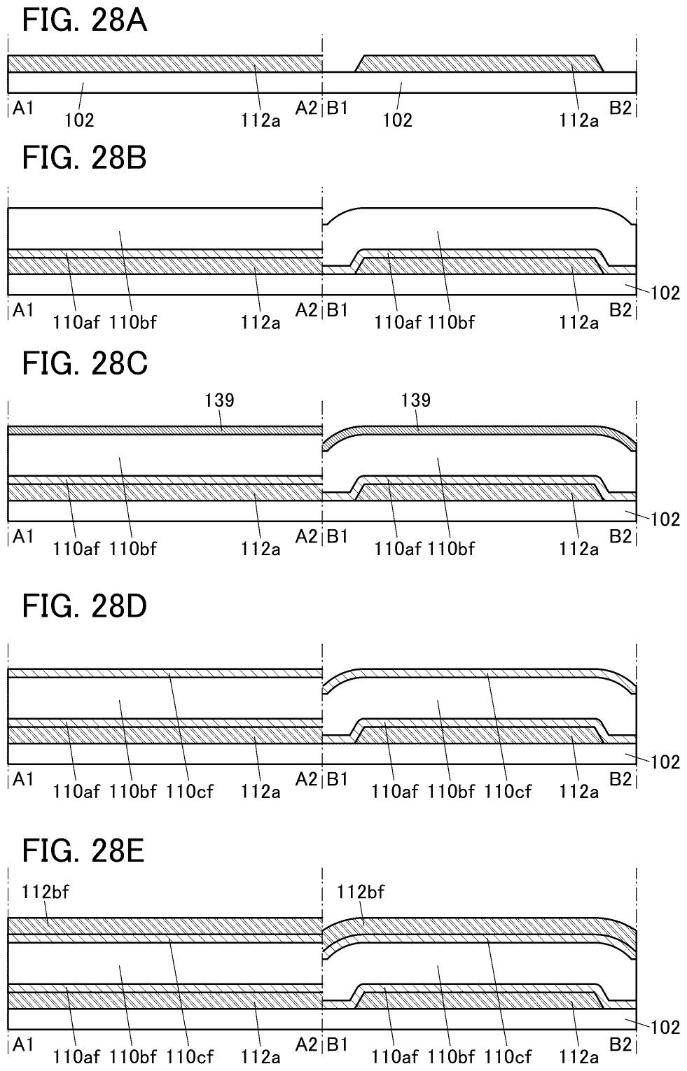

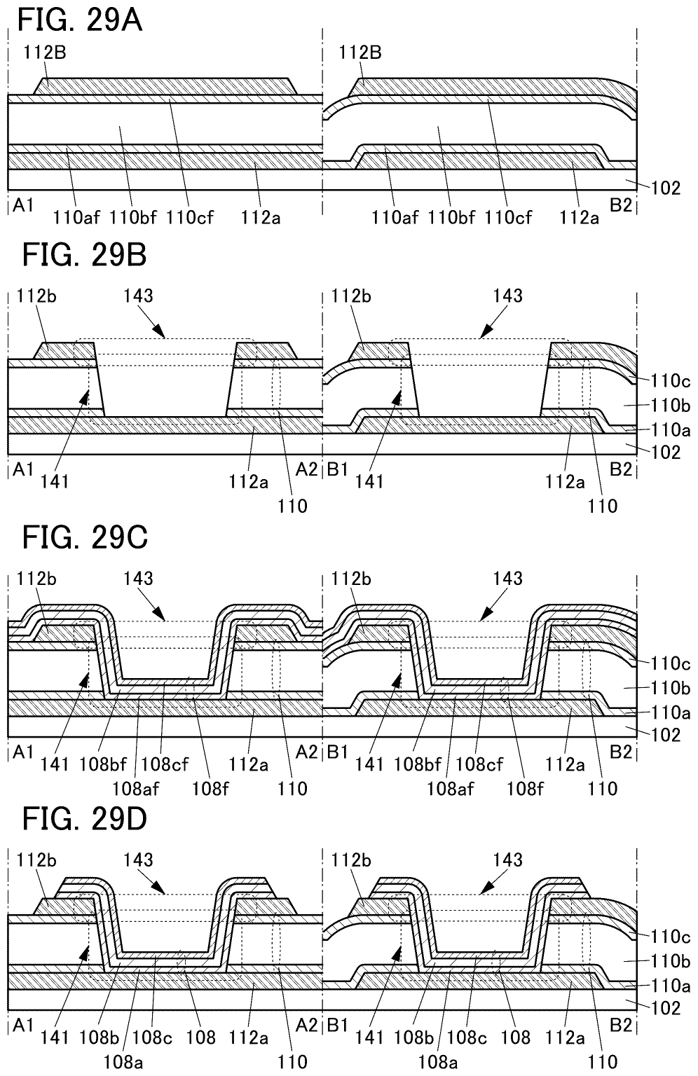

In this embodiment, a method for manufacturing a semiconductor device of one embodiment of the present invention will be described with reference to FIG. 28A to FIG. 29D. Note that as for a material and a formation method of each component, portions similar to the portions described in Embodiment 1 is omitted in some cases.

FIG. 28A to FIG. 29D each illustrate, side by side, a cross section along the dashed-dotted line A1-A2 and a cross section along the dashed-dotted line B1-B2 in FIG. 1A.

Thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a PECVD method and a thermal CVD method. As an example of the thermal CVD method, a metal organic chemical vapor deposition (MOCVD:Metal Organic CVD) method can be given.

Thin films included in the semiconductor device (e.g., insulating films, semiconductor films, and conductive films) can be formed by a wet film formation method such as spin coating, dipping, spray coating, ink-jetting, dispensing, screen printing, offset printing, a doctor knife method, slit coating, roll coating, curtain coating, or knife coating.

When the thin films that form the semiconductor device are processed, a photolithography method or the like can be used. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of a photolithography method. In one of the methods, a resist mask is formed over a thin film to be processed, the thin film is processed by etching or the like, and then the resist mask is removed. In the other method, after a photosensitive thin film is formed, light exposure and development are performed, so that the thin film is processed into a desired shape.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet light, KrF laser light, ArF laser light, or the like can be used. In addition, light exposure may be performed by liquid immersion exposure technique. As the light used for the light exposure, extreme ultraviolet (EUV) light, X-rays, or the like may be used. Instead of the light used for light exposure, an electron beam can be used. It is preferable to use extreme ultraviolet light, X-rays, or an electron beam because extremely minute processing can be performed. Note that a photomask is not needed when light exposure is performed by scanning with a beam such as an electron beam. For etching of thin films, one or more selected from a dry etching method, a wet etching method, and a sandblast method can be used.

First, a conductive film to be the conductive layer 112a is formed over the substrate 102, and the conductive film is processed to form the conductive layer 112a (FIG. 28A). For the formation of the conductive film, a sputtering method can be suitably used.

Next, an insulating film 110af to be the insulating layer 110a and an insulating film 110bf to be the insulating layer 110b are formed over the conductive layer 112a (FIG. 28B).

A sputtering method or a PECVD method can be suitably used for the formation of the insulating film 110af and the insulating film 110bf. It is preferable that the insulating film 110bf be formed in a vacuum successively after the formation of the insulating film 110af, without exposure of a surface of the insulating film 110af to the air. By forming the insulating film 110af and the insulating film 110bf successively, attachment of impurities derived from the air to the surface of the insulating film 110af can be inhibited. Examples of the impurities include water and organic substances.

The substrate temperatures at the time of forming the insulating film 110af and the insulating film 110bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 110af and the insulating film 110bf are in the above range, impurities (e.g., water and hydrogen) released from the insulating films themselves can be reduced, which inhibits diffusion of the impurities to the semiconductor layer 108. Consequently, a transistor with favorable electrical characteristics and high reliability can be obtained. Note that since the insulating film 110af and the insulating film 110bf are formed earlier than the semiconductor layer 108, there is no need to consider the probability of oxygen release from the semiconductor layer 108 due to heat applied thereto at the time of forming the insulating film 110af and the insulating film 110bf.

After the insulating film 110bf is formed, oxygen may be supplied to the insulating film 110bf. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of the apparatus in which a gas is made to be plasma by high-frequency power include PECVD apparatus, a plasma etching apparatus, and a plasma ashing apparatus. The plasma treatment is preferably performed in an atmosphere including oxygen. For example, plasma treatment is preferably performed in an atmosphere including one or more of oxygen, dinitrogen monoxide (N₂O), nitrogen dioxide (NO₂), carbon monoxide, and carbon dioxide.

Note that the plasma treatment may be successively performed in a vacuum without exposure of the surface of the insulating film 110bf to the air. For example, in the case where a PECVD apparatus is used to form the insulating film 110bf, the plasma treatment is preferably performed with the PECVD apparatus. Accordingly, the productivity can be increased. Specifically, after the insulating film 110bf is formed with the PECVD apparatus, N₂O plasma treatment can be successively performed in vacuum.

Next, a metal oxide layer 139 is preferably formed over the insulating film 110bf (FIG. 28C). The formation of the metal oxide layer 139 enables oxygen supply to the insulating film 110bf.

There is no limitation on the conductivity of the metal oxide layer 139. As the metal oxide layer 139, at least one of an insulating film, a semiconductor film, and a conductive film can be used. For the metal oxide layer 139, aluminum oxide, hafnium oxide, hafnium aluminate, indium oxide, indium tin oxide (ITO), or indium tin oxide including silicon (ITSO) can be used, for example.

For the metal oxide layer 139, an oxide including one or more elements that are the same as those of the semiconductor layer 108 is preferably used. It is particularly preferable to use an oxide semiconductor material that can be used for the semiconductor layer 108.

At the time of forming the metal oxide layer 139, the amount of oxygen supplied into the insulating film 110bf can be increased with a higher flow rate ratio of an oxygen gas of the film formation gas introduced into a processing chamber of a film formation apparatus or with higher oxygen partial pressure in the processing chamber. The oxygen flow rate ratio or oxygen partial pressure is, for example, set to higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide layer 139 is formed by a sputtering method in an atmosphere including oxygen in the above manner, oxygen can be supplied to the insulating film 110bf and release of oxygen from the insulating film 110bf can be prevented during the formation of the metal oxide layer 139. As a result, a large amount of oxygen can be enclosed in the insulating film 110bf. Moreover, a large amount of oxygen can be supplied to the semiconductor layer 108 by heat treatment performed later. As a result, the amount of oxygen vacancy and VoH in the semiconductor layer 108 can be reduced, so that a highly reliable transistor exhibiting favorable electrical characteristics can be obtained.

After the metal oxide layer 139 is formed, heat treatment may be performed. By the heat treatment performed after the formation of the metal oxide layer 139, oxygen can be effectively supplied from the metal oxide layer 139 to the insulating film 110bf.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere including one or more of a noble gas, nitrogen, and oxygen. As an atmosphere including nitrogen or an atmosphere including oxygen, clean dry air (CDA) may be used. Furthermore, the content of hydrogen, water, or the like in the atmosphere is preferably as low as possible. As the atmosphere, a high-purity gas with a dew point of −60° C. or lower, preferably −100° C. or lower is preferably used. With use of an atmosphere where the content of hydrogen, water, or the like is as low as possible, entry of hydrogen, water, or the like into the insulating film 110af and the insulating film 110bf can be prevented as much as possible. An oven, a rapid thermal annealing (RTA) apparatus, or the like can be used for the heat treatment. The use of the RTA apparatus can shorten the heat treatment time.

After the formation of the metal oxide layer 139 or after the above-described heat treatment, oxygen may be further supplied to the insulating film 110bf through the metal oxide layer 139. As a method for supplying oxygen, an ion implantation method, an ion doping method, a plasma immersion ion implantation method, or plasma treatment can be used, for example. The above description can be referred to for the plasma treatment; thus, the detailed description thereof is omitted.

Then, the metal oxide layer 139 is removed. There is no particular limitation on a method for removing the metal oxide layer 139, and a wet etching method can be suitably used. With use of a wet etching method, the insulating film 110bf can be inhibited from being etched during the removal of the metal oxide layer 139. This can inhibit a reduction in the thickness of the insulating film 110bf and the thickness of the insulating layer 110b can be uniform.

The treatment for supplying oxygen to the insulating film 110bf is not necessarily performed in the above-described manner. An oxygen radical, an oxygen atom, an oxygen atomic ion, or an oxygen molecular ion is supplied to the insulating film 110bf by an ion doping method, an ion implantation method, or plasma treatment. Alternatively, a film that inhibits oxygen release may be formed over the insulating film 110bf, and then oxygen may be supplied to the insulating film 110bf through the film. It is preferable to remove the film after supply of oxygen. As the above film that inhibits oxygen release, a conductive film or a semiconductor film including one or more of indium, zinc, gallium, tin, aluminum, chromium, tantalum, titanium, molybdenum, nickel, iron, cobalt, and tungsten can be used.

Next, an insulating film 110cf to be the insulating layer 110c is formed over the insulating film 110bf (FIG. 28D). The description of the formation of the insulating film 110af and the insulating film 110bf can be referred to for the formation of the insulating film 110cf; thus, the detailed description thereof is omitted.

Then, a conductive film 112bf to be the conductive layer 112b is formed over the insulating film 110cf (FIG. 28E). For the formation of the conductive film 112bf, a sputtering method can be suitably used, for example.

Next, the conductive film 112bf is processed to form a conductive layer 112B (FIG. 29A). The conductive layer 112B becomes the conductive layer 112b later. For the formation of the conductive layer 112B, a wet etching method can be suitably used, for example.

Next, the conductive layer 112B is partly removed, whereby the conductive layer 112b having the opening 143 is formed. For the formation of the conductive layer 112b, a wet etching method can be suitably used, for example.

Next, the insulating film 110af, the insulating film 110bf, and the insulating film 110cf are partly removed, so that the insulating layer 110 including the opening 141 is formed (FIG. 29B). The opening 141 is provided in a region overlapping with the opening 143. The conductive layer 112a is exposed by the formation of the opening 141. For the formation of the insulating layer 110, a dry etching method can be suitably used.

The opening 141 can be formed using a resist mask used for the formation of the opening 143, for example. Specifically, a resist mask is formed over the conductive layer 112B, the conductive layer 112B is partly removed with use of the resist mask to form the opening 143, and the insulating film 110af, the insulating film 110bf, and the insulating film 110cf are partly removed with use of the resist mask, whereby the opening 141 can be formed. The opening 141 may be formed using a resist mask that is different from the resist mask used for the formation of the opening 143.

Subsequently, a metal oxide film 108f to be the semiconductor layer 108 is formed to cover the opening 141 and the opening 143 (FIG. 29C). Here, as the metal oxide film 108f, a metal oxide film 108af to be the semiconductor layer 108a and a metal oxide film 108bf to be the semiconductor layer 108b, and a metal oxide film 108cf to be the semiconductor layer 108c are stacked. The metal oxide film 108f is provided to be in contact with the top surface and the side surface of the conductive layer 112b, the top surface and the side surface of the insulating layer 110, and the top surface of the conductive layer 112a.

The metal oxide film 108af, the metal oxide film 108bf, and the metal oxide film 108cf are each preferably formed by a sputtering method using a metal oxide target. Alternatively, each of the metal oxide film 108af, the metal oxide film 108bf, and the metal oxide film 108cf are preferably formed by an ALD method. After the formation of the metal oxide film 108af, the metal oxide film 108bf is preferably formed successively without exposure of the surface of the metal oxide film 108af to the air. Similarly, after the formation of the metal oxide film 108bf, the metal oxide film 108cf is preferably formed successively without exposure of the surface of the metal oxide film 108bf to the air. When the metal oxide film 108af, the metal oxide film 108bf, and the metal oxide film 108cf are successively formed, attachment of impurities derived from the air to the surface of the metal oxide film 108af can be inhibited. Examples of the impurities include water and organic substances. Note that the metal oxide film 108af, the metal oxide film 108bf, and the metal oxide film 108cf may be formed using different apparatuses. The metal oxide film 108af, the metal oxide film 108bf, and the metal oxide film 108cf may be formed by different formation methods. For example, the metal oxide film 108af and the metal oxide film 108cf may be formed by an ALD method and the metal oxide film 108bf may be formed by a sputtering method.

An ALD method provides high coverage, and thus can be suitably used for forming one or more of the metal oxide film 108af, the metal oxide film 108bf, and the metal oxide film 108cf that are provided to cover the opening 141 and the opening 143. With an ALD method, a metal oxide film can be formed also on the side surface of the insulating layer 110 with high coverage. In an ALD method, the film formation rate can be easily controlled, so that a thin film can be formed with high yield. Thus, an ALD method can be suitably used particularly for forming the metal oxide film 108af to be the semiconductor layer 108a having a small thickness. Alternatively, instead of a sputtering method and an ALD method, a CVD method may be used for forming any one or more of the metal oxide film 108af, the metal oxide film 108bf, and the metal oxide film 108cf.

The metal oxide film 108af, the metal oxide film 108bf, and the metal oxide film 108cf are each preferably a dense film with as few defects as possible. The metal oxide film 108af, the metal oxide film 108bf, and the metal oxide film 108cf are each preferably a highly purified film in which impurities including a hydrogen element are reduced as much as possible. It is particularly preferable to use a metal oxide film having crystallinity as each of the metal oxide film 108af, the metal oxide film 108bf, and the metal oxide film 108cf.

In forming the metal oxide film 108af, the metal oxide film 108bf, and the metal oxide film 108cf an oxygen gas is preferably used. In particular, in the case of using an oxygen gas at the time of forming the metal oxide film 108af, oxygen can be suitably supplied into the insulating layer 110. For example, in the case of using an oxide or an oxynitride for the insulating layer 110b, oxygen can be suitably supplied into the insulating layer 110b.

By the supply of oxygen to the insulating layer 110b, oxygen is supplied to the semiconductor layer 108 in a later step, so that the amount of oxygen vacancy and VoH in the semiconductor layer 108 can be reduced.

In forming the metal oxide film 108af, the metal oxide film 108bf, and the metal oxide film 108cf, an oxygen gas and an inert gas (e.g., a helium gas, an argon gas, or a xenon gas) may be mixed. Note that when the oxygen flow rate ratio of the film formation gas or the oxygen partial pressure in the treatment chamber is higher in forming the metal oxide film, the metal oxide film can have higher crystallinity and the transistor can have higher reliability. On the other hand, when the oxygen flow rate ratio or the oxygen partial pressure is lower, the metal oxide film can have lower crystallinity and higher electrical conductivity and the transistor can have a higher on-state current. In particular, when the oxygen flow rate ratio or the oxygen partial pressure is reduced in forming the metal oxide film 108bf serving as a main current path, the transistor can have a high on-state current. When the oxygen flow rate ratio in forming the metal oxide film 108af, the oxygen flow rate ratio in forming the metal oxide film 108bf, and the oxygen flow rate ratio in forming the metal oxide film 108cf are made different from each other, the crystallinity can be made different between the metal oxide film 108af, the metal oxide film 108bf, and the metal oxide film 108cf. Note that the oxygen flow rate ratios may be the same or different from each other. The same applies to the oxygen partial pressure.

Here, when the oxygen flow rate ratio or the oxygen partial pressure is high, the metal oxide film has a polycrystalline structure in some cases. In the case of a metal oxide film having a polycrystalline structure, the grain boundary becomes a recombination center and captures carriers and thus might reduce the on-state current of the transistor. Therefore, the oxygen flow rate ratio or the oxygen partial pressure is preferably adjusted for each of the metal oxide film 108af, the metal oxide film 108bf, and the metal oxide film 108cf so that they do not have a polycrystalline structure. Since the ease of forming the polycrystalline structure depends on the composition of the metal oxide film, the oxygen flow rate ratio or the oxygen partial pressure is varied depending on the compositions of the metal oxide film 108af, the metal oxide film 108bf, and the metal oxide film 108cf.

For example, in the case where a material that easily has a polycrystalline structure is used for the metal oxide film 108bf, the oxygen flow rate ratio in forming the metal oxide film 108bf is preferably lower than the oxygen flow rate ratio in forming the metal oxide film 108af and the oxygen flow rate ratio in forming the metal oxide film 108cf. The same applies to the oxygen partial pressure.

When the substrate temperature is higher in forming the metal oxide film, a denser metal oxide film having higher crystallinity can be formed. On the other hand, as the substrate temperature becomes lower, a metal oxide film having lower crystallinity and higher electric conductivity can be formed. Note that the substrate temperature in forming the metal oxide film 108af, the substrate temperature in forming the metal oxide film 108bf, and the substrate temperature in forming the metal oxide film 108cf may be the same or different from each other. With different substrate temperatures, the crystallinity can be made different between the metal oxide film 108af, the metal oxide film 108bf, and the metal oxide film 108cf.

The substrate temperatures during the formation of the metal oxide film 108af, the metal oxide film 108bf, and the metal oxide film 108cf are each preferably higher than or equal to room temperature and lower than or equal to 250° C., further preferably higher than or equal to room temperature and lower than or equal to 200° C., still further preferably higher than or equal to room temperature and lower than or equal to 140° C. For example, when the substrate temperature is higher than or equal to room temperature and lower than or equal to 140° C., high productivity is achieved, which is preferable. Furthermore, when the metal oxide film is formed with the substrate temperature set at room temperature or without heating the substrate, the crystallinity can be made low.

When the substrate temperature is high, the metal oxide film has a polycrystalline structure in some cases. The substrate temperature is preferably adjusted for each of the metal oxide film 108af, the metal oxide film 108bf, and the metal oxide film 108cf so that they do not have a polycrystalline structure. The substrate temperature is varied depending on the compositions applied to the metal oxide film 108af, the metal oxide film 108bf, and the metal oxide film 108cf.

For example, in the case where a material that easily has a polycrystalline structure is used for the metal oxide film 108bf, the substrate temperature in forming the metal oxide film 108bf is preferably lower than the substrate temperature in forming the metal oxide film 108af and the substrate temperature in forming the metal oxide film 108cf.

Here, two or more of the metal oxide film 108af, the metal oxide film 108bf, and the metal oxide film 108cf can be formed using the same sputtering target; thus, the manufacturing cost can be reduced. Furthermore, when two or more of the metal oxide film 108af, the metal oxide film 108bf, and the metal oxide film 108cf are formed at the same substrate temperature, the metal oxide films can be formed with high productivity in the same treatment chamber. For example, it is preferable that the metal oxide film 108bf and the metal oxide film 108cf be successively formed in the same treatment chamber using the same sputtering target. In that case, the substrate temperature is preferably the same, and the oxygen flow rate ratio or the oxygen partial pressure in forming the metal oxide film 108bf is preferably different from the oxygen flow rate ratio or the oxygen partial pressure in forming the metal oxide film 108cf.

In the case of employing an ALD method, a film formation method such as a thermal ALD method or a plasma enhanced ALD (PEALD) method is preferably employed. The thermal ALD method is preferable because of its capability of forming a film with extremely high coverage. The PEALD method is preferable because of its capability of forming a film at low temperatures, in addition to its capability of forming a film with high coverage.

For example, the metal oxide film can be formed by an ALD method using a precursor including a constituent metal element and an oxidizer.

For example, in the case where an In—Ga—Zn oxide is formed, three precursors of a precursor including indium, a precursor including gallium, and a precursor including zinc can be used. Alternatively, two precursors of a precursor including indium and a precursor including gallium and zinc may be used.

Examples of the precursor including indium include triethylindium, tris(2,2,6,6-tetramethyl-3,5-heptanedionato) indium, cyclopentadienylindium, indium (III) chloride, and (3-(dimethylamino) propyl)dimethylindium.

Examples of the precursor including gallium include trimethylgallium, triethylgallium, gallium trichloride, tris(dimethylamido) gallium (III), gallium (III) acetylacetonate, tris(2,2,6,6-tetramethyl-3,5-heptanedionato) gallium, dimethylchlorogallium, and diethylchlorogallium.

Examples of the precursor including zinc include dimethylzinc, diethylzinc, bis(2,2,6,6-tetramethyl-3,5-heptanedionato) zinc, and zinc chloride.

As examples of the oxidizer, ozone, oxygen, and water can be given.

As a method for controlling the composition of a film to be obtained, adjusting one or more of the kinds of source gases, the flow rate ratio of source gases, the flowing time of the source gases, and the order in which the source gases flow is given. By adjusting these, the compositions of the metal oxide film 108af, the metal oxide film 108bf, and the metal oxide film 108cf can be controlled. Moreover, by adjusting these, a film whose composition is continuously changed can be formed. The compositions of one or more of the metal oxide film 108af, the metal oxide film 108bf, and the metal oxide film 108bf may be continuously changed.

For example, a precursor used for forming the metal oxide film 108bf preferably has a lower gallium content percentage than a precursor used for forming the metal oxide film 108af and a precursor used for forming the metal oxide film 108cf. Alternatively, a precursor that does not include gallium may be used for the formation of the metal oxide film 108bf, and a precursor that includes gallium may be used for the formation of the metal oxide film 108af and the metal oxide film 108cf. Although gallium is given as the element M here, one embodiment of the present invention is not limited thereto. Instead of gallium or in addition to gallium, any one or more of the above elements M may be used.

It is preferable to perform at least one of treatment for desorbing water, hydrogen, an organic substance, and the like adsorbed onto the surface of the insulating layer 110 and treatment for supplying oxygen into the insulating layer 110 before the formation of the metal oxide film 108f (specifically, the metal oxide film 108af). For example, heat treatment can be performed at a temperature higher than or equal to 70° C. and lower than or equal to 200° C. in a reduced-pressure atmosphere. Alternatively, plasma treatment may be performed in an atmosphere including oxygen. Alternatively, oxygen may be supplied to the insulating layer 110 by plasma treatment in an atmosphere including an oxidizing gas such as dinitrogen monoxide (N₂O). Performing plasma treatment including a dinitrogen monoxide gas can supply oxygen while suitably removing an organic substance on the surface of the insulating layer 110. It is preferable that the metal oxide film 108f be formed successively after such treatment, without exposure of the surface of the insulating layer 110 to the air.

Next, the metal oxide film 108f is processed into an island shape to form the semiconductor layer 108 (FIG. 29D).

For the formation of the semiconductor layer 108, a wet etching method can be suitably used. At this time, part of the conductive layer 112b in a region not overlapping with the semiconductor layer 108 is etched and thinned in some cases. In a similar manner, part of the insulating layer 110 in a region overlapping with neither the semiconductor layer 108 nor the conductive layer 112b is etched and thinned in some cases. For example, in the insulating layer 110, the insulating layer 110c is removed by etching and the surface of the insulating layer 110b is exposed, in some cases. Note that in etching of the metal oxide film 108f, a reduction in the thickness of the insulating layer 110c can be inhibited when a material having high selectivity is used for the insulating layer 110c.

It is preferable that heat treatment be performed after the metal oxide film 108f is formed or the metal oxide film 108f is processed into the semiconductor layer 108. By the heat treatment, hydrogen or water included in the metal oxide film 108f or the semiconductor layer 108 or adsorbed onto the surface of the metal oxide film 108f or the semiconductor layer 108 can be removed. Furthermore, the film quality of the metal oxide film 108f or the semiconductor layer 108 is improved (e.g., the number of defects is reduced or crystallinity is increased) by the heat treatment in some cases.

Oxygen can be supplied from the insulating layer 110b to the metal oxide film 108f or the semiconductor layer 108 by heat treatment. In this case, it is further preferable that the heat treatment be performed before the semiconductor film 108f is processed into the semiconductor layer 108. The above description can be referred to for the heat treatment; thus, the detailed description thereof is omitted.

Note that the heat treatment is not necessarily performed. The heat treatment in this step may be omitted, and heat treatment performed in a later step may also serve as the heat treatment in this step. In some cases, heat application treatment in a later step (e.g., a film formation step) or the like can serve as the heat treatment in this step.

Then, the insulating layer 106 is formed to cover the semiconductor layer 108, the conductive layer 112b, and the insulating layer 110. For the formation of the insulating layer 106, a PECVD method or an ALD method can be suitably used, for example.

In the case of using an oxide semiconductor for the insulating layer 108, the insulating layer 106 preferably functions as a barrier film that inhibits diffusion of oxygen. The insulating layer 106 having a function of inhibiting diffusion of oxygen inhibits diffusion of oxygen into the conductive layer 104 from above the insulating layer 106 and thus can inhibit oxidation of the conductive layer 104. Consequently, the transistor can have favorable electrical characteristics and high reliability.

In this specification and the like, a barrier film refers to a film having a barrier property. For example, an insulating layer having a barrier property can be referred to as a barrier insulating layer. In this specification and the like, a barrier property means one or both of a function of inhibiting diffusion of a particular substance (or low permeability) and a function of capturing or fixing (also referred to as gettering) a particular substance.

By increasing the temperature at the time of forming the insulating layer 106 functioning as the gate insulating layer, the insulating layer including a small number of defects can be obtained. However, the high temperature at the time of forming the insulating layer 106 sometimes allows release of oxygen from the semiconductor layer 108, which increases the amount of oxygen vacancy and VoH in the semiconductor layer 108 in some cases. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is in the above range, release of oxygen from the semiconductor layer 108 can be inhibited while the defects in the insulating layer 106 can be reduced. Consequently, a transistor with favorable electrical characteristics and high reliability can be obtained.

Before the formation of the insulating layer 106, the surface of the semiconductor layer 108 may be subjected to plasma treatment. By the plasma treatment, an impurity adsorbed onto the surface of the semiconductor layer 108, such as water, can be reduced. Thus, impurities at the interface between the semiconductor layer 108 and the insulating layer 106 can be reduced, achieving a highly reliable transistor. The plasma treatment is particularly suitable in the case where the surface of the semiconductor layer 108 is exposed to the air after the formation of the semiconductor layer 108 but before the formation of the insulating layer 106. For example, plasma treatment can be performed in an atmosphere including oxygen, ozone, nitrogen, dinitrogen monoxide, argon, or the like. The plasma treatment and the formation of the insulating layer 106 are preferably performed successively without exposure to the air.

Next, the conductive layer 104 is formed over the insulating layer 106 (FIG. 1A and FIG. 1B). For the formation of a conductive film to be the conductive layer 104, a sputtering method, a thermal CVD method (including an MOCVD method), or an ALD method can be suitably used, for example.

Through the above steps, the semiconductor device of one embodiment of the present invention can be manufactured.

This embodiment can be combined with the other embodiments as appropriate.

### Embodiment 3

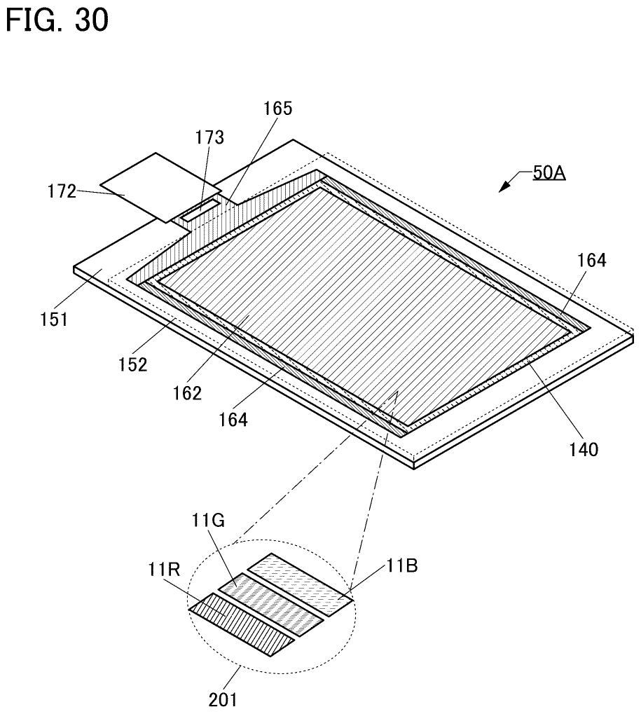

In this embodiment, display devices of embodiments of the present invention are described with reference to FIG. 30 to FIG. 39.

The display device of this embodiment can be a high-definition display device or a large-sized display device. Accordingly, the display device of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop computer, a monitor of a computer or the like, digital signage, and a large game machine such as a pachinko machine.

The display device of this embodiment can be a high-resolution display device. Accordingly, the display device of this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The semiconductor device of one embodiment of the present invention can be used for a display device or a module including the display device. Examples of the module including the display device are a module in which a connector such as a flexible printed circuit board (hereinafter referred to as an FPC) or a tape carrier package (TCP) is attached to the display device, a module in which the display device is mounted with an integrated circuit (IC) by a chip on glass (COG) method, a chip on film (COF) method, or the like, and the like.

The display device in this embodiment may have a function of a touch panel. The display device can employ any of a variety of sensing elements (also referred to as sensor elements) that can sense proximity or touch of a sensing target such as a finger, for example.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The use of a mutual capacitive type is preferable because multiple points can be sensed simultaneously.

Examples of a touch panel include an out-cell touch panel, an on-cell touch panel, and an in-cell touch panel. An in-cell touch panel has a structure where an electrode included in a sensor element is provided on one or both of a substrate supporting a display element and a counter substrate.

### [Display Device 50A]

FIG. 30 is a perspective view of a display device 50A.

In the display device 50A, a substrate 152 and a substrate 151 are bonded to each other.

In FIG. 30, the substrate 152 is indicated by a dashed line.

The display device 50A includes a display portion 162, a connection portion 140, a circuit portion 164, a conductive layer 165, and the like. FIG. 30 illustrates an example where an IC 173 and an FPC 172 are mounted on the display device 50A. Thus, the structure illustrated in FIG. 30 can be regarded as a display module including the display device 50A, the IC, and the FPC.

The connection portion 140 is provided outside the display portion 162. The connection portion 140 can be provided along one or more sides of the display portion 162. The number of connection portions 140 may be one or more. FIG. 30 illustrates an example where the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The conductive layer 165 has a function of supplying a signal and power to the display portion 162 and the circuit portion 164. The signal and power are input to the conductive layer 165 from the outside through the FPC 172 or input to the conductive layer 165 from the IC 173. FIG. 30 illustrates an example where the IC 173 is provided on the substrate 151 by a COG method, a COF method, or the like. An IC including one or both of a scan line driver circuit and a signal line driver circuit can be used as the IC 173, for example. Note that the display device 50A and the display module are not necessarily provided with an IC. The IC may be mounted on the FPC by a COF method or the like.

The semiconductor device of one embodiment of the present invention can be used for one or both of the display portion 162 and the circuit portion 164 of the display device 50A, for example.

When the semiconductor device of one embodiment of the present invention is used for a pixel circuit of a display device, the area occupied by the pixel circuit can be reduced and a high-resolution display device can be provided, for example. When the semiconductor device of one embodiment of the present invention is used for a driver circuit (e.g., one or both of a gate line driver circuit and a source line driver circuit) of a display device, the area occupied by the driver circuit can be reduced and the display device can have a narrow bezel, for example. Since the semiconductor device of one embodiment of the present invention has favorable electrical characteristics, a display device can have increased reliability by using the transistor.

The display portion 162 of the display device 50A is a region where an image is to be displayed, and includes a plurality of pixels 201 that are periodically arranged. An enlarged view of one pixel 201 is illustrated in FIG. 30.

There is no particular limitation on the arrangement of the pixels in the display device of this embodiment, and a variety of methods can be employed. Examples of the arrangement of the pixels include stripe arrangement, S-stripe arrangement, matrix arrangement, delta arrangement, Bayer arrangement, and PenTile arrangement.

The pixel 201 illustrated in FIG. 30 includes a subpixel 11R that emits red light, a subpixel 11G that emits green light, and a subpixel 11B that emits blue light.

The subpixels 11R, 11G, and 11B each include a display element and a circuit for controlling the driving of the display element.

A variety of elements can be used as the display element, and a liquid crystal element or a light-emitting element can be used, for example. Alternatively, it is also possible to use, for example, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like. Alternatively, a QLED (Quantum-dot LED) employing a light source and color conversion technology using quantum dot materials may be used.

As examples of a display device using a liquid crystal element, a transmissive liquid display device, a reflective liquid display device, and a transflective liquid display device can be given.

Examples of a mode that can be used for a display device using a liquid crystal element include a vertical alignment (VA) mode, a FFS (Fringe Field Switching) mode, an IPS (In-Plane Switching) mode, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, and a guest-host mode. Examples of the VA mode include a MVA (Multi-Domain Vertical Alignment) mode, a PVA (Patterned Vertical Alignment) mode, and an ASV (Advanced Super View) mode.

Examples of a liquid crystal material that can be used for the liquid crystal element, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and the selection can be made in accordance with the mode or design that is used.

Examples of the light-emitting element include a self-luminous light-emitting element such as an LED (Light Emitting Diode), an OLED (Organic LED), and a semiconductor laser. Examples of the LED include a mini LED and a micro LED.

Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

The emission color of the light-emitting element can be infrared, red, green, blue, cyan, magenta, yellow, white, or the like. When the light-emitting element has a microcavity structure, the color purity can be increased.

One electrode of the pair of electrodes included in the light-emitting element functions as an anode, and the other electrode functions as a cathode.

The display device of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

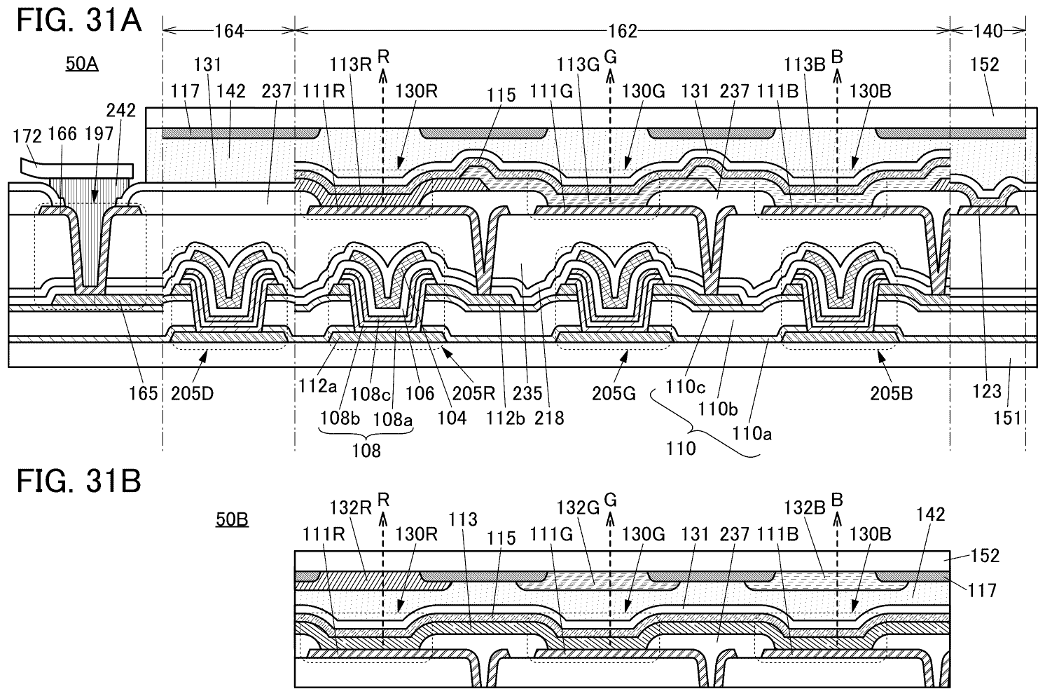

FIG. 31A illustrates an example of cross sections of part of a region including the FPC 172, part of the circuit portion 164, part of the display portion 162, part of the connection portion 140, and part of a region including an end portion of the display device 50A.

The display device 50A illustrated in FIG. 31A includes transistors 205D, 205R, 205G, and 205B, a light-emitting element 130R, a light-emitting element 130G, a light-emitting element 130B, and the like between the substrate 151 and the substrate 152. The light-emitting elements 130R, 130G, and 130B are display elements included in the subpixel 11R that emits red light, the subpixel 11G that emits green light, and the subpixel 11B that emits blue light, respectively.

The display device 50A employs an SBS structure. The SBS structure can optimize materials and structures of light-emitting elements and thus can increase the degree of freedom in selecting materials and structures, so that the luminance and the reliability can be easily improved.

The display device 50A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

The transistors 205D, 205R, 205G, and 205B are each formed over the substrate 151. These transistors can be manufactured using the same material in the same step.

This embodiment describes an example where OS transistors are used as the transistors 205D, 205R, 205G, and 205B. The transistor of one embodiment of the present invention can be used as the transistors 205D, 205R, 205G, and 205B. In other words, the display device 50A includes the transistor of one embodiment of the present invention in both the display portion 162 and the circuit portion 164. When the transistor of one embodiment of the present invention is used in the display portion 162, the pixel size can be reduced and high resolution can be achieved. When the transistor of one embodiment of the present invention is used in the circuit portion 164, the area occupied by the circuit portion 164 can be reduced and a narrower bezel can be achieved. The description in the above embodiment can be referred to for the transistor of one embodiment of the present invention.

Specifically, the transistors 205D, 205R, 205G, and 205B each include the conductive layer 104 functioning as a gate, the insulating layer 106 functioning as a gate insulating layer, the conductive layer 112a and the conductive layer 112b functioning as a source and a drain, the semiconductor layer 108 containing a metal oxide, and the insulating layer 110 (the insulating layers 110a, 110b, and 110c). Here, a plurality of layers obtained by processing the same conductive film are shown with the same hatching pattern. The insulating layer 110 is positioned between the conductive layer 112a and the semiconductor layer 112b. The insulating layer 106 is positioned between the conductive layer 104 and the semiconductor layer 108.

Note that the transistor included in the display device of this embodiment is not limited to the transistor of one embodiment of the present invention. For example, the display device of this embodiment may include the transistor of one embodiment of the present invention and a transistor having another structure in combination.

The display device of this embodiment may include any one or more of a planar transistor, a staggered transistor, and an inverted staggered transistor. A transistor included in the display device of this embodiment may have either a top-gate structure or a bottom-gate structure. Alternatively, gates may be provided above and below the semiconductor layer where a channel is formed.

A Si transistor may be included in the display device of this embodiment.

To increase the emission luminance of the light-emitting element included in the pixel circuit, the amount of current flowing through the light-emitting element needs to be increased. To increase the amount of current, the source-drain voltage of a driving transistor included in the pixel circuit needs to be increased. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting element can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made to flow through an OS transistor than through a Si transistor. Thus, by using an OS transistor as the driving transistor, a stable current can be made to flow through a light-emitting element even when the current-voltage characteristics of a light-emitting element vary, for example. In other words, when the OS transistor operates in the saturation region, the source-drain current hardly changes with a change in the source-drain voltage; hence, the emission luminance of the light-emitting element can be stable.

The transistors included in the circuit portion 164 and the transistors included in the display portion 162 may have the same structure or different structures. A plurality of transistors included in the circuit portion 164 may have the same structure or two or more kinds of structures. Similarly, a plurality of transistors included in the display portion 162 may have the same structure or two or more kinds of structures.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high drive capability. A structure in which an LTPS transistor and an OS transistor are used in combination is referred to as LTPO in some cases. As a more suitable example, a structure in which the OS transistor is used as a transistor or the like functioning as a switch for controlling conduction or non-conduction between wirings, and the LTPS transistor is used as a transistor or the like for controlling current, can be given.

For example, one of the transistors included in the display portion 162 functions as a transistor for controlling a current flowing through the light-emitting element and can also be referred to as a driving transistor. One of a source and a drain of the driving transistor is electrically connected to a pixel electrode of the light-emitting element. An LTPS transistor is preferably used as the driving transistor. In that case, the amount of current flowing through the light-emitting element can be increased in the pixel circuit.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

An insulating layer 218 is provided to cover the transistors 205D, 205R, 205G, and 205B and an insulating layer 235 is provided over the insulating layer 218.

The insulating layer 218 preferably functions as a protective layer of the transistors. A material that does not easily allow diffusion of impurities such as water and hydrogen is preferably used for the insulating layer 218. Accordingly, the insulating layer 218 can function as a barrier film. This structure can effectively inhibit diffusion of impurities into the transistors from the outside and improve the reliability of the display device.

The insulating layer 218 preferably includes one or more inorganic insulating films. Examples of the inorganic insulating film include an oxide insulating film, a nitride insulating film, an oxynitride insulating film, and a nitride oxide insulating film. Specific examples of these inorganic insulating film are as described above.

The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. Accordingly, a depressed portion can be inhibited from being formed in the insulating layer 235 in processing pixel electrodes 111R, 111G, and 111B, for example. Alternatively, a depressed portion may be formed in the insulating layer 235 in processing the pixel electrodes 111R, 111G, and 111B, for example.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 31A emits red light (R). The EL layer 113R includes a light-emitting layer that emits red light.

The light-emitting element 130G includes the pixel electrode 111G over the insulating layer 235, an EL layer 113G over the pixel electrode 111G, and the common electrode 115 over the EL layer 113G. The light-emitting element 130G illustrated in FIG. 31A emits green light (G). The EL layer 113G includes a light-emitting layer that emits green light.

The light-emitting element 130B includes the pixel electrode 111B over the insulating layer 235, an EL layer 113B over the pixel electrode 111B, and the common electrode 115 over the EL layer 113B. The light-emitting element 130B illustrated in FIG. 31A emits blue light (B). The EL layer 113B includes a light-emitting layer that emits blue light.

Although the EL layers 113R, 113G, and 113B have the same thickness in FIG. 31A, the present invention is not limited thereto. The EL layers 113R, 113G, and 113B may have different thicknesses. For example, the thicknesses of the EL layers 113R, 113G, and 113B are preferably set in accordance with an optical path length that intensifies light emitted from each EL layer. Accordingly, a microcavity structure is achieved, and the color purity of light emitted from each light-emitting element can be improved.

The pixel electrode 111R is electrically connected to the conductive layer 112b included in the transistor 205R through an opening provided in the insulating layer 106, the insulating layer 218, and the insulating layer 235. In a similar manner, the pixel electrode 111G is electrically connected to the conductive layer 112b included in the transistor 205G, and the pixel electrode 111B is electrically connected to the conductive layer 112b included in the transistor 205B.

End portions of the pixel electrodes 111R, 111G, and 111B are covered with an insulating layer 237. The insulating layer 237 functions as a partition. The insulating layer 237 can be provided to have a single-layer structure or a stacked-layer structure using one or both of an inorganic insulating material and an organic insulating material. A material that can be used for the insulating layer 218 and a material that can be used for the insulating layer 235 can be used for the insulating layer 237, for example. With the insulating layer 237, the pixel electrode and the common electrode can be electrically insulated from each other. Furthermore, with the insulating layer 237, adjacent light-emitting elements can be electrically insulated from each other. The insulating layer 237 is provided in at least the display portion 162. The insulating layer 237 may be provided in not only the display portion 162 but also the connection portion 140 and the circuit portion 164. The insulating layer 237 may be provided to extend to the end portion of the display device 50A.

The common electrode 115 is a continuous film shared by the light-emitting elements 130R, 130G, and 130B. The common electrode 115 shared by the plurality of light-emitting elements is electrically connected to a conductive layer 123 provided in the connection portion 140. The conductive layer 123 is preferably formed using a conductive layer formed using the same material in the same step as the pixel electrodes 111R, 111G, and 111B.

In the display device of one embodiment of the present invention, a conductive film transmitting visible light is used for the electrode through which light is extracted, which is either the pixel electrode or the common electrode. A conductive film reflecting visible light is preferably used for the electrode through which light is not extracted.

A conductive film transmitting visible light may be used also for the electrode through which light is not extracted. In that case, this electrode is preferably provided between a reflective layer and the EL layer. In other words, light emitted by the EL layer may be reflected by the reflective layer to be extracted from the display device.

As a material that forms the pair of electrodes of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Thus, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² (2 cm.

The EL layers 113R, 113G, and 113B are each provided to have an island shape. In FIG. 31A, an end portion of the EL layer 113R and an end portion of the EL layer 113G that are adjacent to each other overlap with each other, an end portion of the EL layer 113G and an end portion of the EL layer 113B that are adjacent to each other overlap with each other, and an end portion of the EL layer 113R and an end portion of the EL layer 113B that are adjacent to each other overlap with each other. When island-shaped EL layers are formed using a fine metal mask, end portions of the EL layers adjacent to each other may overlap with each other as illustrated in FIG. 31A; however, the present invention is not limited thereto. That is, it is also possible that the EL layers adjacent to each other do not overlap with each other and are apart from each other. Furthermore, both a portion where the EL layers adjacent to each other overlap with each other and a portion where the EL layers adjacent to each other do not overlap with each other and are apart from each other may exist in the display device.

Each of the EL layers 113R, 113G, and 113B includes at least a light-emitting layer. The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time. In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further contain one or both of a bipolar substance and a TADF material.

Either a low molecular compound or a high molecular compound can be used for the light-emitting element, and an inorganic compound may also be contained. Each of the layers included in the light-emitting element can be formed by an evaporation method (including a vacuum evaporation method), a transfer method, a printing method, an inkjet method, a coating method, or the like.

For the light-emitting element, a single structure (a structure including only one light-emitting unit) or a tandem structure (a structure including a plurality of light-emitting units) may be employed. The light-emitting unit includes at least one light-emitting layer. In a tandem structure, a plurality of light-emitting units are connected in series with a charge-generation layer therebetween. The charge-generation layer has a function of injecting electrons into one of the two light-emitting units and injecting holes into the other when voltage is applied between the pair of electrodes. The tandem structure enables a light-emitting element capable of high-luminance light emission. Furthermore, the tandem structure allows the amount of current needed for obtaining the same luminance to be reduced as compared to the case of using a single structure, and thus can improve the reliability. The tandem structure may be referred to as a stack structure.

In the case of using a light-emitting element having a tandem structure in FIG. 31A, it is preferable that the EL layer 113R include a plurality of light-emitting units emitting red light, the EL layer 113G include a plurality of light-emitting units emitting green light, and the EL layer 113B include a plurality of light-emitting units emitting blue light.

A protective layer 13I is provided over the light-emitting elements 130R, 130G, and 130B. The protective layer 131 and the substrate 152 are bonded to each other with an adhesive layer 142 therebetween. The substrate 152 is provided with a light-blocking layer 117. For example, a solid sealing structure or a hollow sealing structure can be employed to seal the light-emitting elements. In FIG. 31A, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting element. The space may be filled with a resin different from that of the frame-like adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit portion 164. It is further preferable that the protective layer 131 be provided to extend to the end portion of the display device 50A. Meanwhile, a connection portion 197 has a portion not provided with the protective layer 131 so that the FPC 172 and a conductive layer 166 are electrically connected to each other.

By providing the protective layer 131 over the light-emitting elements 130R, 130G, and 130B, the reliability of the light-emitting elements can be increased.

The protective layer 131 may have a single-layer structure or a stacked-layer structure of two or more layers. There is no limitation on the conductivity of the protective layer 131. As the protective layer 131, at least one kind of an insulating film, a semiconductor film, and a conductive film can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved.

As the protective layer 131, an inorganic insulating film such as an oxide insulating film, a nitride insulating film, an oxynitride insulating film, or a nitride oxide insulating film can be used, for example. Specific examples of these inorganic insulating films are as described above. In particular, the protective layer 131 preferably includes a nitride insulating film or a nitride oxide insulating film, and further preferably includes a nitride insulating film.

An inorganic film containing ITO, In—Zn oxide, Ga—Zn oxide, Al—Zn oxide, IGZO, or the like can be used as the protective layer 131. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a high property of transmitting visible light. For example, ITO, IGZO, and aluminum oxide are preferable because they are inorganic materials having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 197 is provided in a region of the substrate 151 not overlapping with the substrate 152. In the connection portion 197, the conductive layer 165 is electrically connected to the FPC 172 through the conductive layer 166 and a connection layer 242. In this example, the conductive layer 165 has a single-layer structure of a conductive layer obtained by processing the same conductive film as the conductive layer 112b. An example in which the conductive layer 166 is a single conductive layer obtained by processing the same conductive film as the pixel electrodes 111R, 111G, and 111B is shown. On the top surface of the connection portion 197, the conductive layer 166 is exposed. Thus, the connection portion 197 and the FPC 172 can be electrically connected to each other through the connection layer 242.

The display device 50A has a top-emission structure. Light emitted from the light-emitting element is emitted toward the substrate 152 side. For the substrate 152, a material having a high visible-light-transmitting property is preferably used. The pixel electrodes 111R, 111G, and 111B include a material that reflects visible light, and the counter electrode (the common electrode 115) includes a material that transmits visible light.

The light-blocking layer 117 is preferably provided on the surface of the substrate 152 on the substrate 151 side. The light-blocking layer 117 can be provided between adjacent light-emitting elements, in the connection portion 140, and in the circuit portion 164, for example.

A coloring layer such as a color filter may be provided on the surface of the substrate 152 on the substrate 151 side or over the protective layer 131. When the color filter is provided so as to overlap with the light-emitting element, the color purity of light emitted from the pixel can be increased.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer is formed in a desired position by a printing method, an ink-jet method, an etching method using a photolithography method, or the like.

A variety of optical members can be provided on the outer side of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer side of the substrate 152. For example, it is preferable to provide, as the surface protective layer, a glass layer or a silica layer (SiOₓ layer) because the surface contamination and generation of damage can be inhibited. For the surface protective layer, DLC (diamond-like carbon), aluminum oxide (AlOₓ), a polyester-based material, a polycarbonate-based material, or the like may be used. For the surface protective layer, a material having a high visible-light transmittance is preferably used. For the surface protective layer, a material with high hardness is preferably used.

For each of the substrate 151 and the substrate 152, glass, quartz, ceramics, sapphire, a resin, a metal, an alloy, a semiconductor, or the like can be used. For the substrate on the side from which light from the light-emitting element is extracted, a material that transmits the light is used. When the substrate 151 and the substrate 152 are formed using a flexible material, the flexibility of the display device can be increased and a flexible display can be achieved. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used as at least one of the substrate 151 and the substrate 152.

In the case where a circularly polarizing plate overlaps with the display device, a highly optically isotropic substrate is preferably used as the substrate included in the display device. A highly optically isotropic substrate has a low birefringence (i.e., a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet or the like may be used.

As the connection layer 242, an anisotropic conductive film (ACF), an anisotropic conductive paste (ACP), or the like can be used.

### [Display Device 50B]

FIG. 31B shows an example of a cross section of the display portion 162 of a display device 50B. The display device 50B is different from the display device 50A mainly in that the subpixels of different colors include respective coloring layers (color filters or the like) and the light-emitting elements which share an EL layer 113. The structure illustrated in FIG. 31B can be combined with the structure illustrated in FIG. 31A of the region including the FPC 172, the circuit portion 164, the stacked-layer structure from the substrate 151 to the insulating layer 235 in the display portion 162, the connection portion 140, and the end portion. As for the following description of the display device, description of portions similar to those of the above-described display device is omitted in some cases.

The display device 50B illustrated in FIG. 31B includes the light-emitting elements 130R, 130G, and 130B, a coloring layer 132R transmitting red light, a coloring layer 132G transmitting green light, a coloring layer 132B transmitting blue light, and the like.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display device 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display device 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display device 50B through the coloring layer 132B.

The EL layer 113 and the common electrode 115 are shared between the light-emitting elements 130R, 130G, and 130B. The number of manufacturing steps can be smaller in the structure where the EL layer 113 is provided to be shared between the subpixels of different colors than the structure where the subpixels of different colors are provided with different EL layers.

The light-emitting elements 130R, 130G, and 130B illustrated in FIG. 31B emit white light, for example. When white light emitted from the light-emitting elements 130R, 130G, and 130B passes through the coloring layers 132R, 132G, and 132B, light of desired colors can be obtained.

The light-emitting element that emits white light preferably includes two or more light-emitting layers. When white light emission is obtained using two light-emitting layers, the two light-emitting layers are selected such that emission colors of the light-emitting layers are complementary colors. For example, when an emission color of a first light-emitting layer and an emission color of a second light-emitting layer are complementary colors, the light-emitting element can be configured to emit white light as a whole. In the case where three or more light-emitting layers are used to obtain white light, the light-emitting element is configured to emit white light as a whole by combining emission colors of the three or more light-emitting layers.

The EL layer 113 preferably includes a light-emitting layer containing a light-emitting substance that emits blue light and a light-emitting layer containing a light-emitting substance that emits visible light having a longer wavelength than blue light, for example. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specifically, examples of applicable structures are as follows: a two-unit tandem structure including a light-emitting unit emitting yellow light and a light-emitting unit emitting blue light; a two-unit tandem structure including a light-emitting unit emitting red light and green light and a light-emitting unit emitting blue light; a three-unit tandem structure in which a light-emitting unit emitting blue light, a light-emitting unit emitting yellow light, yellow-green light, or green light, and a light-emitting unit emitting blue light are stacked in this order; and a three-unit tandem structure in which a light-emitting unit emitting blue light, a light-emitting unit emitting yellow light, yellow-green light, or green light and red light, and a light-emitting unit emitting blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

In the case where the light-emitting element configured to emit white light has a microcavity structure, light with a specific wavelength such as red, green, or blue is sometimes intensified and emitted.

Alternatively, the light-emitting elements 130R, 130G, and 130B illustrated in FIG. 31B emit blue light, for example. In this case, the EL layer 113 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by the subpixel can be improved.

### [Display Device 50C]

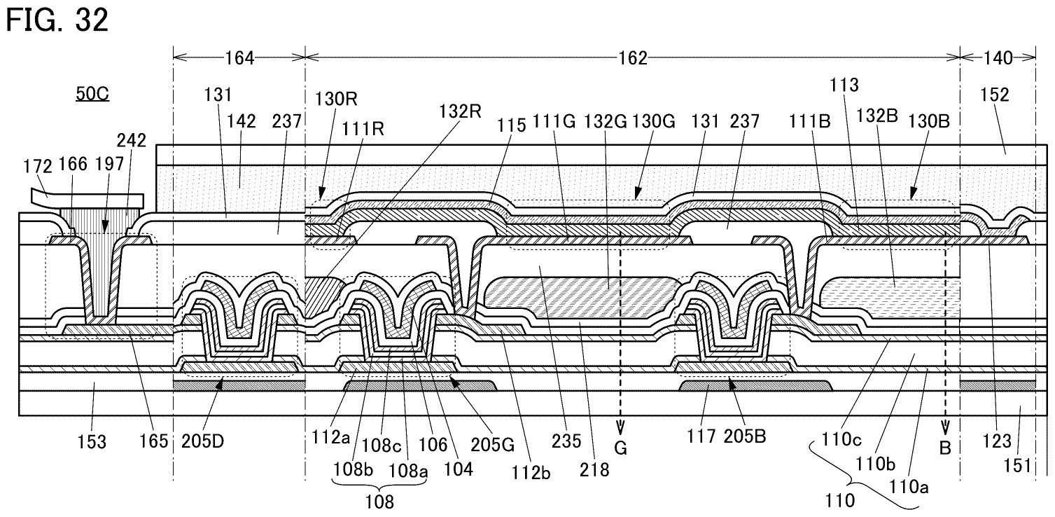

A display device 50C illustrated in FIG. 32 is different from the display device 50B mainly in having a bottom-emission structure.

Light emitted from the light-emitting element is emitted toward the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 32 illustrates an example where the light-blocking layers 117 are provided over the substrate 151, an insulating layer 153 is provided over the light-blocking layers 117, and the transistor 205D, the transistor 205R (not illustrated), the transistor 205G, and the transistor 205B and the like are provided over the insulating layer 153. In addition, the coloring layer 132R, the coloring layer 132G, and the coloring layer 132B are provided over the insulating layer 218 and the insulating layer 235 is provided over the coloring layer 132R, the coloring layer 132G, and the coloring layer 132B.

The light-emitting element 130R overlapping with the coloring layer 132R includes the pixel electrode 111R, the EL layer 113, and the common electrode 115.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

A material having a good visible-light-transmitting property is used for each of the pixel electrodes 111R, 111G, and 111B. A material reflecting visible light is preferably used for the common electrode 115. In the display device having a bottom-emission structure, a metal or the like having low resistance can be used for the common electrode 115; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display device having a bottom-emission structure.

### [Display Device 50D]

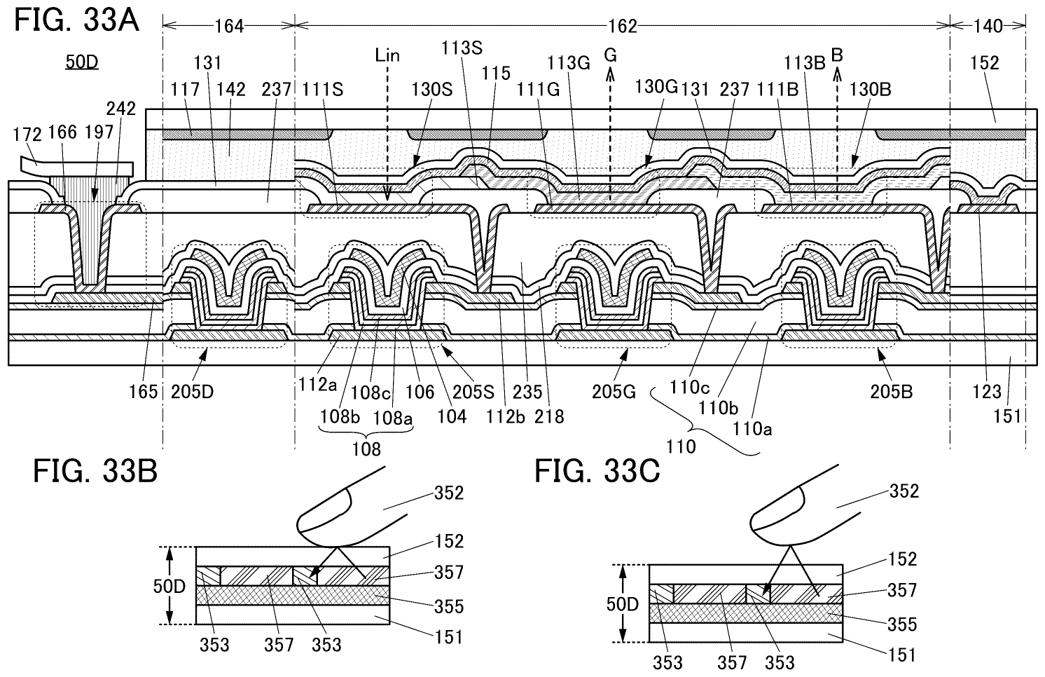

A display device 50D illustrated in FIG. 33A is different from the display device 50A mainly in including a light-receiving element 130S.

The display device 50D includes light-emitting elements and a light-receiving element in a pixel. In the display device 50D, organic EL elements are preferably used as the light-emitting elements and an organic photodiode is preferably used as the light-receiving element. The organic EL elements and the organic photodiodes can be formed over the same substrate. Thus, the organic photodiodes can be incorporated in a display device including the organic EL elements.

In the display device 50D including light-emitting elements and a light-receiving element in each pixel, the pixel has a light-receiving function; thus, the display device can detect a contact or approach of an object while displaying an image. Accordingly, the display portion 162 has one or both of an image capturing function and a sensing function in addition to a function of displaying an image. For example, all the subpixels included in the display device 50D can display an image; alternatively, some of the subpixels can emit light as a light source, some of the rest of the subpixels can detect light, and the other subpixels can display an image.

Accordingly, a light-receiving portion and a light source do not need to be provided separately from the display device 50D; hence, the number of components of an electronic device can be reduced. For example, a biometric authentication device provided in the electronic device, a capacitive touch panel for scroll operation, or the like is not necessarily provided separately. Thus, with the use of the display device 50D, the electronic device can be provided at lower manufacturing costs.

When the light-receiving elements are used as an image sensor, the display device 50D can capture an image using the light-receiving elements. For example, image capturing for personal authentication with the use of a fingerprint, a palm print, the iris, the shape of a blood vessel (including the shape of a vein and the shape of an artery), a face, or the like is possible by using the image sensor.

The light-receiving element can be used for a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display device and the object come in direct contact with each other. Furthermore, the contactless sensor can detect an object even when the object is not in contact with the display device.

The light-receiving element 130S includes a pixel electrode 111S over the insulating layer 235, a functional layer 113S over the pixel electrode 111S, and the common electrode 115 over the functional layer 113S. Light Lin enters the functional layer 113S from the outside of the display device 50D.

The pixel electrode 111S is electrically connected to the conductive layer 112b included in a transistor 205S through an opening provided in the insulating layer 106, the insulating layer 218, and the insulating layer 235.

An end portion of the pixel electrode 111S is covered with the insulating layer 237.

The common electrode 115 is a continuous film provided to be shared by the light-receiving element 130S, the light-emitting element 130R (not illustrated), the light-emitting element 130G, and the light-emitting element 130B. The common electrode 115 shared by the light-emitting elements and the light-receiving element is electrically connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment describes an example where an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

In addition to the active layer, the functional layer 113S may further include a layer containing a substance having a high hole-transport property, a substance having a high electron-transport property, a substance having a bipolar property, or the like. Without limitation to the above, the functional layer 113S may further include a layer containing a substance having a high hole-injection property, a hole-blocking material, a substance having a high electron-injection property, an electron-blocking material, or the like. The functional layer 113S can be formed using a material that can be used for the light-emitting element.

Either a low molecular compound or a high molecular compound can be used for the light-receiving element, and an inorganic compound may be included. Each of the layers included in the light-receiving element can be formed by an evaporation method (including a vacuum evaporation method), a transfer method, a printing method, an inkjet method, a coating method, or the like.

The display device 50D illustrated in FIG. 33B and FIG. 33C includes, between the substrate 151 and the substrate 152, a layer 353 including a light-receiving element, a circuit layer 355, and a layer 357 including light-emitting elements.

The layer 353 includes the light-receiving element 130S, for example. The layer 357 includes the light-emitting elements 130R, 130G, and 130B, for example.

The functional layer 355 includes a circuit for driving the light-receiving element and a circuit for driving the light-emitting element. The circuit layer 355 includes the transistors 205R, 205G, and 205B, for example. One or more of a switch, a capacitor, a resistor, a wiring, a terminal, and the like can be provided in the circuit layer 355.

FIG. 33B illustrates an example where the light-receiving element 130S is used as a touch sensor. Light emitted from the light-emitting element in the layer 357 is reflected by a finger 352 that touches the display device 50D as illustrated in FIG. 33B, and the light-receiving element in the layer 353 detects the reflected light. Thus, the touch of the finger 352 on the display device 50D can be detected.

FIG. 33C is an example where the light-receiving element 130S is used as a contactless sensor. Light emitted from the light-emitting element in the layer 357 is reflected by the finger 352 that is approaching (i.e., that is not in contact with) the display device 50D as illustrated in FIG. 33C, and the light-receiving element in the layer 353 detects the reflected light.

### [Display Device 50E]

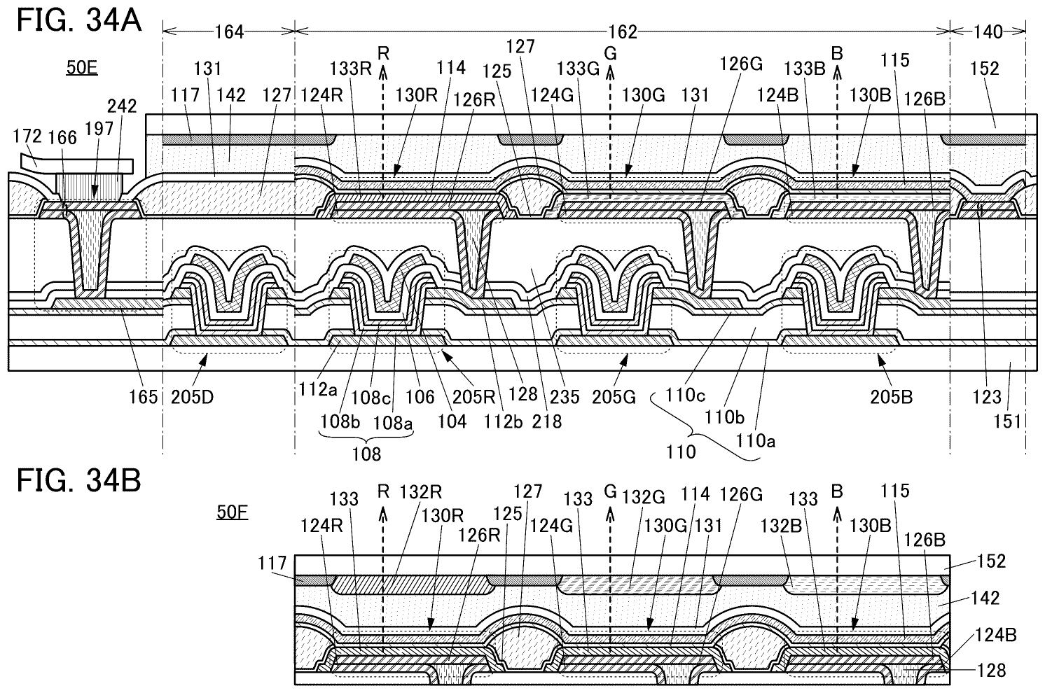

A display device 50E illustrated in FIG. 34A is an example of a display device having an MML (metal maskless) structure. In other words, the display device 50E includes a light-emitting element that is formed without using a fine metal mask. The stacked-layer structure from the substrate 151 to the insulating layer 235 and the stacked-layer structure from the protective layer 131 to the substrate 152 are similar to those in the display device 50A; thus, the description thereof is omitted.

In FIG. 34A, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 34A emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 34A emits green light (G). The layer 133G includes a light-emitting layer that emits green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 34A emits blue light (B). The layer 133B includes a light-emitting layer that emits blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 114. In this specification and the like, the layer 133R, the layer 133G, and the layer 133B are sometimes referred to as island-shaped EL layers, EL layers formed in an island shape, or the like, in which case the common layer 114 is not included.

The layer 133R, the layer 133G, and the layer 133B are separated from one another. When the EL layer is provided to have an island shape for each light-emitting element, a leakage current between adjacent light-emitting elements can be inhibited. This can prevent unintended light emission due to crosstalk, so that a display device with extremely high contrast can be obtained.

Although the layers 133R, 133G, and 133B have the same thickness in FIG. 34A, the present invention is not limited thereto. The layers 133R, 133G, and 133B may have different thicknesses.

The conductive layer 124R is electrically connected to the conductive layer 112b included in the transistor 205R through an opening provided in the insulating layer 106, the insulating layer 218, and the insulating layer 235. In a similar manner, the conductive layer 124G is electrically connected to the conductive layer 112b included in the transistor 205G and the conductive layer 124B is electrically connected to the conductive layer 112b included in the transistor 205B.

The conductive layers 124R, 124G, and 124B are formed to cover the openings provided in the insulating layer 235. A layer 128 is embedded in each of the depressed portions of the conductive layers 124R, 124G, and 124B.

The layer 128 has a planarization function for the depressed portions of the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressed portions of the conductive layers 124R, 124G, and 124B can also be used as the light-emitting regions, increasing the aperture ratio of the pixels. The conductive layer 124R and the conductive layer 126R each preferably include a conductive layer functioning as a reflective electrode.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 34A illustrates an example where the top surface of the layer 128 includes a flat portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle greater than 0° and less than 90°. In the case where the end portion of the pixel electrode has a tapered shape, the layer 133R provided along the side surface of the pixel electrode has an inclined portion. When the side surface of the pixel electrode has a tapered shape, coverage with an EL layer provided along the side surface of the pixel electrode can be favorable.

Since the conductive layers 124G and 126G and the conductive layers 124B and 126B are similar to the conductive layers 124R and 126R, the detailed description thereof is omitted.

The top surface and the side surface of the conductive layer 126R are covered with the layer 133R. Similarly, top surface and the side surface of the conductive layers 126G are covered with the layer 133G, and the top surface and the side surface of the conductive layers 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layer 133R, the layer 133G, and the layer 133B are covered with insulating layers 125 and 127. The common layer 114 is provided over the layer 133R, the layer 133G, and the layer 133B and the insulating layers 125 and 127, and the common electrode 115 is provided over the common layer 114. The common layer 114 and the common electrode 115 are each a continuous film shared by a plurality of light-emitting elements.

In FIG. 34A, the insulating layer 237 illustrated in FIG. 31A or the like is not provided between the conductive layer 126R and the layer 133R. That is, an insulating layer (also referred to as a partition wall, a bank, a spacer, or the like) in contact with the pixel electrode and covering an upper end portion of the pixel electrode is not provided in the display device 50E. Thus, the distance between adjacent light-emitting elements can be extremely narrowed. Accordingly, the display device can have high resolution or high definition. In addition, a mask for forming the insulating layer is not needed, which leads to a reduction in manufacturing cost of the display device.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting elements 130R, 130G, and 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surfaces (and part of the top surfaces) of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting element can be increased. The insulating layer 127 is provided over the insulating layer 125 to fill a depressed portion of the insulating layer 125. The insulating layer 127 preferably covers at least part of the side surface of the insulating layer 125.

The insulating layers 125 and 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display device of one embodiment of the present invention, the step can be reduced with the insulating layer 125 and the insulating layer 127, and the coverage with the common layer 114 and the common electrode 115 can be improved. Thus, connection defects caused by step disconnection can be inhibited. Alternatively, an increase in electrical resistance caused by local thinning of the common electrode 115 due to level difference can be inhibited.

The top surface of the insulating layer 127 preferably has a shape with higher flatness. The top surface of the insulating layer 127 may include at least one of a flat surface, a convex surface, and a concave surface. For example, the top surface of the insulating layer 127 preferably has a convex shape with a large radius of curvature.

The insulating layer 125 can be an insulating layer including an inorganic material. As the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 may have a single-layer structure or a stacked-layer structure. In particular, aluminum oxide is preferable because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used as the insulating layer 125, the insulating layer 125 having few pinholes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of the barrier insulating layer, entry of impurities (typically, at least one of water and oxygen) that may diffuse into the light-emitting elements from the outside can be inhibited. With this structure, a highly reliable light-emitting element and a highly reliable display device can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 127 provided over the insulating layer 125 has a function of filling large unevenness of the insulating layer 125, which is formed between the adjacent light-emitting elements. In other words, the insulating layer 127 has an effect of improving the flatness of the formation surface of the common electrode 115.

As the insulating layer 127, an insulating layer containing an organic material can be favorably used. As the organic material, a photosensitive organic resin is preferably used, and for example, a photosensitive resin composite including an acrylic resin is preferably used. In this specification and the like, an acrylic resin refers to not only a polymethacrylic acid ester or a methacrylic resin, but also all the acrylic-based polymers in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. Examples of organic materials used for the insulating layer 127 include polyvinyl alcohol (PVA), polyvinyl butyral, polyvinyl pyrrolidone, polyethylene glycol, polyglycerin, pullulan, water-soluble cellulose, and an alcohol-soluble polyamide resin. A photoresist may be used for the photosensitive resin. As the photosensitive organic resin, either a positive material or a negative material may be used.

For the insulating layer 127, a material absorbing visible light may be used. When the insulating layer 127 absorbs light emitted from the light-emitting element, leakage of light (stray light) from the light-emitting element to an adjacent light-emitting element through the insulating layer 127 can be inhibited. Thus, the display quality of the display device can be improved. Since no polarizing plate is required to improve the display quality of the display device, the weight and thickness of the display device can be reduced.

Examples of the material absorbing visible light include materials including pigment of black or the like, materials including dye, light-absorbing resin materials (e.g., polyimide), and resin materials that can be used for color filters (color filter materials). Using a resin material obtained by stacking or mixing color filter materials of two colors or three or more colors is particularly preferable, in which case the effect of blocking visible light can be enhanced. In particular, mixing color filter materials of three or more colors enables the formation of a black or nearly black resin layer. [Display device 50F]

FIG. 34B shows an example of a cross section of the display portion 162 of a display device 50F. The display device 50F is different from the display device 50E mainly in that the subpixels of different colors are provided with coloring layers (color filters or the like). The structure illustrated in FIG. 34B can be combined with the structure of the region including the FPC 172, the circuit portion 164, the stacked-layer structure from the substrate 151 to the insulating layer 235 in the display portion 162, the connection portion 140, and the end portion, which is illustrated in FIG. 34A.

In the display device 50F illustrated in FIG. 34B, the light-emitting elements 130R, 130G, and 130B, the coloring layer 132R transmitting red light, the coloring layer 132G transmitting green light, the coloring layer 132B transmitting blue light, and the like are provided.

Light emitted from the light-emitting element 130R is extracted as red light to the outside of the display device 50F through the coloring layer 132R. Similarly, light emitted from the light-emitting element 130G is extracted as green light to the outside of the display device 50F through the coloring layer 132G. Light emitted from the light-emitting element 130B is extracted as blue light to the outside of the display device 50F through the coloring layer 132B.

The light-emitting elements 130R, 130G, and 130B each include a layer 133. These three layers 133 are formed using the same material in the same step. The three layers 133 are separated from each other. When the EL layer is provided to have an island shape for each light-emitting element, a leakage current between adjacent light-emitting elements can be inhibited. This can prevent unintended light emission due to crosstalk, so that a display device with extremely high contrast can be obtained.

The light-emitting elements 130R, 130G, and 130B illustrated in FIG. 34B emit white light, for example. When white light emitted from the light-emitting elements 130R, 130G, and 130B passes through the coloring layers 132R, 132G, and 132B, light of desired colors can be obtained.

Alternatively, the light-emitting elements 130R, 130G, and 130B illustrated in FIG. 34B emit blue light, for example. In this case, the layer 133 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light transmitted through the color conversion layer is extracted through the coloring layer, light other than light of the intended color can be absorbed by the coloring layer, and color purity of light exhibited by a subpixel can be improved.

### [Display Device 50G]

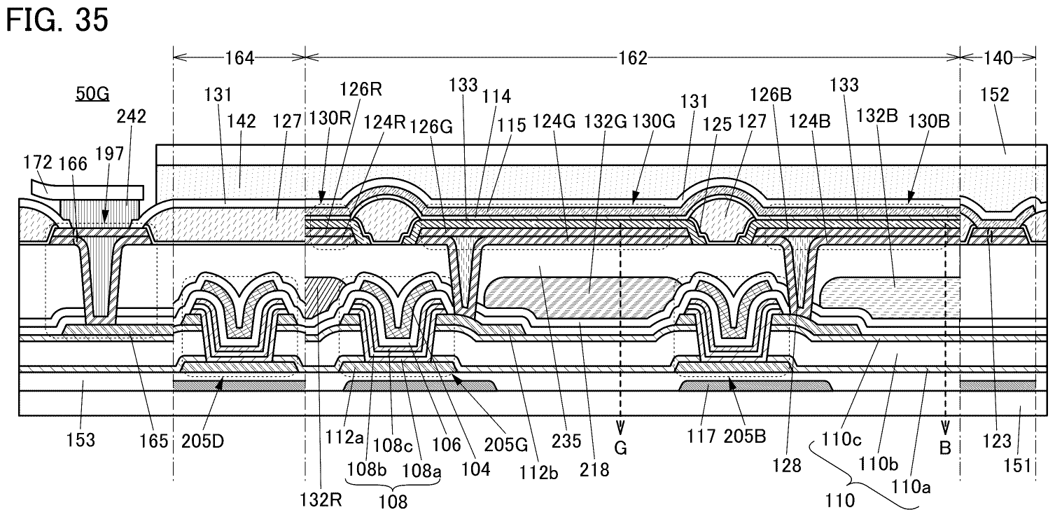

A display device 50G illustrated in FIG. 35 is different from the display device 50F mainly in having a bottom-emission structure.

Light emitted from the light-emitting element is emitted toward the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 35 illustrates an example where the light-blocking layers 117 are provided over the substrate 151, the insulating layer 153 is provided over the light-blocking layers 117, and the transistor 205D, the transistor 205R (not illustrated), the transistor 205G, and the transistor 205B and the like are provided over the insulating layer 153. In addition, the coloring layer 132R, the coloring layer 132G, and the coloring layer 132B are provided over the insulating layer 218 and the insulating layer 235 is provided over the coloring layer 132R, the coloring layer 132G, and the coloring layer 132B.

The light-emitting element 130R overlapping with the coloring layer 132R includes the conductive layer 124R, the conductive layer 126R, the layer 133, the common layer 114, and the common electrode 115.

The light-emitting element 130G overlapping with the coloring layer 132G includes the conductive layer 124G, the conductive layer 126G, the layer 133, the common layer 114, and the common electrode 115.

The light-emitting element 130B overlapping with the coloring layer 132B includes the conductive layer 124B, the conductive layer 126B, the layer 133, the common layer 114, and the common electrode 115.

A material having a good visible-light-transmitting property is used for each of the conductive layers 124R, 124G, 124B, 126R, 126G, and 126B. A material reflecting visible light is preferably used for the common electrode 115. In the display device having a bottom-emission structure, a metal or the like having low resistance can be used for the common electrode 115; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display device having a bottom-emission structure.

### [Display Device 50H]

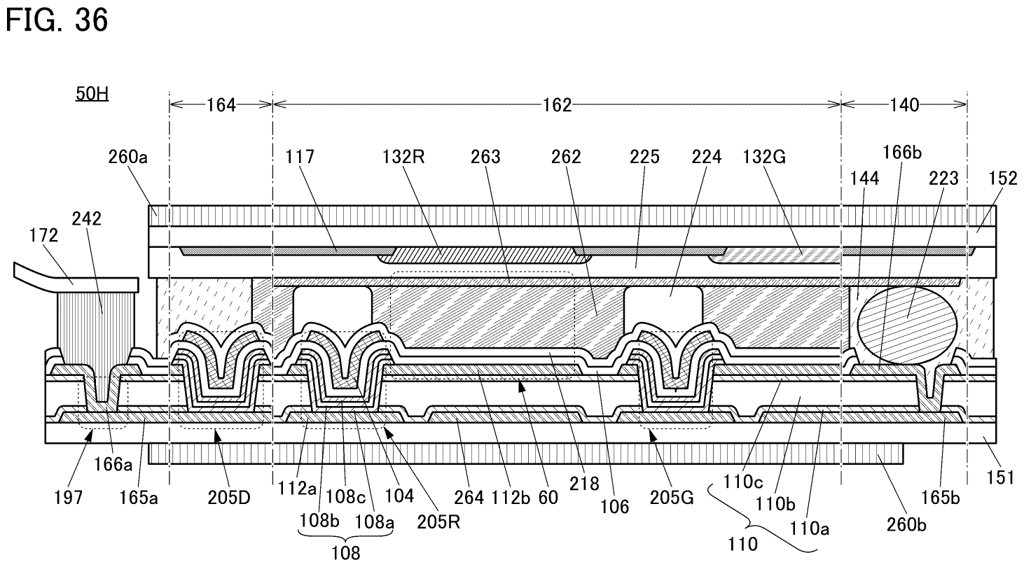

A display device 50H illustrated in FIG. 36 is a liquid crystal display device in a VA mode.

The substrate 151 and the substrate 152 are attached to each other with an adhesive layer 144. A liquid crystal 262 is encapsulated in a region that is surrounded by the substrate 151, the substrate 152, and the adhesive layer 144. A polarizing plate 260a is positioned on the outer surface of the substrate 152, and a polarizing plate 260b is positioned on the outer surface of the substrate 151. Although not illustrated, a backlight can be provided outside the polarizing plate 260a or outside the polarizing plate 260b.

The substrate 151 is provided with the transistors 205D, 205R, and 205G, the connection portion 197, a spacer 224, and the like. The transistor 205D is provided in the circuit portion 164, and the transistor 205R and the transistor 205G are provided in the display portion 162. The conductive layers 112b included in the transistor 205R and the transistor 205G function as a pixel electrode of a liquid crystal element 60.

The substrate 152 is provided with the coloring layer 132R, the coloring layer 132G, the light-blocking layer 117, an insulating layer 225, an conductive layer 263, and the like. The conductive layer 263 functions as a common electrode of the liquid crystal element 60.

The transistors 205D, 205R, and 205G each include the conductive layer 112a, the semiconductor layer 108, the insulating layer 106, the conductive layer 104, and the conductive layer 112b. The conductive layer 112a functions as one of a source electrode and a drain electrode and the conductive layer 112b functions as the other of the source electrode and the drain electrode. The conductive layer 104 functions as a gate electrode. Part of the insulating layer 106 serves as a gate insulating layer.

As above, this embodiment describes an example where OS transistors are used as the transistors 205D, 205R, and 205G. The transistor of one embodiment of the present invention can be used as the transistors 205D, 205R, and 205G. In other words, the display device 50H includes the transistor of one embodiment of the present invention in both the display portion 162 and the circuit portion 164. When the display portion 162 includes the transistor of one embodiment of the present invention, the pixel size can be reduced and high resolution can be achieved. When the circuit portion 164 includes the transistor of one embodiment of the present invention, the area occupied by the circuit portion 164 can be reduced and a narrower bezel can be achieved. The description in the above embodiment can be referred to for the transistor of one embodiment of the present invention.

The transistors 205D, 205R, and 205G are covered with the insulating layer 218. The insulating layer 218 functions as a protective layer of the transistors 205D, 205R, and 205G.

A subpixel included in the display portion 162 includes a transistor, the liquid crystal element 60, and a coloring layer. For example, a subpixel that emits red light includes the transistor 205R, the liquid crystal element 60, and the coloring layer 132R that transmits red light. A subpixel that emits green light includes the transistor 205G, the liquid crystal element 60, and the coloring layer 132G that transmits green light. Similarly, although not illustrated, a subpixel that emits blue light includes a transistor, the liquid crystal element 60, and a coloring layer that transmits blue light.

The liquid crystal element 60 includes the conductive layer 112b, the conductive layer 263, and the liquid crystal 262 sandwiched therebetween.

Over the substrate 151, a conductive layer 264 positioned on the same plane as the conductive layer 112a is provided. The conductive layer 264 includes a portion overlapping with the conductive layer 112b with the insulating layer 110 (the insulating layer 110a, the insulating layer 110b, and the insulating layer 110c) therebetween. The conductive layer 112b, the conductive layer 264, and the insulating layer 110 positioned between the conductive layers 112b and 264 form a storage capacitor. Note that any one or two layers included in the insulating layer 110 may be removed by etching as long as at least one insulating layer is provided between the conductive layer 112b and the conductive layer 264.

The insulating layer 225 is provided on the substrate 152 side to cover the coloring layer 132R, the coloring layer 132G, and the light-blocking layer 117. The insulating layer 225 may have a function as a planarization layer. The conductive layer 263 can have a substantially flat surface owing to the insulating layer 225, resulting in a uniform alignment state of the liquid crystal 262.

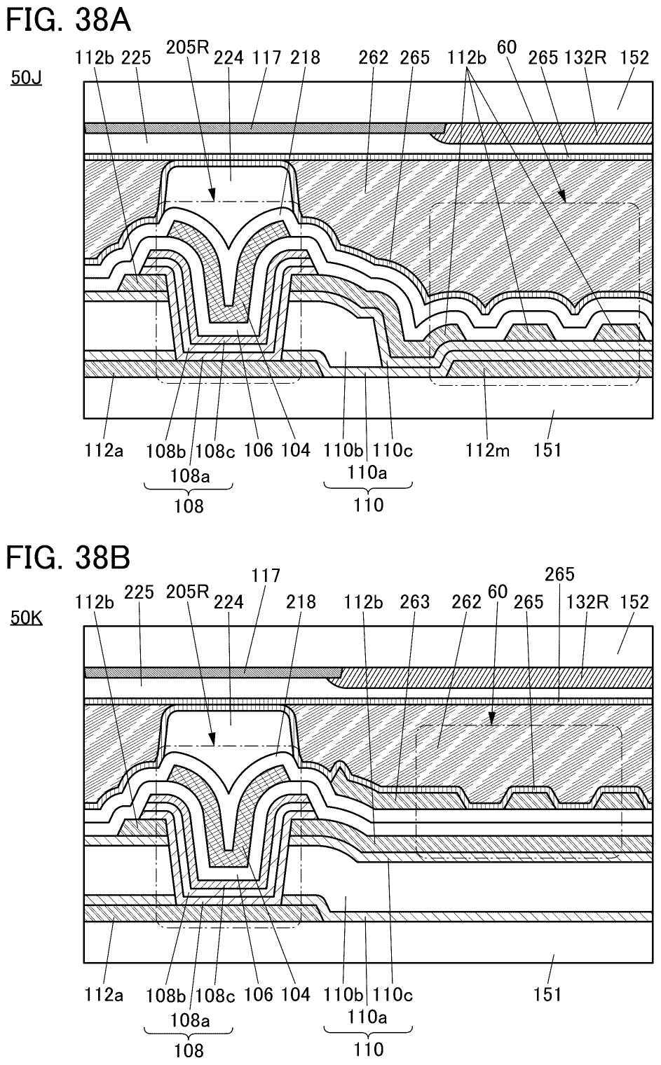

Note that in the conductive layer 263, the insulating layer 218, and the like, the surface in contact with the liquid crystal 262 may be provided with an alignment film for controlling the alignment of the liquid crystal 262 (see an alignment film 265 in FIG. 38A and FIG. 38B).

The conductive layer 112b and the conductive layer 263 transmit visible light. Thus, the display device 50H can be a transmissive liquid crystal display device. For example, in the case where a backlight is provided on the substrate 152 side, light from the backlight which is polarized by the polarizing plate 260a passes through the substrate 152, the conductive layer 263, the liquid crystal 262, the conductive layer 112b, and the substrate 151, and then reaches the polarizing plate 260b. In this case, optical modulation of the light can be controlled by controlling the alignment of the liquid crystal 262 with a voltage applied between the conductive layer 112b and the conductive layer 263. In other words, the intensity of light emitted through the polarizing plate 260b can be controlled. Light other than that in a particular wavelength region is absorbed by the coloring layer, so that red light is extracted, for example.

As the polarizing plate 260b, a linear polarizing plate may be used or a circularly polarizing plate can also be used. An example of a circularly polarizing plate is a stack including a linear polarizing plate and a quarter-wave retardation plate. Reflection of external light can be reduced with a circularly polarizing plate used as the polarizing plate 260b.

In the case where a circularly polarizing plate is used as the polarizing plate 260b, a circularly polarizing plate or a general linear polarizing plate may be used as the polarizing plate 260a. The cell gap, alignment, drive voltage, and the like of the liquid crystal element used as the liquid crystal element 60 are controlled depending on the kind of the polarizing plate used as the polarizing plate 260a and the polarizing plate 260b so that desirable contrast is obtained.

The conductive layer 263 is electrically connected to a conductive layer 166b provided on the substrate 151 side through a connector 223 in the connection portion 140. The conductive layer 166b is electrically connected to a conductive layer 165b through an opening provided in the insulating layer 110. Thus, a potential or a signal can be supplied to the conductive layer 263 from the FPC, the IC, or the like provided on the substrate 151 side. In the structure illustrated in FIG. 36, the conductive layer 165b is formed using the same material in the same step as the conductive layer 112a, and the conductive layer 166b is formed using the same material in the same step as the conductive layer 112b.

As the connector 223, a conductive particle can be used, for example. As the conductive particle, a particle of an organic resin, silica, or the like coated with a metal material can be used. It is preferable to use nickel or gold as the metal material because contact resistance can be reduced. It is also preferable to use a particle coated with layers of two or more types of metal materials, such as a particle coated with nickel and further with gold. As the connector 223, a material capable of elastic deformation or plastic deformation is preferably used. At this time, as illustrated in FIG. 36, the conductive particle has a shape that is vertically crushed in some cases. With the crushed shape, the contact area of the connector 223 and a conductive layer electrically connected to this can be increased, thereby reducing contact resistance and reducing issues such as disconnection. The connector 223 is preferably provided so as to be covered with the adhesive layer 144. For example, the connectors 223 can be dispersed in the adhesive layer 144 before curing of the adhesive layer 144.

In a region near an end portion of the substrate 151, the connection portion 197 is provided. In the connection portion 197, a conductive layer 166a is electrically connected to the FPC 172 through the connection layer 242. The conductive layer 166a is electrically connected to a conductive layer 165a through an opening provided in the insulating layer 110. In the structure illustrated in FIG. 36, the conductive layer 165a is formed using the same material in the same step as the conductive layer 112a, and the conductive layer 166a is formed using the same material in the same step as the conductive layer 112b.

### [Display Device 50I]

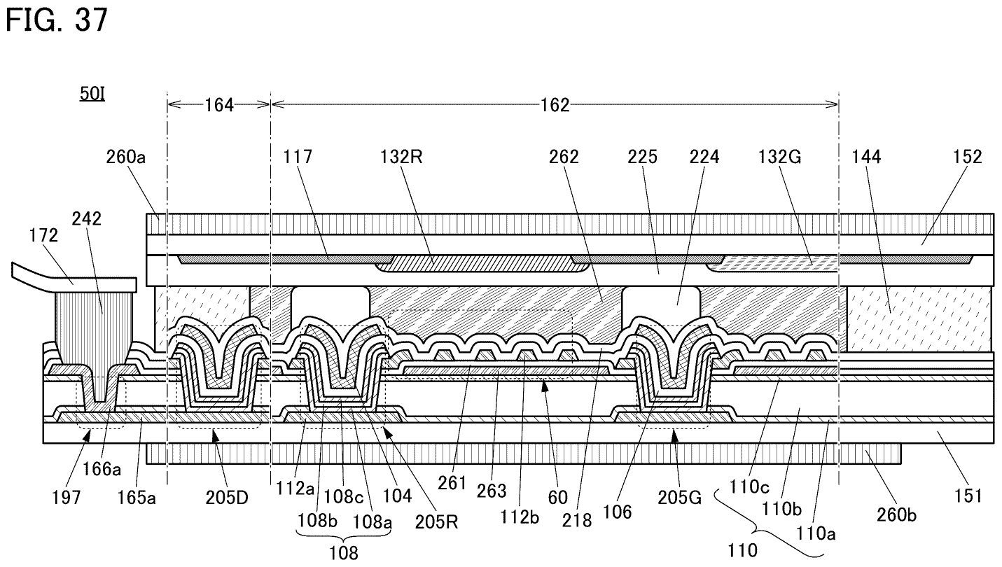

A display device 501 illustrated in FIG. 37 is a liquid crystal display device in an FFS mode. The display device 501 is different from the display device 50H mainly in the structure of the liquid crystal element 60.

The conductive layer 263 functioning as a common electrode of the liquid crystal element 60 is provided over the insulating layer 110, and an insulating layer 261 is provided over the conductive layer 263. The conductive layer 112b having a function of the other of the source electrode and the drain electrode of the transistor and a function of the pixel electrode of the liquid crystal element 60 is provided over the insulating layer 261. The insulating layer 218 is provided over the conductive layer 112b.

In a plan view, the conductive layer 112b has a comb-like shape or a shape with a slit. The conductive layer 263 is provided to overlap with the conductive layer 112b. There is a portion where the conductive layer 112b is not provided over the conductive layer 263 in a region overlapping with the coloring layer.

The conductive layer 112b and the conductive layer 263 are stacked with the insulating layer 261 therebetween, whereby a capacitor is formed. Therefore, it is not necessary to provide a capacitor additionally, and thus the aperture ratio can be increased.

Note that in the liquid crystal element 60, both the conductive layer 112b and the conductive layer 263 may have a comb-like top surface shape. Meanwhile, as shown in the display device 501, only one of the conductive layer 112b and the conductive layer 263 has a comb-like top surface shape in the liquid crystal element 60, whereby the conductive layer 112b and the conductive layer 263 partly overlap with each other. With this structure, capacitance between the conductive layer 112b and the conductive layer 263 can be used as a storage capacitor, and thus a capacitor does not need to be provided additionally; accordingly, the aperture ratio of the display device can be increased.

### [Display Device 50J]

In a display device 50J illustrated in FIG. 38A, a portion of the insulating layer 110b overlapping with the liquid crystal element 60 is removed by etching. The liquid crystal element 60 included in the display device 50J includes a portion where the conductive layer 112b, the insulating layer 110a, and the insulating layer 110c are stacked in this order. The liquid crystal element 60 and the insulating layer 110b are not overlapped with each other, which enables not only an increase in the light transmittance but also a reduction in the number of interfaces positioned on paths of light from the light source. Accordingly, influences of interface reflection and interface scattering can be inhibited.

The conductive layer 112b functions as a pixel electrode of the liquid crystal element 60. A conductive layer 112m serves as a common electrode of the liquid crystal element 60. The conductive layer 112m is formed from the same conductive film that is used for forming the conductive layer 112a.

Note that a portion of at least one of the insulating layer 106 and the insulating layer 218 that overlaps with the liquid crystal element 60 may be removed by etching. The insulator 218 is not necessarily provided. This facilitates transmission of electric fields of the conductive layer 112b and the conductive layer 112m to the liquid crystal 262, which enables high-speed operation of the liquid crystal element 60. Furthermore, light transmittance of a portion overlapping with the liquid crystal element 60 can be increased and the influences of interface reflection and interface scattering can be inhibited. A portion of at least one of the insulating layer 110a and the insulating layer 110c that overlaps with the liquid crystal element 60 may be removed by etching. This also facilitates transmission of the electric fields of the conductive layer 112b and the conductive layer 112m to the liquid crystal 262. Furthermore, the capacitance between the conductive layer 112b and the conductive layer 112m can be increased in some cases. In the liquid crystal element 60, both the conductive layer 112b and the conductive layer 112m may have a comb-like top surface shape. Meanwhile, as shown in the display device 50J, only one of the conductive layer 112b and the conductive layer 112m has a comb-like top surface shape in the liquid crystal element 60, whereby the conductive layer 112b and the conductive layer 112m partly overlap with each other. With this structure, capacitance between the conductive layer 112b and the conductive layer 112m can be used as a storage capacitor, and thus a capacitor does not need to be provided additionally; accordingly, the aperture ratio of the display device can be increased.

### [Display Device 50K]

A display device 50K illustrated in FIG. 38B is different from the display device 501 mainly in that a common electrode is provided over the pixel electrode. The conductive layer 112b included in the transistor 100 functions as a pixel electrode in the liquid crystal element 60. The insulating layer 106 and the insulating layer 218 are provided over the conductive layer 112b, and the conductive layer 263 is provided over the insulating layer 218. The conductive layer 263 functions as a common electrode of the liquid crystal element 60. In a plan view, the conductive layer 263 has a comb-like shape or a shape with a slit.

### Manufacturing Method Example of Display Device

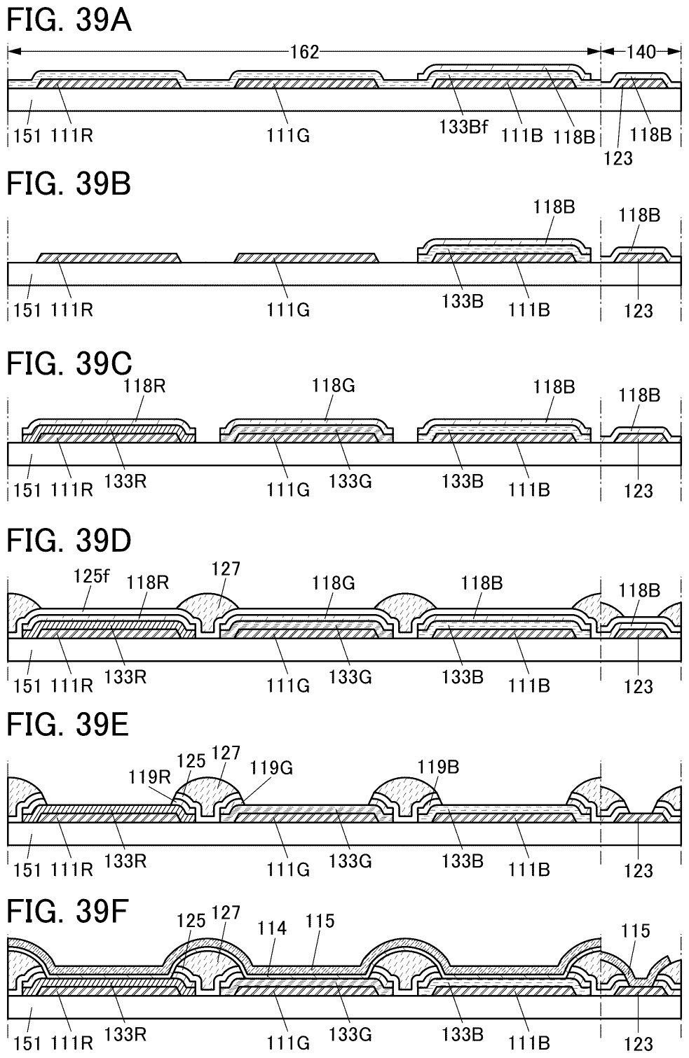

A method for manufacturing a display device having an MML (metal maskless) structure will be described below with reference to FIG. 39. Here, steps of manufacturing light-emitting elements without using a fine metal mask will be described in detail. In FIG. 39, cross-sectional views of three light-emitting elements included in the display portion 162 and the connection portion 140 in the manufacturing steps are illustrated.

For manufacture of the light-emitting elements, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure method, or a micro-contact printing method).

In the method described below for manufacturing the display device, the island-shaped layer (the layer including the light-emitting layer) is formed not by using a fine metal mask but by forming a light-emitting layer on the entire surface and then processing the light-emitting layer by a photolithography method. Accordingly, a high-resolution display device or a display device with a high aperture ratio, which has been difficult to achieve, can be manufactured. Moreover, light-emitting layers can be formed separately for the respective colors, enabling the display device to perform extremely clear display with high contrast and high display quality. In addition, a sacrificial layer provided over a light-emitting layer can reduce damage to the light-emitting layer in the manufacturing process of the display device, increasing the reliability of the light-emitting element.

For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by repeating formation of a light-emitting layer and processing by photolithography three times.

First, the pixel electrodes 111R, 111G, and 111B and the conductive layer 123 are formed over the substrate 151 provided with the transistors 205R, 205G, and 205B and the like (not illustrated) (FIG. 39A).

A conductive film to be the pixel electrodes can be formed by a sputtering method or a vacuum evaporation method, for example. A resist mask is formed over the conductive film by a photolithography process, and then the conductive film is processed, whereby the pixel electrodes 111R, 111G, and 111B and the conductive layer 123 can be formed. For the processing of the conductive film, one or both of a wet etching method and a dry etching method can be used. Next, a film 133Bf to be the layer 133B later is formed over the pixel electrodes 111R, 111G, and 111B (FIG. 39A). The film 133Bf (to be the layer 133B later) includes a light-emitting layer that emits blue light.

In an example described in this embodiment, an island-shaped EL layer included in the light-emitting element that emits blue light is formed first, and then island-shaped EL layers included in the light-emitting elements that emit light of the other colors are formed.

In the formation process of the island-shaped EL layers, the pixel electrode of the light-emitting element of the color formed second or later is sometimes damaged by the preceding step. In this case, the driving voltage of the light-emitting element of the color formed second or later might be high.

In view of this, in manufacture of the display device of one embodiment of the present invention, it is preferable that an island-shaped EL layer of a light-emitting element that emits light with the shortest wavelength (e.g., the blue-light-emitting element) be formed first. For example, it is preferable that island-shaped EL layers be formed in the order of blue, green, and red or in the order of blue, red, and green.

This enables the blue-light-emitting element to keep the favorable state of the interface between the pixel electrode and the EL layer and to be inhibited from having an increased driving voltage. Furthermore, the lifetime of the blue-light-emitting element can be prolonged and the reliability can be increased. Note that the red-light-emitting element and the green-light-emitting element have a smaller increase in driving voltage or the like than the blue-light-emitting element, resulting in a lower driving voltage and higher reliability of the whole display device.

Note that the formation order of the island-shaped EL layers is not limited to the above; for example, the island-shaped EL layers may be formed in the order of red, green, and blue.

As illustrated in FIG. 39A, the film 133Bf is not formed over the conductive layer 123. For example, by using an area mask, the film 133Bf can be formed only in a desired region. Employing a film formation step using an area mask and a processing step using a resist mask enables a light-emitting element to be manufactured by a relatively easy process.

The upper temperature limit of the compounds contained in the film 133Bf is preferably higher than or equal to 100° C. and lower than or equal to 180° C., further preferably higher than or equal to 120° C. and lower than or equal to 180° C., still further preferably higher than or equal to 140° C. and lower than or equal to 180° C. Thus, the reliability of the light-emitting element can be increased. In addition, the upper limit of the temperature that can be applied in the manufacturing process of the display device can be increased. Thus, the range of choices of the materials and the formation method of the display device can be widened, thereby improving the yield and the reliability.

The upper temperature limit, for example, can be any of the glass transition point, the softening point, the melting point, the thermal decomposition temperature, and the 5% weight loss temperature, preferably the lowest temperature thereof.

The film 133Bf can be formed by an evaporation method, specifically a vacuum evaporation method, for example. Alternatively, the film 133Bf may be formed by a transfer method, a printing method, an inkjet method, a coating method, or the like.

Next, a sacrificial layer 118B is formed over the film 133Bf and the conductive layer 123 (FIG. 39A). A resist mask is formed over a film to be the sacrificial layer 118B by a photolithography process, and then the film is processed, whereby the sacrificial layer 118B can be formed.

The sacrificial layer 118B provided over the film 133Bf can reduce damage to the film 133Bf in the manufacturing process of the display device, increasing the reliability of the light-emitting element.

The sacrificial layer 118B is preferably provided to cover the end portions of the pixel electrodes 111R, 111G, and 111B. Accordingly, an end portion of the layer 133B formed in a later step is positioned outward from the end portion of the pixel electrode 111B. The entire top surface of the pixel electrode 111B can be used as a light-emitting region, so that the aperture ratio of the pixel can be increased. The end portion of the layer 133B might be damaged in a step after the formation of the layer 133B, and thus is preferably positioned outward from the end portion of the pixel electrode 111B, i.e., not used as the light-emitting region. This can inhibit a variation in the characteristics of the light-emitting elements and can improve reliability.

When the layer 133B covers the top surface and the side surface of the pixel electrode 111B, the steps after the formation of the layer 133B can be performed in a state where the pixel electrode 111B is not exposed. When the end portion of the pixel electrode 111B is exposed, corrosion might occur in the etching step or the like. When corrosion of the pixel electrode 111B is inhibited, the yield and characteristics of the light-emitting element can be improved.

The sacrificial layer 118B is preferably provided also at a position overlapping with the conductive layer 123. This can inhibit the conductive layer 123 from being damaged during the manufacturing process of the display device.

As the sacrificial layer 118B, a film that is highly resistant to the process conditions for the film 133Bf, specifically, a film having high etching selectivity with the film 133Bf is used.

The sacrificial layer 118B is formed at a temperature lower than the upper temperature limit of each compound included in the film 133Bf. The typical substrate temperature in the formation of the sacrificial layer 118B is lower than or equal to 200° C., preferably lower than or equal to 150° C., further preferably lower than or equal to 120° C., still further preferably lower than or equal to 100° C., yet still further preferably lower than or equal to 80° C.

The upper temperature limit of the compound included in the film 133Bf is preferably high, in which case the film formation temperature of the sacrificial layer 118B can be high. For example, the substrate temperature in formation of the sacrificial layer 118B can be higher than or equal to 100° C., higher than or equal to 120° C., or higher than or equal to 140° C. An inorganic insulating film can have higher density and a higher barrier property as the formation temperature becomes higher. Thus, forming the sacrificial layer at such a temperature can further reduce damage to the film 133Bf and improve the reliability of the light-emitting element.

Note that the same can be applied to the film formation temperature of another layer formed over the film 133Bf (e.g., an insulating film 125f).

The sacrificial layer 118B can be formed by a sputtering method, an ALD method (including a thermal ALD method and a PEALD method), a CVD method, or a vacuum evaporation method, for example. Alternatively, the aforementioned wet film formation method may be used for the formation.

The sacrificial layer 118B (or a layer that is in contact with the film 133Bf in the case where the sacrificial layer 118B has a stacked-layer structure) is preferably formed by a formation method that causes less damage to the film 133Bf. For example, the sacrificial layer 118B is preferably formed by an ALD method or a vacuum evaporation method rather than a sputtering method.

The sacrificial layer 118B can be processed by a wet etching method or a dry etching method. The sacrificial layer 118B is preferably processed by anisotropic etching.

The use of a wet etching method can reduce damage to the film 133Bf in processing of the sacrificial layer 118B, as compared with the case of employing a dry etching method. In the case of employing a wet etching method, it is preferable to use a developer, a tetramethylammonium hydroxide (TMAH) aqueous solution, dilute hydrofluoric acid, oxalic acid, phosphoric acid, acetic acid, nitric acid, or a mixed solution containing two or more of these acids, for example. In the case of employing a wet etching method, a mixed acid chemical solution containing water, phosphoric acid, diluted hydrofluoric acid, and nitric acid may be used. A chemical solution used for the wet etching treatment may be alkaline or acid.

As the sacrificial layer 118B, one or more kinds of a metal film, an alloy film, a metal oxide film, a semiconductor film, an inorganic insulating film, and an organic insulating film can be used, for example.

For the sacrificial layer 118B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

For the sacrificial layer 118B, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, an element M (M is one or more kinds selected from of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

For example, a semiconductor material such as silicon or germanium can be used as a material with a high affinity for the semiconductor manufacturing process. Alternatively, an oxide or a nitride of the semiconductor material can be used. Alternatively, a non-metal material such as carbon or a compound thereof can be used. Alternatively, a metal, such as titanium, tantalum, tungsten, chromium, or aluminum, or an alloy containing one or more of them can be given. Alternatively, an oxide containing the above-described metal, such as titanium oxide or chromium oxide, or a nitride such as titanium nitride, chromium nitride, or tantalum nitride can be used.

As the sacrificial layer 118B, a variety of inorganic insulating films that can be used as the protective layer 131 can be used. In particular, an oxide insulating film is preferable because its adhesion to the film 133Bf is higher than that of a nitride insulating film. For example, an inorganic insulating material such as aluminum oxide, hafnium oxide, or silicon oxide can be used for the sacrificial layer 118B. As the sacrificial layer 118B, an aluminum oxide film can be formed by an ALD method, for example. The use of an ALD method is preferable because damage to a base (in particular, the film 133Bf) can be reduced.

For example, a stacked-layer structure of an inorganic insulating film (e.g., an aluminum oxide film) formed by an ALD method and an inorganic film (e.g., an In—Ga—Zn oxide film, a silicon film, or a tungsten film) formed by a sputtering method can be employed for the sacrificial layer 118B.

Note that the same inorganic insulating film can be used for both the sacrificial layer 118B and the insulating layer 125 that is to be formed later. For example, an aluminum oxide film formed by an ALD method can be used for both the sacrificial layer 118B and the insulating layer 125. Here, for the sacrificial layer 118B and the insulating layer 125, the same film-formation condition may be used or different film-formation conditions may be used. For example, when the sacrificial layer 118B is formed under conditions similar to those of the insulating layer 125, the sacrificial layer 118B can be an insulating layer having a high barrier property against at least one of water and oxygen. Meanwhile, the sacrificial layer 118B is a layer most or all of which is to be removed in a later step, and thus is preferably easy to process. Thus, the sacrificial layer 118B is preferably formed with a substrate temperature lower than that for formation of the insulating layer 125.

An organic material may be used for the sacrificial layer 118B. For example, as the organic material, a material that can be dissolved in a solvent chemically stable with respect to at least the uppermost film of the film 133Bf may be used. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed under a reduced-pressure atmosphere, in which case the solvent can be removed at a low temperature in a short time and thermal damage to the film 133Bf can be accordingly reduced.

The sacrificial layer 118B may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin like perfluoropolymer.

For example, a stacked-layer structure of an organic film (e.g., a PVA film) formed by an evaporation method or the above wet film formation method and an inorganic film (e.g., a silicon nitride film) formed by a sputtering method can be employed for the sacrificial layer 118B.

Note that in the display device of one embodiment of the present invention, part of the sacrificial film remains as the sacrificial layer in some cases.

Then, the film 133Bf is processed using the sacrificial layer 118B as a hard mask, so that the layer 133B is formed (FIG. 39B).

Accordingly, as illustrated in FIG. 39B, the stacked-layer structure of the layer 133B and the sacrificial layer 118B remains over the pixel electrode 111B. In addition, the pixel electrode 111R and the pixel electrode 111G are exposed. In a region corresponding to the connection portion 140, the sacrificial layer 118B remains over the conductive layer 123.

The film 133Bf is preferably processed by anisotropic etching. Anisotropic dry etching is particularly preferable. Alternatively, wet etching may be employed.

After that, steps similar to the formation step of the film 133Bf, the formation step of the sacrificial layer 118B, and the formation step of the layer 133B are repeated twice under the condition where at least light-emitting substances are changed, whereby a stacked-layer structure of the layer 133R and a sacrificial layer 118R is formed over the pixel electrode 111R and a stacked-layer structure of the layer 133G and a sacrificial layer 118G is formed over the pixel electrode 111G (FIG. 39C). Specifically, the layer 133R and the layer 133G are formed to include a light-emitting layer that emits red light and a light-emitting layer that emits green light, respectively. The sacrificial layers 118R and 118G can be formed using a material that can be used for the sacrificial layer 118B, and the sacrificial layers 118R and 118G may be formed using the same material or different materials.

Note that the side surfaces of the layer 133B, the layer 133G, and the layer 133R are preferably perpendicular or substantially perpendicular to their formation surfaces. For example, the angle between the formation surfaces and these side surfaces is preferably greater than or equal to 60° and less than or equal to 90°.

As described above, the distance between two adjacent layers among the layer 133B, the layer 133G, and the layer 133R formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between opposite end portions of two adjacent layers among the layer 133B, the layer 133G, and the layer 133R. When the distance between the island-shaped EL layers is shortened in this manner, a display device with a high resolution and a high aperture ratio can be provided.

Next, the insulating film 125f to be the insulating layer 125 later is formed to cover the pixel electrodes, the layer 133B, the layer 133G, the layer 133R, the sacrificial layer 118B, the sacrificial layer 118G, and the sacrificial layer 118R, and then the insulating layer 127 is formed over the insulating film 125f (FIG. 39D).

As the insulating film 125f, an insulating film is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125f is preferably formed by an ALD method, for example. An ALD method is preferably used, in which case damage due to the film formation can be reduced and a film with high coverage can be formed. As the insulating film 125f, an aluminum oxide film is preferably formed by an ALD method, for example.

Alternatively, the insulating film 125f may be formed by a sputtering method, a CVD method, or a PECVD method that provides a higher film formation speed than an ALD method. In this case, a highly reliable display device can be manufactured with high productivity.

For example, the insulating film to be the insulating layer 127 is preferably formed by the aforementioned wet film formation method (e.g., spin coating) using a photosensitive resin composite containing an acrylic resin. After the formation, heat treatment (also referred to as pre-baking) is preferably performed to eliminate a solvent contained in the insulating film. Next, part of the insulating film is irradiated with visible light or ultraviolet rays, so that the insulating film is partly exposed to light. Subsequently, the region of the insulating film exposed to light is removed by development. After that, heat treatment (also referred to as post-baking) is performed. Accordingly, the insulating layer 127 illustrated in FIG. 39D can be formed. Note that the shape of the insulating layer 127 is not limited to the shape illustrated in FIG. 39D. For example, the top surface of the insulating layer 127 can include one or more of a convex surface, a concave surface, and a flat surface. The insulating layer 127 may cover the side surface of an end portion of at least one of the insulating layer 125, the sacrificial layer 118B, the sacrificial layer 118G, and the sacrificial layer 118R.

Next, as illustrated in FIG. 39E, etching treatment is performed using the insulating layer 127 as a mask to remove the insulating film 125f and parts of the sacrificial layers 118B, 118G, and 118R. Consequently, openings are formed in the sacrificial layers 118B, 118G, and 118R, and the top surfaces of the layer 133B, the layer 133G, the layer 133R, and the conductive layer 123 are exposed. Parts of the sacrificial layers 118B, 118G, and 118R may remain in positions overlapping with the insulating layer 127 and the insulating layer 125 (see sacrificial layers 119B, 119G, and 119R).

The etching treatment can be performed by dry etching or wet etching. The insulating film 125f is preferably formed using a material similar to that for the sacrificial layers 118B, 118G, and 118R, in which case etching treatment can be performed collectively.

As described above, providing the insulating layer 127, the insulating layer 125, the sacrificial layer 118B, the sacrificial layer 118G, and the sacrificial layer 118R can inhibit the common layer 114 and the common electrode 115 between the light-emitting elements from having connection defects due to a disconnected portion and an increase in electric resistance due to a locally thinned portion. Thus, the display quality of the display device of one embodiment of the present invention can be improved.

Next, the common layer 114 and the common electrode 115 are formed in this order over the insulating layer 127, the layer 133B, the layer 133G, and the layer 133R (FIG. 39F).

The common layer 114 can be formed by a method such as an evaporation method (including a vacuum evaporation method), a transfer method, a printing method, an inkjet method, or a coating method.

The common electrode 115 can be formed by a sputtering method or a vacuum evaporation method, for example. Alternatively, a film formed by an evaporation method and a film formed by a sputtering method may be stacked.

As described above, in the method for manufacturing the display device of one embodiment of the present invention, the island-shaped layer 133B, the island-shaped layer 133G, and the island-shaped layer 133R are formed not by using a fine metal mask but by forming a film over the entire surface and processing the film; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the layer 133B, the layer 133G, and the layer 133R can be inhibited from being in contact with each other in the adjacent subpixels. Accordingly, generation of a leakage current between the subpixels can be inhibited. This can prevent unintended light emission due to crosstalk, so that a display device with extremely high contrast can be obtained.

Provision of the insulating layer 127 having a tapered end portion between adjacent island-shaped EL layers can inhibit formation of step disconnection and prevent formation of a locally thinned portion in the common electrode 115 at the time of forming the common electrode 115. This can inhibit the common layer 114 and the common electrode 115 from having connection defects due to the disconnected portion and an increased electric resistance due to the locally thinned portion. Thus, the display device of one embodiment of the present invention can have both a higher resolution and higher display quality.

This embodiment can be combined with the other embodiments as appropriate.

### Embodiment 4

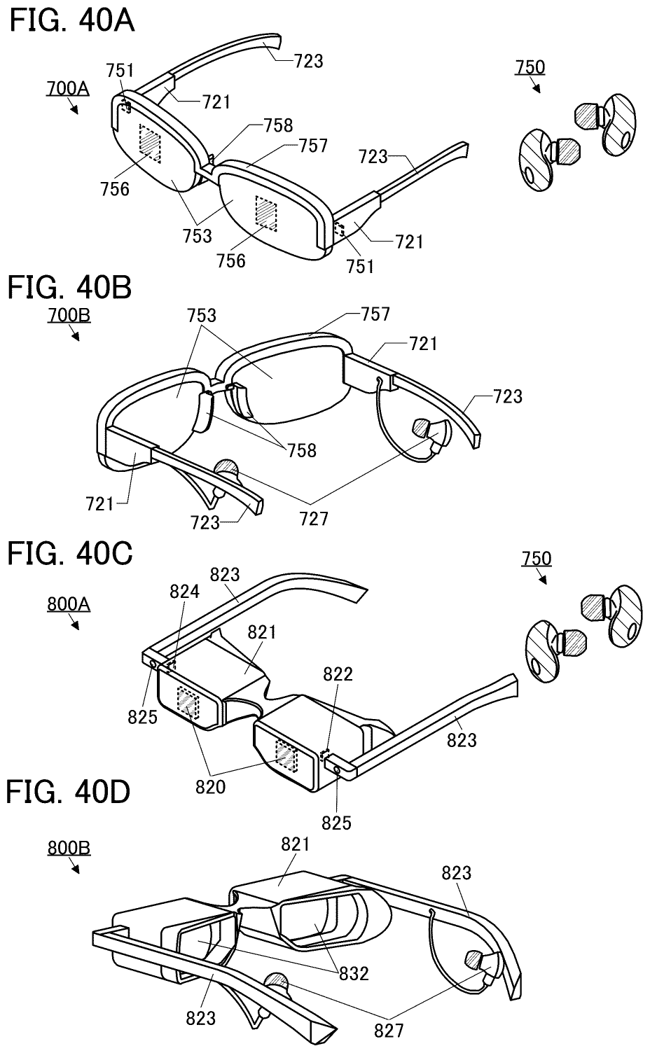

In this embodiment, electronic devices of one embodiment of the present invention will be described with reference to FIG. 40 to FIG. 42.

Electronic devices in this embodiment each include the display device of one embodiment of the present invention in a display portion. The display device of one embodiment of the present invention can be easily increased in resolution and definition. Thus, the display device of one embodiment of the present invention can be used for a display portion of a variety of electronic devices.

A semiconductor device of one embodiment of the present invention can also be applied to any other portion of an electronic device than a display portion. For example, the semiconductor device of one embodiment of the present invention is preferably used for a control portion or the like of an electronic device because lower power consumption can be achieved.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display device of one embodiment of the present invention can have high resolution, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560× 1600), 4K (number of pixels: 3840× 2160), or 8K (number of pixels: 7680× 4320). In particular, the definition is preferably 4K, 8K, or higher. The pixel density (resolution) of the display device of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device capable of being worn on a head are described with reference to FIG. 40A to FIG. 40D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 40A and an electronic device 700B illustrated in FIG. 40B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of the wireless communication device or in addition to the wireless communication device, a connector to which a cable for supplying a video signal and a power supply potential can be connected may be provided.

The electronic device 700A and the electronic device 700B are each provided with a battery (not illustrated) so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 40C and an electronic device 800B illustrated in FIG. 40D each include a pair of display portions 820, a housing 821, a communication portion 822, a pair of wearing portions 823, a control portion 824, a pair of image capturing portions 825, and a pair of lenses 832. Note that the display portions 820, the communication portion 822, and the image capturing portions 825 are omitted in FIG. 40D.

The display device of one embodiment of the present invention can be used for the display portions 820. Thus, the electronic device can perform display with extremely high resolution. This enables a user to feel high sense of immersion.

The display portions 820 are provided at a position inside the housing 821 so as to be seen through the lenses 832. When the pair of the display portions 820 displays different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 40C and the like illustrate examples where the wearing portion has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A. The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 40A has a function of transmitting information to the earphones 750 with the wireless communication function. As another example, the electronic device 800A in FIG. 40C has a function of transmitting information to the earphones 750 with the wireless communication function.

The electronic device may include an earphone portion. The electronic device 700B illustrated in FIG. 40B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 40D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. The earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

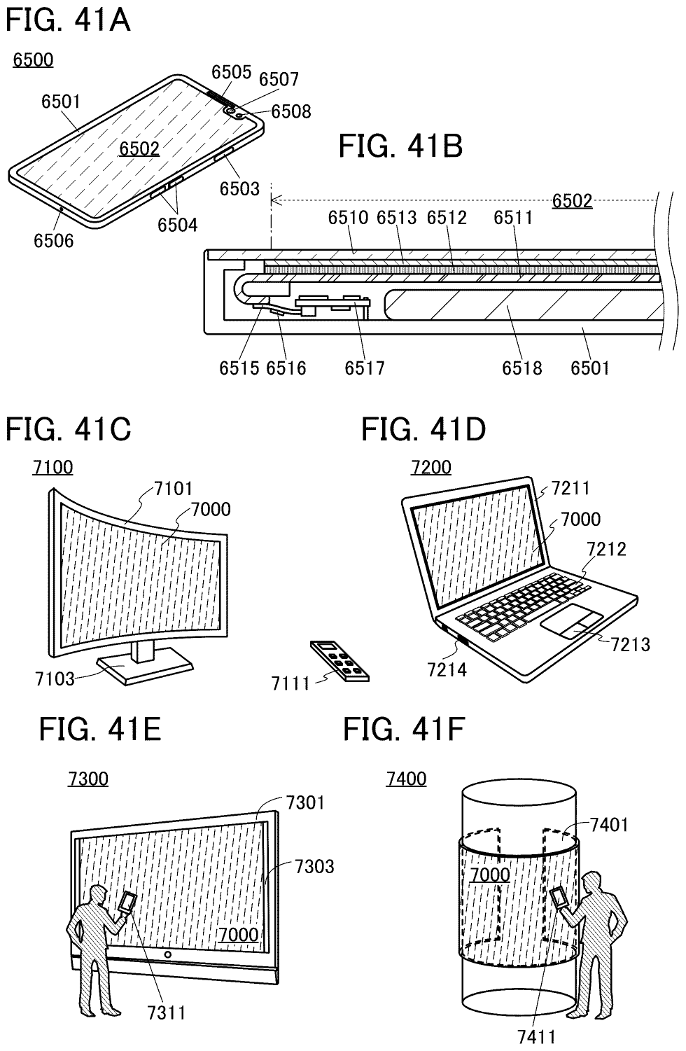

An electronic device 6500 illustrated in FIG. 41A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used for the display portion 6502.

FIG. 41B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while an increase in thickness of the electronic device is reduced. Moreover, part of the display panel 6511 is folded back so that a connection portion with the FPC 6515 is provided on the back side of the pixel portion, whereby an electronic device with a narrow bezel can be achieved.

FIG. 41C illustrates an example of a television device. In a television device 7100, a display portion 7000 is incorporated in a housing 7101. Here, a structure in which the housing 7101 is supported by a stand 7103 is illustrated.

The display device of one embodiment of the present invention can be used for the display portion 7000.

Operation of the television device 7100 illustrated in FIG. 41C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 41D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display device of one embodiment of the present invention can be used for the display portion 7000.

FIG. 41E and FIG. 41F illustrate examples of digital signage.

Digital signage 7300 illustrated in FIG. 41E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 41F is digital signage 7400 attached to a cylindrical pillar 7401. The digital signage 7400 includes the display portion 7000 provided along a curved surface of the pillar 7401.

The display device of one embodiment of the present invention can be used for the display portion 7000 in each of FIG. 41E and FIG. 41F.

A larger area of the display portion 7000 can increase the amount of information that can be provided at a time. The larger the display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 41E and FIG. 41F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

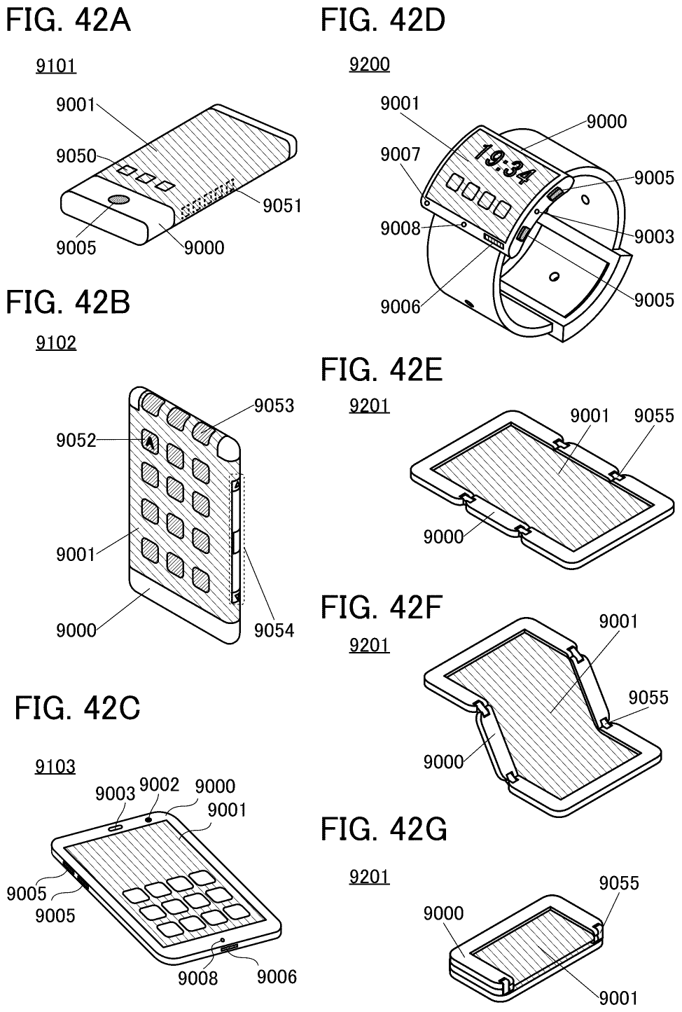

Electronic devices illustrated in FIG. 42A to FIG. 42G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, a smell, or infrared rays), a microphone 9008, and the like.

The display device of one embodiment of the present invention can be used for the display portion 9001 in FIG. 42A to FIG. 42G.

The electronic devices illustrated in FIG. 42A to FIG. 42G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. The functions of the electronic devices are not limited thereto, and the electronic devices can have a variety of functions. The electronic devices may each include a plurality of display portions. The electronic devices may each be provided with a camera or the like and have a function of taking a still image or a moving image and storing the taken image in a storage medium (an external storage medium or a storage medium incorporated in the camera), a function of displaying the taken image on the display portion, or the like.

The electronic devices illustrated in FIG. 42A to FIG. 42G are described in detail below.

FIG. 42A is a perspective view illustrating a portable information terminal 9101. For example, the portable information terminal 9101 can be used as a smartphone. The portable information terminal 9101 may be provided with the speaker 9003, the connection terminal 9006, the sensor 9007, or the like. The portable information terminal 9101 can display characters and image information on its plurality of surfaces. FIG. 42A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 42B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 42C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 42D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. The charging operation may be performed by wireless power feeding.

FIG. 42E to FIG. 42G are perspective views illustrating a foldable portable information terminal 9201. FIG. 42E is a perspective view of an opened state of the portable information terminal 9201, FIG. 42G is a perspective view of a folded state thereof, and FIG. 42F is a perspective view of a state in the middle of change from one of FIG. 42E and FIG. 42G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### Example

In this example, a semiconductor device including transistors of one embodiment of the present invention was fabricated and the electrical characteristics of the transistors were evaluated.

For the structure of a sample fabricated in this example, the description of FIG. 7A and FIG. 7B can be referred to. For the fabrication method, the description of FIG. 28A to FIG. 29D can be referred to. As illustrated in FIG. 7A and FIG. 7B, the insulating layer 110a had a stacked-layer structure of the insulating layer 110a_1 and the insulating layer 110a_2, and the insulating layer 110c had a stacked-layer structure of the insulating layer 110c_1 and the insulating layer 110c_2.

### <Fabrication of Sample>

First, the conductive layer 112a was formed over the substrate 102. The conductive layer 112a had a stacked-layer structure of an approximately 300-nm-thick copper film and an approximately 100-nm-thick In—Sn—Si oxide (ITSO) film. A glass substrate with a size of 600 mm×720 mm was used as the substrate 102.

Next, an approximately 70-nm-thick silicon nitride film was formed as a first insulating film to be the insulating layer 110a_1, an approximately 100-nm-thick silicon nitride film was formed as a second insulating film to be the insulating layer 110a_2, and an approximately 500-nm-thick silicon oxynitride film was formed as a third insulating film to be the insulating layer 110b (the insulating film 110bf). The first insulating film, the second insulating film, and the third insulating film were successively formed using the same apparatus by a PECVD method. Silane (SiH₄), nitrogen (N₂), and ammonia (NH₃) were used as a film formation gas used for forming the first insulating film, and silane (SiH₄) and nitrogen (N₂) were used as a film formation gas used for forming the second insulating film (the insulating film 110af). That is, the ammonia flow rate ratio at the time of forming the first insulating film was made higher than the ammonia flow rate ratio at the time of forming the second insulating film (the insulating film 110af).

Next, an approximately 20-nm-thick IGZO film was formed as the metal oxide layer 139 over the third insulating film (the insulating film 110bf). The metal oxide layer 139 was formed by a sputtering method using an IGZO sputtering target with an atomic ratio of metal elements of In:Ga:Zn=1:1:1.

Then, heat treatment was performed at 250° C. in a dry air atmosphere for one hour. An oven apparatus was used for the heat treatment.

Next, the metal oxide layer 139 was removed. The metal oxide layer 139 was removed by a wet etching method.

Next, an approximately 5-nm-thick IGZO film was formed over the third insulating film (the insulating film 110bf) by a sputtering method. The IGZO film was formed using an IGZO sputtering target with an atomic ratio of metal elements of In:Ga:Zn=1:1:1.

Then, plasma treatment was performed in an atmosphere containing oxygen. An ashing apparatus was used for the plasma treatment.

Next, the IGZO film was removed. For the removal of the IGZO film, a wet etching method was used.

Next, an approximately 50-nm-thick silicon nitride film was formed as the fourth insulating film to be the insulating layer 110c_1 over the third insulating film (the insulating film 110bf), and an approximately 100-nm-thick silicon nitride film was formed as the fifth insulating film to be the insulating layer 110c_2. The fourth insulating film and the fifth insulating film were successively formed using the same apparatus by a PECVD method. Silane (SiH₄) and nitrogen (N₂) were used as deposition gases for forming the fourth insulating film, and silane (SiH₄), nitrogen (N₂), and ammonia (NH₃) were used as deposition gases for forming the fifth insulating film. That is, the ammonia flow rate ratio at the time of forming the fifth insulating film was higher than the ammonia flow rate ratio at the time of forming the fourth insulating film.

Then, an approximately 100-nm-thick In—Sn—Si oxide (ITSO) film was formed as the conductive film 112bf over the fifth insulating film by a sputtering method.

Subsequently, the conductive film 112bf was processed to obtain the conductive layer 112B.

Next, the conductive layer 112B in a region overlapping with the conductive layer 112a was removed to form the conductive layer 112b having the opening 143, and the first insulating film to the fifth insulating film in a region overlapping with the conductive layer 112a were removed to form the insulating layer 110 having the opening 141. The conductive layer 112B was removed by a wet etching method. The first insulating film to the fifth insulating film were removed by a dry etching method. The top surface shapes of the opening 141 and the opening 143 were circular.

Next, the metal oxide film 108f was formed by a sputtering method to cover the opening 141 and the opening 143. As the metal oxide film 108f, an approximately 1-nm-thick metal oxide film 108af, an approximately 10-nm-thick metal oxide film 108bf over the metal oxide film 108af, and an approximately 5-nm-thick metal oxide film 108cf over the metal oxide film 108bf were formed. The metal oxide film 108af and the metal oxide film 108cf were each formed using an IGZO sputtering target with an atomic ratio of metal elements of In:Ga:Zn=1:1:1. The metal oxide film 108bf was formed using an IZO sputtering target with an atomic ratio of metal elements of In:Zn=4:1.

Next, the metal oxide film 108f was processed to obtain the semiconductor layer 108 including the semiconductor layer 108a, the semiconductor layer 108b, and the semiconductor layer 108c.

Next, heat treatment was performed at 350° C. in a dry air atmosphere for one hour. An oven apparatus was used for the heat treatment.

Next, an approximately 50-nm-thick silicon oxynitride film was formed as the insulating layer 106 by a plasma CVD method.

Next, an approximately 50-nm-thick titanium film, an approximately 200-nm-thick aluminum film, and an approximately 50-nm-thick titanium film were each deposited by a sputtering method. After that, the conductive films were processed to obtain the conductive layer 104.

Thus, a transistor corresponding to the transistor 100A was formed.

Next, an approximately 300-nm-thick silicon nitride oxide film was formed by a plasma CVD method as a protective layer of the transistor.

Then, heat treatment was performed at 300° C. in a dry air atmosphere for one hour. An oven apparatus was used for the heat treatment.

Next, an approximately 1.5-μm-thick polyimide film was formed as a protective layer. Then, heat treatment was performed at 250° C. in a nitrogen atmosphere for one hour. An oven apparatus was used for the heat treatment.

Through the above process, the samples were obtained.

### <Id-Vd Characteristics>

Then, the Id-Vg characteristics of the transistors of the samples fabricated above were measured.

For measuring the Id-Vg characteristics of the transistors, voltage applied to the gate electrode (hereinafter also referred to as gate voltage (Vg)) was applied from −10 V to +10 V in increments of 0.1 V. Moreover, a voltage applied to the source electrode (hereinafter also referred to as a source voltage (Vs)) was 0 V (comm), and a voltage applied to the drain electrode (hereinafter also referred to as a drain voltage (V_{d})) was 0.1 V and 5.1 V. The lower measurement limit of a drain current (I_{d}) was approximately 1×10⁻¹³ A.

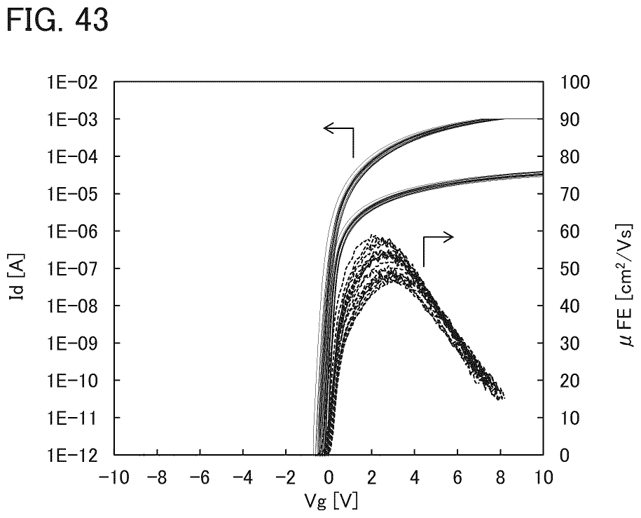

Here, the transistor with the channel width W100 of approximately 6.3 μm (the width D143 of the opening 143 of 2.0 μm) was measured. The number of measurements was set to 20 in a substrate plane of 600 mm×720 mm. The channel length L100 was approximately 0.5 μm. FIG. 43 shows the Id-Vg characteristics of Sample. In FIG. 43, the horizontal axis represents a gate voltage (Vg), the left vertical axis represents a drain current (Id), and the right vertical axis represents field-effect mobility (μFE) at a drain voltage (Vd) of 5.1 V. FIG. 43 shows superimposed Id-Vg characteristics of the 20 transistors. The average threshold voltage (Vₜₕ) of 20 transistors obtained from the Id-Vg characteristics was −0.08 V. The field-effect mobility that was maximum (hereinafter also referred to as maximum field-effect mobility) was greater than or equal to 46 cm²/Vs in each transistor, and the average maximum field-effect mobility of the 20 transistors was 52.6 cm²/Vs. The off-state current was smaller than the lower measurement limit (approximately 1×10⁻¹³ A).

As shown in FIG. 43, it was confirmed that the transistor with a short channel length had all of a threshold voltage close to 0 V, a high on-state current, high field-effect mobility, and a low off-state current.

[Reference Numerals]

10A: semiconductor device, 10B: semiconductor device, 10C: semiconductor device, 10D:
semiconductor device, 10E: semiconductor device, 10: semiconductor device, 11B: subpixel,
11G: subpixel, 11R: subpixel, 30: semiconductor device, 40: semiconductor device, 50A: display
device, 50B: display device, 50C: display device, 50D: display device, 50E: display device, 50F:
display device, 50G: display device, 50H: display device, 50I: display device, 50J: display device,
50K: display device, 60: liquid crystal element, 100_1: transistor, 100_2: transistor, 100_3:
transistor, 100_4: transistor, 100_p: transistor, 100_q: transistor, 100A: transistor, 100B: transistor,
100C: transistor, 100D: transistor, 100: transistor, 102: substrate, 103: conductive layer, 104:
conductive layer, 106: insulating layer, 107: insulating layer, 108_1: semiconductor layer, 108_2:
semiconductor layer, 108_3: semiconductor layer, 108_4: semiconductor layer, 108a:
semiconductor layer, 108af: metal oxide film, 108b: semiconductor layer, 108bf: metal oxide film,
108c: semiconductor layer, 108cf: metal oxide film, 108f: metal oxide film, 108: semiconductor
layer, 110a: insulating layer, 110a_1: insulating layer, 110a_2: insulating layer, 110af: insulating
film, 110b: insulating layer, 110bf: insulating film, 110c: insulating layer, 110c_1: insulating layer,
110c_2: insulating layer, 110cf: insulating film, 110: insulating layer, 111B: pixel electrode,
111G: pixel electrode, 111R: pixel electrode, 111S: pixel electrode, 112a: conductive layer, 112B:
conductive layer, 112b: conductive layer, 112bf: conductive film, 112c: conductive layer, 112d:
conductive layer, 112e: conductive layer, 112m: conductive layer, 113B: EL layer, 113G: EL layer,
113R: EL layer, 113S: functional layer, 113: EL layer, 114: common layer, 115: common
electrode, 117: light-blocking layer, 118B: sacrificial layer, 118G: sacrificial layer, 118R:
sacrificial layer, 119B: sacrificial layer, 119G: sacrificial layer, 120a: insulating layer, 120b:
insulating layer, 120: insulating layer, 123: conductive layer, 124B: conductive layer, 124G:
conductive layer, 124R: conductive layer, 125f: insulating film, 125: insulating layer, 126B:
conductive layer, 126G: conductive layer, 126R: conductive layer, 127: insulating layer, 128:
layer, 130B: light-emitting element, 130G: light-emitting element, 130R: light-emitting element,
130S: light-receiving element, 131: protective layer, 132B: coloring layer, 132G: coloring layer,
132R: coloring layer, 133B: layer, 133Bf: film, 133G: layer, 133R: layer, 133: layer, 139: metal
oxide layer, 140: connection portion, 141_1: opening, 141_4: opening, 141: opening, 142:
adhesive layer, 143_1: opening, 143_2: opening, 143_3: opening, 143_4: opening, 143: opening,
144: adhesive layer, 146: opening, 147a: opening, 147b: opening, 148: opening, 149: opening,
150A: transistor, 150: transistor, 151: substrate, 152: substrate, 153: insulating layer, 162: display
portion, 164: circuit portion, 165a: conductive layer, 165b: conductive layer, 165: conductive layer,
166a: conductive layer, 166b: conductive layer, 166: conductive layer, 172: FPC, 173: IC, 190:
capacitor, 195: insulating layer, 197: connection portion, 200: transistor, 201: pixel, 202:
conductive layer, 204: conductive layer, 205B: transistor, 205D: transistor, 205G: transistor,
205R: transistor, 205S: transistor, 208a: semiconductor layer, 208b: semiconductor layer, 208c:
semiconductor layer, 208D: region, 208L: region, 208: semiconductor layer, 212a: conductive
layer, 212b: conductive layer, 218: insulating layer, 223: connector, 224: spacer, 225: insulating
layer, 235: insulating layer, 237: insulating layer, 241: opening, 242: connection layer, 243:
opening, 250: transistor, 252: insulating layer, 253D: region, 253: semiconductor layer, 254:
insulating layer, 255: conductive layer, 256: insulating layer, 257a: opening, 257b: opening, 258a:
conductive layer, 258b: conductive layer, 259: conductive layer, 260a: polarizing plate, 260b:
polarizing plate, 261: insulating layer, 262: liquid crystal, 263: conductive layer, 264: conductive
layer, 265: alignment film, 352: finger, 353: layer, 355: circuit layer, 357: layer, 700A: electronic
device, 700B: electronic device, 721: housing, 723: wearing portion, 727: earphone portion, 750:
earphone, 751: display panel, 753: optical member, 756: display region, 757: frame, 758: nose
pad, 800A: electronic device, 800B: electronic device, 820: display portion, 821: housing, 822:
communication portion, 823: wearing portion, 824: control portion, 825: image capturing portion,
827: earphone portion, 832: lens, 6500: electronic device, 6501: housing, 6502: display portion,
6503: power button, 6504: button, 6505: speaker, 6506: microphone, 6507: camera, 6508: light
source, 6510: protection member, 6511: display panel, 6512: optical member, 6513: touch sensor
panel, 6515: FPC, 6516: IC, 6517: printed circuit board, 6518: battery, 7000: display portion,
7100: television device, 7101: housing, 7103: stand, 7111: remote control, 7200: laptop personal
computer, 7211: housing, 7212: keyboard, 7213: pointing device, 7214: external connection port,
7300: digital signage, 7301: housing, 7303: speaker, 7311: information terminal, 7400: digital
signage, 7401: pillar, 7411: information terminal, 9000: housing, 9001: display portion, 9002:
camera, 9003: speaker, 9005: operation key, 9006: connection terminal, 9007: sensor, 9008:
microphone, 9050: icon, 9051: information, 9052: information, 9053: information, 9054:
information, 9055: hinge, 9101: portable information terminal, 9102: portable information
terminal, 9103: tablet terminal, 9200: portable information terminal, 9201: portable information
terminal

1. A semiconductor device comprising:
a first semiconductor layer, a second semiconductor layer, a third semiconductor layer, a first conductive layer, a second conductive layer, and a first insulating layer,
wherein the first insulating layer is provided over the first conductive layer,
wherein the second conductive layer is provided over the first insulating layer,
wherein the first insulating layer and the second conductive layer comprise an opening reaching the first conductive layer,
wherein the first semiconductor layer is in contact with a top surface of the first conductive layer, a side surface of the first insulating layer, and a top surface and a side surface of the second conductive layer,
wherein the second semiconductor layer is provided over the first semiconductor layer,
wherein the third semiconductor layer is provided over the second semiconductor layer,
wherein the first semiconductor layer comprises a first material,
wherein the second semiconductor layer comprises a second material,
wherein the third semiconductor layer comprises a third material,
wherein a band gap of the first material is larger than a band gap of the second material, and
wherein a band gap of the third material is larger than the band gap of the second material.

2. The semiconductor device according to claim 1,
wherein the first material is the same as the third material.

3. A semiconductor device comprising:
a first semiconductor layer, a second semiconductor layer, a third semiconductor layer, a first conductive layer, a second conductive layer, and a first insulating layer,
wherein the first insulating layer is provided over the first conductive layer,
wherein the second conductive layer is provided over the first insulating layer,
wherein the first insulating layer and the second conductive layer comprise an opening reaching the first conductive layer,
wherein the first semiconductor layer is in contact with a top surface of the first conductive layer, a side surface of the first insulating layer, and a top surface and a side surface of the second conductive layer,
wherein the second semiconductor layer is provided over the first semiconductor layer,
wherein the third semiconductor layer is provided over the second semiconductor layer,
wherein the first semiconductor layer comprises a first metal oxide,
wherein the second semiconductor layer comprises a second metal oxide,
wherein the third semiconductor layer comprises a third metal oxide,
wherein a band gap of the first metal oxide is larger than a band gap of the second metal oxide, and
wherein a band gap of the third metal oxide is larger than the band gap of the second metal oxide.

4. The semiconductor device according to claim 3,
wherein a composition of the first metal oxide is the same as a composition of the third metal oxide.

5. A semiconductor device comprising:
a first semiconductor layer, a second semiconductor layer, a third semiconductor layer, a first conductive layer, a second conductive layer, and a first insulating layer,
wherein the first insulating layer is provided over the first conductive layer,
wherein the second conductive layer is provided over the first insulating layer,
wherein the first insulating layer and the second conductive layer comprise an opening reaching the first conductive layer,
wherein the first semiconductor layer is in contact with a top surface of the first conductive layer, a side surface of the first insulating layer, and a top surface and a side surface of the second conductive layer,
wherein the second semiconductor layer is provided over the first semiconductor layer,
wherein the third semiconductor layer is provided over the second semiconductor layer,
wherein the first semiconductor layer comprises a first metal oxide,
wherein the second semiconductor layer comprises a second metal oxide,
wherein the third semiconductor layer comprises a third metal oxide,
wherein the first metal oxide comprises indium and a first element,
wherein the second metal oxide comprises indium,
wherein the third metal oxide comprises indium and a second element,
wherein the first element is one or more of gallium, aluminum, and tin,
wherein the second element is one or more of gallium, aluminum, and tin,
wherein a content percentage of the first element in the first metal oxide is higher than a sum of content percentages of gallium, aluminum, and tin in the second metal oxide, and
wherein a content percentage of the second element in the third metal oxide is higher than the sum of the content percentages of gallium, aluminum, and tin in the second metal oxide.

6. The semiconductor device according to claim 5,
wherein a composition of the first metal oxide is the same as a composition of the third metal oxide.

7. The semiconductor device according to claim 1,
wherein a thickness of the first semiconductor layer is smaller than a thickness of the second semiconductor layer, and
wherein a thickness of the third semiconductor layer is smaller than the thickness of the second semiconductor layer.

8. The semiconductor device according to claim 1,
wherein the first conductive layer and the second conductive layer each comprise an oxide conductor.

9. The semiconductor device according to claim 1,
wherein the first insulating layer comprises a second insulating layer, a third insulating layer over the second insulating layer, and a fourth insulating layer over the third insulating layer,
wherein the third insulating layer comprises oxygen, and
wherein the second insulating layer and the fourth insulating layer each comprise nitrogen.

10. The semiconductor device according to claim 1,
wherein the first insulating layer comprises a second insulating layer, a third insulating layer over the second insulating layer, a fourth insulating layer over the third insulating layer, a fifth insulating layer over the fourth insulating layer, and a sixth insulating layer over the fifth insulating layer,
wherein the fourth insulating layer comprises oxygen,
wherein the second insulating layer, the third insulating layer, the fifth insulating layer, and the sixth insulating layer each comprise nitrogen,
wherein the second insulating layer comprises a region having a higher hydrogen content than the third insulating layer, and
wherein the sixth insulating layer comprises a region having a higher hydrogen content than the fifth insulating layer.

11. The semiconductor device according to claim 3,
wherein a thickness of the first semiconductor layer is smaller than a thickness of the second semiconductor layer, and
wherein a thickness of the third semiconductor layer is smaller than the thickness of the second semiconductor layer.

12. The semiconductor device according to claim 3,
wherein the first conductive layer and the second conductive layer each comprise an oxide conductor.

13. The semiconductor device according to claim 3,
wherein the first insulating layer comprises a second insulating layer, a third insulating layer over the second insulating layer, and a fourth insulating layer over the third insulating layer,
wherein the third insulating layer comprises oxygen, and
wherein the second insulating layer and the fourth insulating layer each comprise nitrogen.

14. The semiconductor device according to claim 3,
wherein the first insulating layer comprises a second insulating layer, a third insulating layer over the second insulating layer, a fourth insulating layer over the third insulating layer, a fifth insulating layer over the fourth insulating layer, and a sixth insulating layer over the fifth insulating layer,
wherein the fourth insulating layer comprises oxygen,
wherein the second insulating layer, the third insulating layer, the fifth insulating layer, and the sixth insulating layer each comprise nitrogen,
wherein the second insulating layer comprises a region having a higher hydrogen content than the third insulating layer, and
wherein the sixth insulating layer comprises a region having a higher hydrogen content than the fifth insulating layer.

15. The semiconductor device according to claim 5,
wherein a thickness of the first semiconductor layer is smaller than a thickness of the second semiconductor layer, and
wherein a thickness of the third semiconductor layer is smaller than the thickness of the second semiconductor layer.

16. The semiconductor device according to claim 5,
wherein the first conductive layer and the second conductive layer each comprise an oxide conductor.

17. The semiconductor device according to claim 5,
wherein the first insulating layer comprises a second insulating layer, a third insulating layer over the second insulating layer, and a fourth insulating layer over the third insulating layer,
wherein the third insulating layer comprises oxygen, and
wherein the second insulating layer and the fourth insulating layer each comprise nitrogen.

18. The semiconductor device according to claim 5,
wherein the first insulating layer comprises a second insulating layer, a third insulating layer over the second insulating layer, a fourth insulating layer over the third insulating layer, a fifth insulating layer over the fourth insulating layer, and a sixth insulating layer over the fifth insulating layer,
wherein the fourth insulating layer comprises oxygen,
wherein the second insulating layer, the third insulating layer, the fifth insulating layer, and the sixth insulating layer each comprise nitrogen,
wherein the second insulating layer comprises a region having a higher hydrogen content than the third insulating layer, and
wherein the sixth insulating layer comprises a region having a higher hydrogen content than the fifth insulating layer.
